(19) United States
(12) Patent Application Publication
(10) Pub. No.: US 2025/0286031 A1
(43) Pub. Date: Sep. 11, 2025

(54) SEMICONDUCTOR MODULE

(71) Applicant: RESEARCH ASSOCIATION FOR ADVANCED SYSTEMS, Tokyo (JP)

(72) Inventors: Masaya Kawano, Tokyo (JP); Tadahiro KURODA, Tokyo (JP)

(21) Appl. No.: 19/219,204

(22) Filed: May 27, 2025

Related U.S. Application Data
(63) Continuation of application No. PCT/JP2023/045466, filed on Dec. 19, 2023.

(30) Foreign Application Priority Data
Dec. 20, 2022 (JP) 2022-203554

(51) Int. Cl. H01L 25/16; H01L 23/00; H01L 23/528; H01L 23/58; H10B 80/00

(52) U.S. Cl. CPC H01L 25/16; H01L 23/5286; H01L 23/585; H01L 24/16; H10B 80/00; H01L 2224/16225

(57) ABSTRACT

A semiconductor module includes a plurality of memory chips in a memory cube are stacked along a first direction parallel to a plane formed by a second direction and a third direction perpendicular to the first direction. The memory cube includes first and third outermost surfaces in the third direction and second and fourth outermost surfaces in the second direction. Each of the memory chips includes a substrate and a wiring layer. The substrate includes first to fourth side surfaces along each of the first to fourth outermost surfaces. A first insulating film is included between the first to fourth outermost surfaces and the corresponding first to fourth side surfaces. Internal wirings included in the wiring layer are connected to electrodes provided on at least one of the second to fourth outermost surfaces. The memory cube is spaced apart from the semiconductor chips and performs signal transmission.

### CROSS-REFERENCE TO RELATED APPLICATIONS

This application is a Continuation of International Patent Application No. PCT/JP2023/045466, filed on Dec. 19, 2023, which claims the benefit of priority to Japanese Patent Application No. 2022-203554, filed on Dec. 20, 2022, the entire contents of which are incorporated herein by reference.

### FIELD

An embodiment of the present invention relates to a semiconductor module.

### BACKGROUND

In recent years, the amount of data communication in an electronic computer such as a data center has increased. In addition, with an increase in the amount of data communication, the power consumption, the memory capacity, and the demand for a reduction in power consumption and an increase in capacity of the electronic computer is increasing. For example, the electronic computer includes a plurality of logic chips and a plurality of memory chips electrically connected to the plurality of logic chips. The logic chip is, for example, an IC (Integrated Circuit) chip mounted with a logic circuit, and a memory chip is a semiconductor chip in which a memory circuit is mounted. Data communication in an electronic computer is performed between a logic chip and a memory chip, for example. For example, a three-dimensional implementation method of a stacked logic chip and a memory chip is one effective solution for reducing power consumption of an electronic computer and increasing the capacity of the memory.

As an example of a three-dimensional implementation method, a semiconductor module including a structure (vertically stacked memory cube) in which a plurality of memory chips are stacked is arranged on a substrate or a logic chip so that the plurality of memory chips is parallel to the substrate or the logic chip, or a semiconductor module including a structure (horizontally stacked memory cube) in which a plurality of memory chips is stacked is placed vertically on a substrate or a logic chip so that the plurality of memory chips is perpendicular to the substrate or the logic chip is known.

Further, as an example of the three-dimensional implementation method, the memory cube and the logic chip are electrically connected using TSV, micro-bumps, flip-chip bonding, or the like. Further, as an example of a three-dimensional implementation method, a technique of forming a wiring on a sidewall of a vertically stacked memory cube is disclosed.

### SUMMARY

A semiconductor module includes a memory cube in which a plurality of memory chips is stacked along a first direction parallel to a plane formed by a second direction perpendicular to the first direction and a third direction perpendicular to the second direction. The memory cube includes a first outermost surface, a third outermost surface opposite the first outermost surface, and a second outermost surface and a fourth outermost surface opposite the second outermost surface, the second outermost surface and the fourth outermost surface being the two outermost surfaces in the second direction. The first outermost surface is arranged on a side on which a semiconductor chip is arranged in the third direction. Each of the plurality of memory chips includes a substrate and a wiring layer stacked on the substrate. The substrate includes a first side surface along the first outermost surface, a second side surface along the second outermost surface, a third side surface along the third outermost surface and a fourth side surface along the fourth outermost surface. A first insulating film is included between the first outermost surface and the first side surface, between the second outermost surface and the second side surface, between the third outermost surface and the third side surface, and between the fourth outermost surface and the fourth side surface. The wiring layer includes an internal wiring. The internal wiring is connected to an electrode provided on at least one of the second outermost surface, the third outermost surface, and the fourth outermost surface, and the memory cube is configured to transmit signals while being spaced apart from the semiconductor chip.

A semiconductor module includes a memory cube in which a plurality of memory chips is stacked along a first direction parallel to a plane formed by a second direction perpendicular to the first direction and a third direction perpendicular to the second direction. The memory cube includes a first substrate, a second substrate, a bottom, and an upper surface opposite to the bottom surface. The first substrate and the second substrate sandwiches the plurality of memory chips in the first direction. The bottom surface is an outermost surface on a side where the semiconductor chips are arranged in the third direction. Each of the first substrate and the second substrate does not include a transistor layer including a transistor. Each of the first substrate and the second substrate does not include a transistor layer including a wiring circuit transistor. Each of the plurality of memory chips includes a substrate, and the transistor layer and a wiring layer stacked on the substrate. The wiring layer includes a first internal wiring, a second internal wiring, and a first inductor. The first internal wiring, the second internal wiring, and the first inductor are arranged apart from each other. The semiconductor module includes the first internal wiring, a first conductive layer in contact with the upper surface and an upper surface of the first substrate along the third direction, a second conductive layer electrically connected to the first conductive layer, and a heat conductive member electrically connected to the second conductive layer.

### BRIEF DESCRIPTION OF DRAWINGS

FIG. 1 is a perspective view showing a configuration of a semiconductor module according to a first embodiment of the present invention.

FIG. 2 is a perspective view showing a configuration of a memory chip according to the first embodiment of the present invention.

FIG. 3 is a cross-sectional view showing a cross-section structure of the memory chip taken along a line A1-A2 shown in FIG. 2.

FIG. 4 is a block diagram showing the configuration of the memory chip according to the first embodiment of the present invention.

FIG. 5A is a cross-sectional view showing a cross-section structure of a memory cube according to the first embodiment of the present invention.

FIG. 5B is a schematic diagram showing a method for manufacturing the memory cube according to the first embodiment of the present invention.

FIG. 6A is a schematic diagram showing a method for manufacturing the memory chip according to the first embodiment of the present invention.

FIG. 6B is a schematic diagram showing the method for manufacturing the memory chip according to the first embodiment of the present invention.

FIG. 7A is a schematic diagram showing a method for manufacturing the memory cube and a rewiring layer (a side power wiring and a side ground wiring) according to the first embodiment of the present invention.

FIG. 7B is a cross-sectional view showing a cross-section structure of the memory cube taken along a line B1-B2 of FIG. 7A.

FIG. 8A is a schematic diagram showing configurations of the memory cube and the rewiring layer (the side power wiring and the side ground wiring) according to the first embodiment of the present invention.

FIG. 8B is a cross-sectional view showing cross-section structures of the memory cube and the rewiring layer taken along a line B1-B2 in FIG. 8A.

FIG. 9A is a schematic diagram showing the method for manufacturing the memory cube and the rewiring layer according to the first embodiment of the present invention.

FIG. 9B is a cross-sectional view of a cross-section structure of the memory cube taken along a line C1-C2 of FIG. 9A.

FIG. 10A is a schematic diagram showing the configurations of the memory cube and the rewiring layer according to the first embodiment of the present disclosure.

FIG. 10B is a cross-sectional view of cross-section structures of the memory cube and the rewiring layer taken along a line C1-C2 in FIG. 10A.

FIG. 11A is a plan view showing configurations of a seal ring and a signal transmission wiring included in the memory chip according to the first embodiment of the present invention.

FIG. 11B is a cross-sectional view showing cross sections of the seal ring and the signal transmission wiring included in the memory chip taken along a line E1-E2 of FIG. 11A.

FIG. 12 is a cross-sectional view showing a mounting example of the semiconductor module according to the first embodiment of the present invention.

FIG. 13 is a cross-sectional view showing a mounting example of a semiconductor module according to a second embodiment of the present invention.

FIG. 14 is a block diagram showing a configuration of the semiconductor module according to the second embodiment of the present invention.

FIG. 15 is a cross-sectional view showing a mounting example of a semiconductor module according to a third embodiment of the present invention.

FIG. 16 is a cross-sectional view showing a mounting example of a semiconductor module according to a fourth embodiment of the present invention.

FIG. 17 is a cross-sectional view showing a mounting example of a semiconductor module according to a fifth embodiment of the present invention.

FIG. 18 is a cross-sectional view showing a mounting example of a semiconductor module according to a sixth embodiment of the present invention.

FIG. 19A is a perspective view showing a conductive film formed on a side surface of a memory cube according to a seventh embodiment of the present invention.

FIG. 19B is a perspective view showing the conductive film formed on the side surface of the memory cube according to the seventh embodiment of the present invention.

FIG. 20A is a perspective view showing a method for manufacturing the conductive film on the side surface of the memory cube according to the seventh embodiment of the present invention.

FIG. 20B is a perspective view showing a method for manufacturing the conductive film on the side surface of the memory cube according to the seventh embodiment of the present invention.

FIG. 21A is a perspective view showing the conductive film formed on the side surface of the memory cube according to the seventh embodiment of the present invention.

FIG. 21B is a schematic diagram showing a configuration of a memory cube according to an eighth embodiment of the present invention.

FIG. 22A is a cross-sectional view showing the cross-section structure of the memory cube according to the first embodiment of the present invention.

FIG. 22B is a cross-sectional view showing the cross-section structure of the memory cube according to the first embodiment of the present invention.

FIG. 23A is a schematic diagram showing the configurations of the memory cube and the rewiring layer (the side power wiring and the side ground wiring) according to the first embodiment of the present invention.

FIG. 23B is a cross-sectional view of the memory cube and the rewiring layer taken along a line B1-B2 in FIG. 23A.

FIG. 24A is a schematic diagram showing the configurations of the memory cube and the rewiring layer (the side power wiring and the side ground wiring) according to the first embodiment of the present invention.

FIG. 24B is a cross-sectional view of cross-section structures of the memory cube and the rewiring layer taken along a line F1-F2 in FIG. 24A.

FIG. 25 is a cross-sectional view showing a mounting example of a semiconductor module according to a ninth embodiment of the present invention.

FIG. 26 is a cross-sectional view showing a mounting example of the semiconductor module according to the ninth embodiment of the present invention.

FIG. 27 is a cross-sectional view showing a mounting example of the semiconductor module according to the ninth embodiment of the present invention.

FIG. 28 is a block diagram showing a configuration of a semiconductor module according to a tenth embodiment of the present invention.

FIG. 29 is a plan view showing a configuration of a seal ring and a signal transmission wiring according to the tenth embodiment of the present invention.

FIG. 30 is a cross-sectional view showing cross sections of the seal ring and the signal transmission wiring taken along a line E3-E4 of FIG. 29.

FIG. 31 is a cross-sectional view showing cross sections of the seal ring and an inductor taken along a line E5-E6 of FIG. 29.

FIG. 32 is a cross-sectional view showing cross sections of the seal ring and the inductor shown in FIG. 29.

FIG. 33 is a plan view showing configurations of the seal ring and the inductor according to the tenth embodiment of the present invention.

FIG. 34 is a cross-sectional view showing a cross section of the inductor taken along a line E7-E8 of FIG. 33.

FIG. 35 is a cross-sectional view showing cross sections of the seal ring and inductor taken along a line E9-E10 of FIG. 33.

FIG. 36 is a cross-sectional view showing a cross section of the inductor taken along a line E11-E12 of FIG. 33.

FIG. 37 is a plan view showing the configurations of the seal ring and the inductor according to the tenth embodiment of the present invention.

FIG. 38 is a cross-sectional view showing cross sections of the seal ring and inductor taken along a line E13-E14 of FIG. 37.

FIG. 39 is a cross-sectional view showing a cross section of the inductor taken along a line E15-E16 of FIG. 37.

FIG. 40 is a cross-sectional view showing a cross section of the inductor taken along a line E17-E18 of FIG. 37.

FIG. 41 is a plan view showing a method for manufacturing an inductor according to an eleventh embodiment and a side view of a semiconductor module taken along a line F1-F2.

FIG. 42 is a plan view showing the method for manufacturing the inductor according to the eleventh embodiment and a cross-sectional view of the semiconductor module taken along a line F3-F4.

FIG. 43 is a plan view showing the method for manufacturing the inductor according to the eleventh embodiment and a side view of the semiconductor module taken along a line F5-F6.

FIG. 44 is a plan view showing the method for manufacturing the inductor according to the eleventh embodiment and a cross-sectional view of the semiconductor module taken along a line F7-F8.

FIG. 45 is a plan view showing the method for manufacturing the inductor according to the eleventh embodiment and a side view of the semiconductor module taken along a line F9-F10.

FIG. 46 is a plan view showing the method for manufacturing the inductor according to the eleventh embodiment and a cross-sectional view of the semiconductor module taken along a line F11-F12.

FIG. 47 is a flowchart showing a method for manufacturing a memory cube according to a twelfth embodiment of the present invention.

FIG. 48 is a plan view showing the method for manufacturing the memory cube according to the twelfth embodiment of the present invention.

FIG. 49 is a plan view showing the method for manufacturing the memory cube according to the twelfth embodiment of the present invention.

FIG. 50 is a plan view showing the method for manufacturing the memory cube according to the twelfth embodiment of the present invention and a cross-sectional view showing a cross section of the memory chip taken along a line G1-G2.

FIG. 51 is a cross-sectional view showing the method for manufacturing the memory cube according to the twelfth embodiment of the present invention.

FIG. 52 is a cross-sectional view showing the method for manufacturing the memory cube according to the twelfth embodiment of the present invention.

FIG. 53 is a cross-sectional view showing the method for manufacturing the memory cube according to the twelfth embodiment of the present invention.

FIG. 54 is a flowchart showing a method for manufacturing a memory cube according to a thirteenth embodiment of the present invention.

FIG. 55 is a cross-sectional view showing the method for manufacturing the memory cube according to the thirteenth embodiment of the present invention.

FIG. 55 is a cross-sectional view showing the method for manufacturing the memory cube according to the thirteenth embodiment of the present invention.

FIG. 56 is a cross-sectional view showing the method for manufacturing the memory cube according to the thirteenth embodiment of the present invention.

FIG. 57 is a flowchart showing a method for manufacturing a memory cube according to a fourteenth embodiment of the present invention.

FIG. 58 is a perspective view showing a method for manufacturing the memory cube according to the fourteenth embodiment of the present invention.

FIG. 59 is a cross-sectional view showing the method for manufacturing the memory cube according to the fourteenth embodiment and a cross-sectional view showing a cross section taken along a line H1-H2.

FIG. 60 is a cross-sectional view showing the method for manufacturing the memory cube according to the fourteenth embodiment of the present invention.

FIG. 61 is flowchart showing a method for manufacturing a memory cube according to a fifteenth embodiment of the present invention.

FIG. 62 is a cross-sectional view and a plan view showing the method for manufacturing the memory cube according to the fifteenth embodiment of the present invention.

FIG. 63 is a plan view showing a marker of a memory chip according to the fifteenth embodiment of the present invention.

FIG. 64 is a cross-sectional view showing the method for manufacturing the memory cube according to the fifteenth embodiment of the present invention.

FIG. 65 is a side view showing a configuration of a memory cube according to a sixteenth embodiment of the present invention.

FIG. 66 is a side view (top view) showing the configuration of the memory cube according to the sixteenth embodiment of the present invention.

FIG. 67 is a side view showing the configuration of the memory cube according to the sixteenth embodiment of the present invention.

FIG. 68 is a cross-sectional view showing a mounting example of a semiconductor module according to the sixteenth embodiment of the present invention.

FIG. 69 is a side view showing a configuration of a memory cube according to a seventeenth embodiment of the present invention.

FIG. 70 is a cross-sectional view showing a mounting example of a semiconductor module according to the seventeenth embodiment of the present invention.

FIG. 71 is a flowchart showing a method for manufacturing a memory cube according to an eighteenth embodiment of the present invention.

FIG. 72 is a plan view showing the method for manufacturing the memory cube according to the eighteenth embodiment of the present invention and a cross-sectional view showing a cross section of the memory chip taken along a line J1-J2.

FIG. 73 is a cross-sectional view showing the method for manufacturing the memory cube according to the eighteenth embodiment of the present invention.

FIG. 74 is a cross-sectional view showing the method for manufacturing the memory cube according to the eighteenth embodiment of the present invention.

FIG. 75 is a cross-sectional view showing the method for manufacturing the memory cube according to the eighteenth embodiment of the present invention.

FIG. 76 is a cross-sectional view showing the method for manufacturing the memory cube according to the eighteenth embodiment of the present invention.

### DESCRIPTION OF EMBODIMENTS

For example, well-known three-dimensional implementation techniques may expose sidewalls (for example, also referred to as sides and end surfaces) of a memory cube. When the sidewalls of the memory cube are exposed, the memory cube may become contaminated with metal or the like, which may cause a defect in electrical characteristics of the memory cube. Further, when the sidewalls of the memory cube are exposed, there is a possibility that a problem arises in insulation between respective memory chips in the memory cube and between respective electrodes even in the same chip.

That is, if the sidewalls of the memory cube are exposed, a problem may arise in long-term reliability of a semiconductor module or the memory cube. Therefore, in the three-dimensional implementation technology, it is a problem to maintain long-term reliability.

In view of such problems, an object of an embodiment of the present invention is to provide a semiconductor module capable of maintaining long-term reliability.

Hereinafter, embodiments of the present invention will be described with reference to the drawings and the like. However, the present invention can be implemented in many different aspects, and should not be construed as being limited to the description of the embodiments exemplified below. Although the drawings may be schematically represented with respect to the width, thickness, shape, and the like of each part as compared with the actual embodiment in order to make the description clearer, the drawings are merely examples, and do not limit the interpretation of the present invention. In addition, in the present specification and the drawings, the same reference signs (or reference signs denoted by a, b, and the like) are given to the same elements as those described above with respect to the previous drawings, and detailed description thereof may be omitted as appropriate. Furthermore, the terms “first” and “second” with respect to the respective elements are convenient signs used to distinguish the respective elements, and do not have any further meaning unless otherwise specified.

In one embodiment of the invention, in the case where a member or region is “above (or below)” another member or region, this includes not only a case where it is directly above (or directly below) the other member or region, unless otherwise limited, but also a case where it is above (or below) the other member or region, that is, a case where another component is included between above (or below) the other member or region.

In an embodiment of the present disclosure, a direction D1 intersects a direction D2, and a direction D3 intersects the direction D1 and the direction D2 (a plane D1D2). For example, the direction D1 is orthogonal to the direction D2 and the direction D3, and the direction D2 is orthogonal to the direction D3. The direction D1 is referred to as a first direction, the direction D2 is referred to as a second direction, and the direction D3 is referred to as a third direction.

In one embodiment of the present invention, in the case where the terms “same” and “coincide” are used, the same and coincide may include errors within the scope of the design. In addition, in an embodiment of the present invention, in the case where an error within the scope of design is included, the expression “substantially the same” and “substantially coincide” may be used in some cases.

### First Embodiment

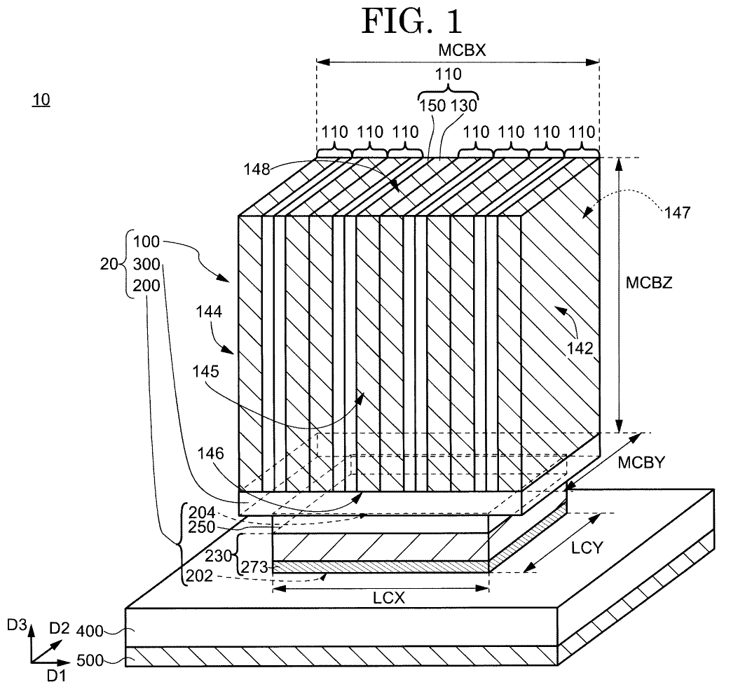

The semiconductor module 10 according to the first embodiment will be described with reference to FIG. 1 to FIG. 12.

### [1-1. Overview of Semiconductor Module 10]

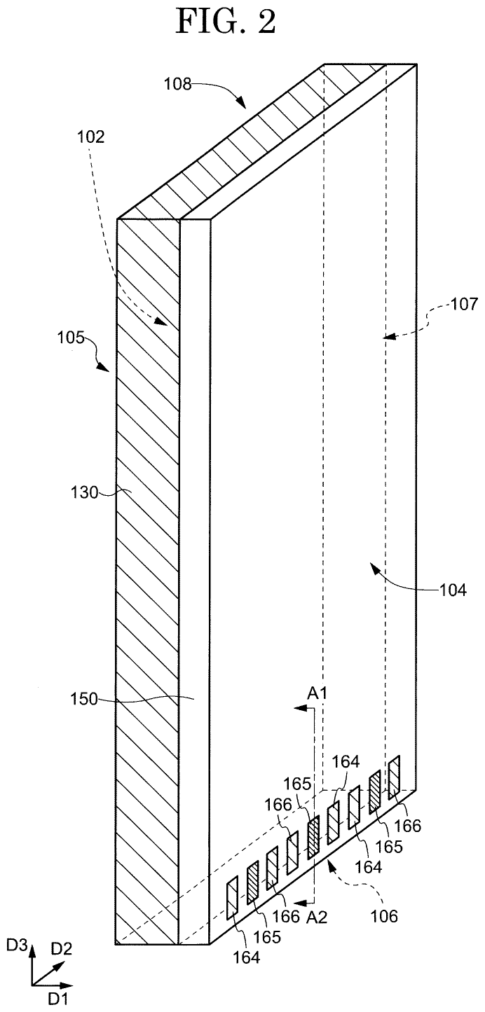

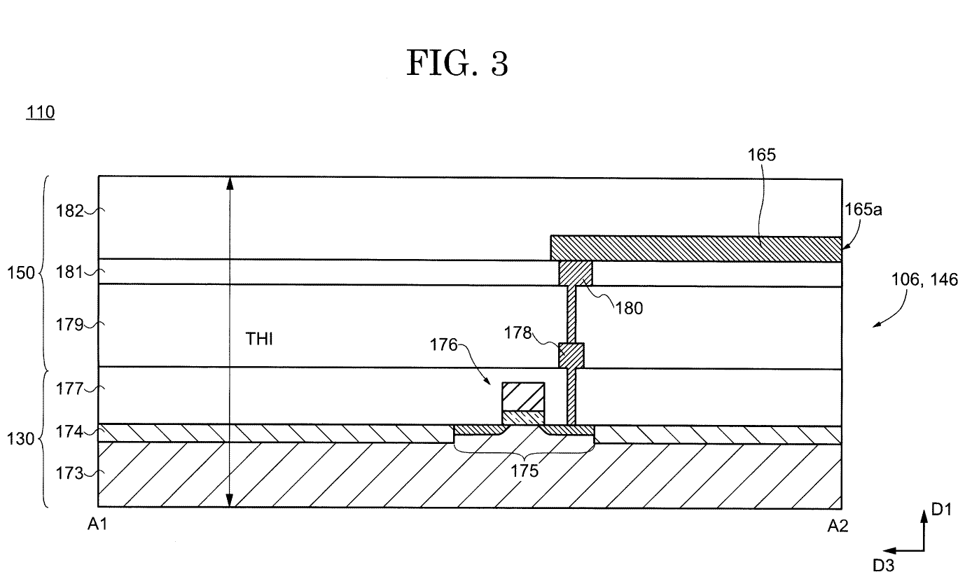

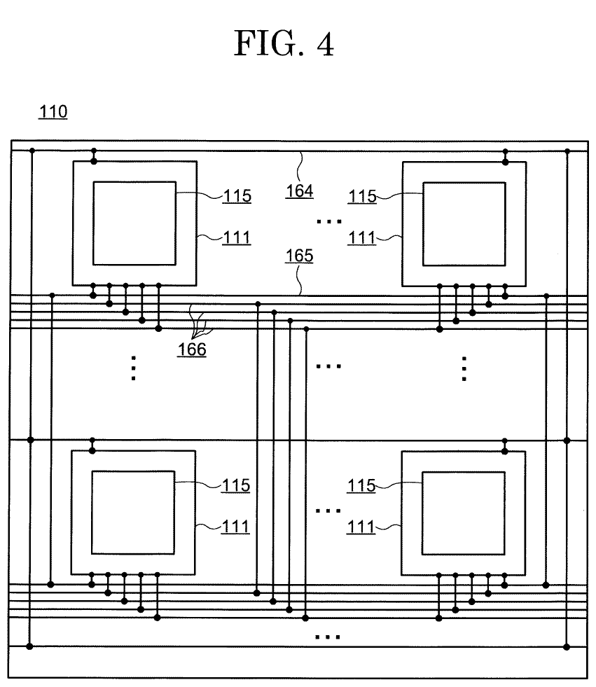

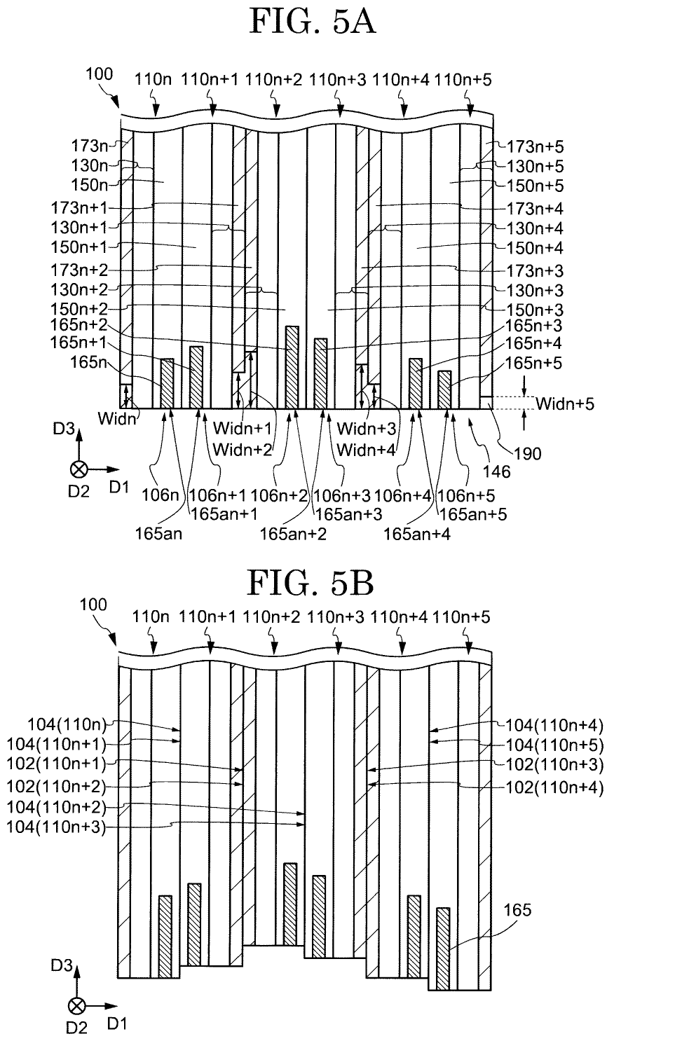

An overview of a semiconductor module 10 will be described referring to FIG. 1 to FIG. 5A. FIG. 1 is a perspective view showing a configuration of the semiconductor module 10. FIG. 2 is a perspective view showing a configuration of a memory chip 110. FIG. 3 is a cross-sectional view of the memory chip 110 taken along a line A1-A2 shown in FIG. 2. FIG. 4 is a block diagram showing the configuration of the memory chip 110. FIG. 5A is a cross-sectional view of a memory cube 100.

First, the configuration of the semiconductor module 10 will be described with reference to FIG. 1. The semiconductor module 10 includes the memory cube 100, a logic chip 200, and a rewiring layer 300. For example, the memory cube 100, the logic chip 200, and the rewiring layer 300 constitute a structure 20. The semiconductor module 10 may include a wiring substrate 400 and a bump layer 500. The logic chip 200 may be referred to as a semiconductor chip. Although details will be described later, the structure 20 may include elements other than the memory cube 100, the logic chip 200, and the rewiring layer 300.

The memory cube 100 includes, for example, a function of storing received data and a function of transmitting stored data. The memory cube 100 includes a configuration in which a plurality of memory chips 110 are stacked. The memory cube 100 includes a first surface 142 parallel to the directions D2 and D3 and a second surface 144 opposite the first surface 142 and parallel to the first surface 142 with respect to the direction D1. The memory cube 100 also includes a first side surface 146 that is perpendicular to the first surface 142 and the second surface 144, a second side surface 145 that is adjacent to the first side surface 146, a third side surface 148 that is adjacent to the second side surface 145, and a fourth side surface 147 that is adjacent to the third side surface 148 and the first side surface 146. The first side surface 146 is in contact with and electrically connected to the rewiring layer 300, and the memory cube 100 is arranged on a second surface 204 of the logic chip 200.

In the memory cube 100, the first side surface 146 is the outermost surface on a side where the logic chip 200 is arranged in the direction D3, and the third side surface 148 is the outermost surface on a side opposite the first side surface 146 in the direction D3. The second side surface 145 and the fourth side surface 147 opposite the second side surface 145 are the two outermost surfaces of the memory cube 100 in the direction D2. Further, the first surface 142 and the second surface 144 opposite the first surface 142 are the two outermost surfaces of the memory cube 100 in the direction D1. The first side surface 146 may be referred to as a bottom surface or a cube bottom surface, the second side surface 145 may be referred to as a second outermost surface or a cube front side surface, the fourth side surface 147 may be referred to as a fourth outermost surface or a cube rear side surface, and the third side surface 148 may be referred to as a third outermost surface or a cube upper surface.

The logic chip 200 includes a function of driving the memory cube 100. The logic chip 200 includes, for example, a first surface 202 and the second surface 204 which are parallel to the direction D1 and the direction D2 intersecting the direction D1, a wiring layer 250, and a transistor layer 230. The first surface 202 is a surface on which the wiring substrate 400 is arranged, and the second surface 204 is a surface on which the rewiring layer 300 is arranged. The wiring layer 250 and the transistor layer 230 are stacked parallel to the first surface 202 and the second surface 204 in the direction D3. In the logic chip 200 according to the present embodiment, a substrate 273 is arranged downward with respect to the direction D3 (toward the first surface 202 side), and the wiring layer 250 is stacked above the substrate 273 with respect to the direction D3. In the semiconductor module 10, for example, the substrate 273 (the first surface 202) of the logic chip 200 is arranged on the wiring substrate 400, and the logic chip 200 is mounted face-up on the wiring substrate 400.

The rewiring layer 300 is arranged between the first side surface 146 of the memory cube 100 and the second side surface 204 of the logic chip 200, and is directly connected to the memory cube 100, and includes a function of electrically connecting the memory cube 100 and the logic chip 200.

Although details will be described later, the wiring substrate 400 includes a multilayer wiring structure in which wirings and insulating layers are alternately stacked, and includes a function of connecting the memory cube 100, the logic chip 200, and the like to an external substrate, an external circuit, and the like. The insulating layer may include a low dielectric constant film that allows moisture absorption. The bump layer 500 has a function of connecting the wiring substrate 400 on which the memory cube 100 and the logic chip 200 are mounted to an external substrate, an external circuit, and the like, as will be described in detail later in the same manner as the wiring substrate 400.

The memory cube 100 has a length MCBX, a length MCBY, and a length MCBZ along the direction D1, the direction D2, and the direction D3. The rewiring layer 300 has the length MCBX and the length MCBY along the directions D1 and D2. A length of the rewiring layer 300 in the direction D3 may be any length. The logic chip 200 has a length LCX and a length LCY along the direction D1 and the direction D2. A length of the logic chip 200 in the direction D3 may be any length. The length MCBX is longer than the length LCX, and the length MCBY is longer than the length LCY. That is, a size of the memory cube 100 is larger than a size of the logic chip 200.

Next, the configuration of the memory chip will be described referring to FIG. 1 to FIG. 5A. As shown in FIG. 1 or FIG. 5A, each of the plurality of memory chips 110 has the same configuration and function, and includes, for example, a transistor layer 130 and a wiring layer 150. Each of the plurality of memory chips 110 includes, for example, a memory chip 110n, a memory chip 110n+1 adjacent to the memory chip 110n, a memory chip 110n+2 adjacent to the memory chip 110n+1, a memory chip 110n+3 adjacent to the memory chip 110n+2, a memory chip 110n+4 adjacent to the memory chip 110n+3, and a memory chip 110n+5 adjacent to the memory chip 110n+4.

In the case where each of the plurality of memory chips 110 is not distinguished, the memory chip is represented as the memory chip 110. In the case where each of the plurality of memory chips 110 is distinguished, the memory chip is represented as the memory chip 110n, the memory chip 110n+1, the memory chip 110n+2, and the like.

As shown in FIG. 2, the memory chip 110 includes a first surface 102 and a second surface 104 that are parallel to the directions D2 and D3. The first surface 102 is a surface on which the transistor layer 130 is arranged, and the second surface 104 is a surface on which the wiring layer 150 is arranged. The first surface 102 and the second surface 104 are parallel to the first surface 142 and the second surface 144.

In addition, the memory chip 110 also includes a first side surface 106 perpendicular to the first side surface 102 and the second side surface 104, a second side surface 105 adjacent to the first side surface 106, a third side surface 108 adjacent to the second side surface 105, and a fourth side surface 107 adjacent to the third side surface 108 and the first side surface 106. The first side surface 106 is part of the first side surface 146, the second side surface 105 is part of the second side surface 145, the third side surface 108 is part of the third side surface 148, and the fourth side surface 107 is part of the fourth side surface 147.

As shown in FIG. 3, the wiring layer 150 is stacked on the transistor layer 130 in the direction D1. The transistor layer 130 includes, for example, portions of a substrate 173, an element isolation region 174, an activation region 175, a transistor 176, an insulating layer 177, and a wiring 178. The substrate 173 is, for example, a Si substrate or a Si-wafer.

The wiring layer 150 includes a multilayer wiring structure in which wirings and insulating layers are alternately stacked. The wiring layer 150 includes, for example, portions of the wiring 178, an insulating layer 179, a wiring 180, an insulating layer 181, an insulating layer 182, and a plurality of ground wirings 165. An end surface 165a of the ground wiring 165 of a part of the plurality of ground wirings 165 is exposed to the first side surface 106 (the first side surface 146 of the memory cube 100) of the memory chip 110, and the end surface 165a is flush with the first side surface 106. A plurality of power wirings 164 (see FIG. 2) and a plurality of signal transmission wirings 166 (see FIG. 2) are arranged in the same layer as the plurality of ground wirings 165. Similar to the plurality of ground wirings 165, part of the plurality of power wirings 164 and part of a plurality of signal transmission wirings 166 are exposed to the first side surface 106 of the memory chip 110, and each end surface is flush with the first side surface 106. That is, inner wirings (the ground wiring 165, the power wiring 164, and the signal transmission wiring 166) of the memory chip 110 extend in the direction D3 and are exposed to the first side surface 146 of the memory cube 100, and the first side surface 146 is flattened.

The number of layers of the multilayer wiring in the wiring layer 150 is not limited to three layers shown in FIG. 3. The number of layers of the multilayer wiring in the wiring layer 150 may be four or more. The number of layers of the multilayer wiring in the wiring layer 150 can be appropriately changed according to the specifications, applications, and the like of the semiconductor module 10.

In addition, the logic chip 200 includes a configuration and a function similar to those of the stacked structure shown in FIG. 3. Therefore, although detailed explanation is omitted, for example, the substrate 273 is a Si substrate or a Si-wafer, similar to the substrate 173. The wiring layer 250 includes a multilayer wiring structure in which wirings and insulating layers are alternately stacked in the same manner as the wiring layer 150. Further, the logic chip 200 includes a plurality of transistors formed in the same manner as the transistor 176, and includes a plurality of logic circuits formed using the plurality of transistors or the like, and can drive the memory cube 100 using the plurality of logic circuits.

As shown in FIG. 4, the memory chip 110 includes a plurality of memory modules 111. Each of the plurality of memory modules 111 includes a memory cell array 115.

Each of the plurality of memory modules 111 includes a function of storing data included in the received signal in the memory cell array 115, a function of reading data from the memory cell array 115, and a function of transmitting a signal including data. The plurality of memory modules 111 is electrically connected to the plurality of power wirings 164, the plurality of ground wirings 165, and the plurality of signal transmission wirings 166.

Although explained in detail later, the plurality of power wirings 164 and the plurality of ground wirings 165 are electrically connected to, for example, the logic chip 200 and an external circuit (not shown), and a power supply voltage VDD, a voltage VSS, and the like are supplied from the external circuit. The power supply voltage VDD is, for example, 3 V or 5 V. The voltage VSS is, for example, a ground voltage of 0 V or the like. Further, the plurality of signal transmission wirings 166 is electrically connected to, for example, the logic chip 200 and an external circuit (not shown), and an address signal, an enable signal, and the like for controlling the memory chip 110 are supplied from the logic chip 200 and the external circuit.

The memory cell array 115 includes a plurality of memory cells (not shown). Each of the plurality of memory cell arrays 115 is, for example, a SRAM (Static Random Access Memory), and each of the plurality of memory cells is a SRAM cell. In addition, SRAM, SRAM cell, and the memory module 111 for SRAM can employ a technique used in the technical field of SRAM. Therefore, detailed description will be omitted here. In addition, the plurality of memory cell arrays 115 and the plurality of memory cells may be memory cell arrays and memory cells other than SRAM, and may be, for example, DRAM (Dynamic Random Access Memory) and DRAM cells, MRAM (Magnetoresistive Random Access Memory) and MRAM cells, or the like.

### 1-2. Example of Manufacturing Method of Memory Cube 100

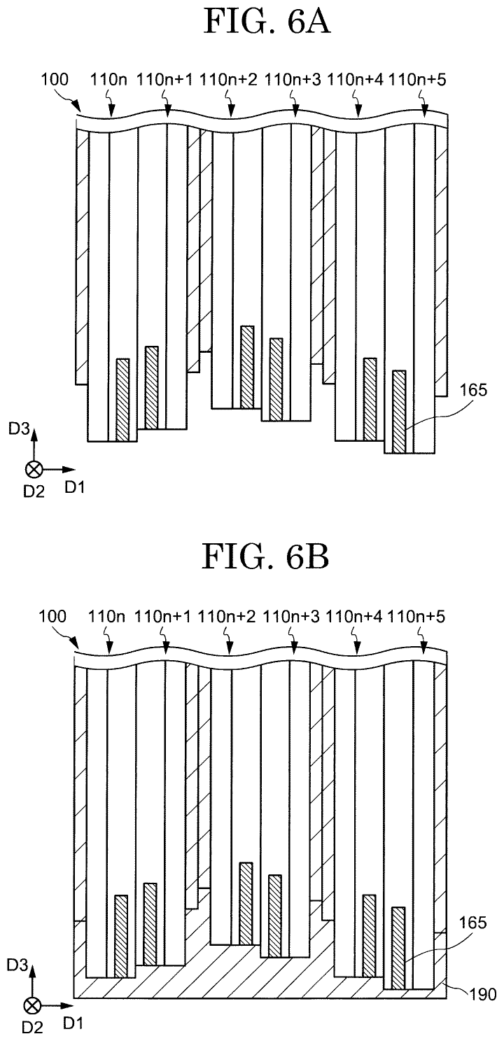

An example of a method for manufacturing the memory cube 100 will be mainly described referring to FIG. 5A to FIG. 10B. FIG. 5A is a cross-sectional view of the memory cube 100, and FIG. 5B to FIG. 6B are schematic views showing the method for manufacturing the memory cube 100. The same or similar configurations as those in FIG. 1 to FIG. 4 will not be described here.

Stacking (bonding) memory chips 110 so as to face the second surfaces 104 facing each other on the wiring layers 150 is referred to as, for example, F2F bonding (Face to Face Fusion). Stacking (bonding) memory chips 110 such that the first surfaces 102 of the transistor layers 130 are opposite each other on the substrate 173 side, is referred to as, for example, B2B bonding (Back to Back Fusion). Stacking (bonding) memory chips 110 so that the second surface 104 on the wiring layer 150 side faces the first surface 102 on the substrate 173 side included in the transistor layer 130 is referred to as, for example, F2B bonding (Face to Back Fusion). For example, a technique such as welding (Fusion Bonding) or silicon direct bonding (Silicon Direct Bonding (SDB)) can be used for stacking (bonding) the memory chips. Since welding and silicon direct bonding are techniques used in the art, detailed description is omitted here.

As shown in FIG. 5A, the memory cube 100 includes, for example, a structure in which the memory chips 110n to 110n+5 are stacked. For the sake of clarity, in the memory chip 110, the transistor layer 130 including the substrate 173 and the wiring layer 150 including the ground wiring 165 are shown, and illustration of other components is omitted.

The memory chip 110n includes a transistor layer 130n including a substrate 173n and a wiring layer 150n including a ground wiring 165n. Similar to the memory chip 110n, the memory chip 110n+1 includes a transistor layer 130n+1 including the substrate 173n+1 and the wiring layer 150n+1 including the ground wiring 165n+1. As with the memory chip 110n and the memory chip 110n+1, the transistor layer 130 including the substrate 173 and the wiring layer 150 including the ground wiring 165 corresponding to each of the memory chips 110n+2 to 110n+5 are labeled with the subscripts n+2 to n+5 of the memory chips 110.

Next, a configuration of the memory chip 110 in a cross-sectional view shown in FIG. 5A will be described. In the memory chip 110n, the ground wiring 165n is exposed to a first side surface 106n, and an end surface 165an of the ground wiring 165n coincides with the first side surface 106n. In addition, a length between an end surface of the substrate 173n and the first side surface 106n is a length Widn, a space between the end surface of the substrate 173n and the first side surface 106n is filled with an insulating film 190, and an end surface of the insulating film 190 coincides with an exposed wiring surface of the first side surface 106n. In addition, the insulating film 190 may cover side surfaces of an insulating layer on the first side surface 106n. Although details will be described later, it is important to cover the insulating layer with an insulating film 190 that prevents moisture absorption from side surfaces thereof, particularly in the case where the insulating layer includes a low dielectric constant film. In this case, SiO₂, SIN, SiON, SICN, a composite film thereof, or the like can be used as the insulating film. The first surface 142 and the second surface 144 of the memory cube 100 may be covered. The insulating film 190 may be referred to as a first insulating film. In the memory chip 110 (the memory cube 100), the end surface of the substrate 173 is the outermost surface on which the logic chip 200 is arranged in the direction D3. The end surface of the substrate 173 may be referred to as a substrate bottom surface.

Similar to the memory chip 110n, in the memory chip 165n+1, the ground wiring 165n+1 is exposed to a first side surface 106n+1, and an end surface 165an +1 of the ground wiring 165n+1 coincides with the first side surface 106n+1. Further, a length from the end surface of the substrate 173n+1 to the first side surface 106n+1 is a length Widn+1, the insulating film 190 is filled between the end surface of the substrate 173n+1 and the first side surface 106n+1, and the end surface of the insulating film 190 coincides with the first side surface 106n+1.

In the memory chip 110n+2, a length from an end surface of a substrate 173n+2 to the first side surface 106n+2 is a length Widn+2. In the memory chip 110n+3, a length from an end surface of a substrate 173n+3 to a first side surface 106n+3 is a length Widn+3. In the memory chip 110n+4, a length from an end surface of a substrate 173n+4 to a first side surface 106n+4 is a length Widn+4. In the memory chip 110n+5, a length from an end surface of a substrate 173n+5 to a first side surface 106n+5 is a length Widn+5. The other configurations of the memory chips 110n+2 to 110n+5 are the same as those of the memory chip 110n and the memory chip 110n+1, and detailed explanation thereof is omitted here.

Although not shown, similar to ground wirings 165n to 165n+5 included in the memory chips 110n to 110n+5, each of the power wirings and the signal transmission wirings is exposed to the first side surfaces 106n to 106n+5, and end surfaces of the power wirings and the signal transmission wirings coincide with the first side surfaces 106n to 106n+5. In addition, the memory chips 110n to 110n+5 include the plurality of ground wirings 165, the plurality of power wirings 164 and the plurality of signal transmission wirings 166, part of the ground wiring 165 of the plurality of ground wirings 165, part of the power wiring 164 of the plurality of power wirings 164, and part of the signal transmission wiring 166 of the plurality of signal transmission wirings 166 are exposed to the first side surface 106n to 106n+5.

In the memory cube 100, the first side surface 146 is polished and planarized, as described in detail below. That is, the first side surface 146 coincides with the first side surfaces 106n to 106n+5 of each of the memory chips 110n to 110n+5. Further, although details will be described later, in the memory cube 100, a length of each memory chip 110 from the end surface of the substrate 173 to the first side surface 106 is different. That is, the lengths Widn to Widn+5 differ in length.

Next, the method for manufacturing the memory cube 100 will be described. Step 1 of the method for manufacturing the memory cube 100 is shown in FIG. 5B. In step 1, the second surface 104 of the memory chip 110n and the second surface 104 of the memory chip 110n+1 are stacked (bonded) so as to face each other, the second surface 104 of the memory chip 110n+2 and the second surface 104 of the memory chip 110n+3 are stacked (bonded) so as to face each other, and the second surface 104 of the memory chip 110n+4 and the second surface 104 of the memory chip 110n+5 are stacked (bonded) so as to face each other. That is, in step 1, the two memory chips 110n and 110n+1, the two memory chips 110n+2 and 110n+3, and the two memory chips 110n+4 and 110n+5 are bonded by the F2F bonding.

Further, in step 1, the memory chip 110n and the memory chip 110n+1 which are F2F bonded to each other are bonded to the memory chip 110n+2 and the memory chip 110n+3 which are F2F bonded to each other, and the memory chip 110n+2 and the memory chip 110n+3 which are F2F bonded to each other are bonded to the memory chip 110n+4 and the memory chip 110n+5 which are F2F bonded to each other.

For example, the memory chip 110n and the first surface 102 of the memory chip 110n+1 on a side of the memory chip 110n are bonded to the memory chip 110n+2 and the first surface 102 of the memory chip 110n+3 on a side of the memory chip 110n+2. That is, the four memory chips 110n to 110n+3 are B2B bonded. Further, although not shown, a memory chip 110n+6 and a first surface 102 of a memory chip 110n+7 on a side of the memory chip 110n+6 are bonded to the memory chip 110n+4 and the first surface 102 of the memory chip 110n+5 on a side of the memory chip 110n+4. That is, the four memory chips 110n+4 to 110n+7 are B2B bonded. The four B2B bonded memory chips 110n to 110n+3 are B2B bonded to the four memory chips 110n+4 to 110n+7.

For example, memory chips 110n to 110n+63 may be stacked (bonded) to form the memory cube 100 in which the 64-layer memory chips 110 are stacked. The number of stacked memory chips 110 is not limited to 64 layers, and may be 128 layers or 256 layers. Further, the method for stacking the memory chips 110 is not limited to the method described in the present embodiment. F2B bonding may be repeated as the method for stacking the memory chips 110. The number of stacked memory chips 110 and the method of stacking can be appropriately selected based on the specifications, applications, and the like of the semiconductor module 10 without departing from the scope of the present invention.

As shown in FIG. 5B, in a state where the plurality of memory chips 110n to 110n+5 is stacked in step 1, a step-like step occurs at a joint surface between the memory chips. That is, in a state where the plurality of memory chips 110n to 110n+5 is stacked in step 1, the first side surfaces 106n to 106n+5 of the respective memory chips are not in the same plane.

Next, in step 2, the substrate 173 is selectively etched by anisotropic dry etching (see FIG. 6A). Since the first side surfaces 106n to 106n+5 of each memory chip are not flush with each other, a step-like step occurs at the joint surface between the substrates 173n to 173n+5 of each memory chip.

Next, in step 3, the insulating film 190 is provided in a step-like step at the joint surface between the memory chips and in a step-like step at the joint surface between the substrates 173n to 173n+5 of the memory chips (see FIG. 6B). Since the insulating film 190 is embedded in the step-like step at the joint surface between the memory chips and the step-like step at the joint surface between the substrates 173n to 173n+5 of the memory chips, the step-like step is relaxed on the surface of the memory cube 100 provided with the insulating film 190.

Next, in step 4, a surface of the memory cube 100 is polished and the first side surface 146 of the memory cube 100 is planarized (see FIG. 5A). Consequently, as shown in FIG. 5A, for example, the end surface 165a of the ground wiring 165 is exposed to the first side surface 146. Polishing can be performed using, for example, a chemical mechanical polishing (Chemical Mechanical Polishing (CMP)) device.

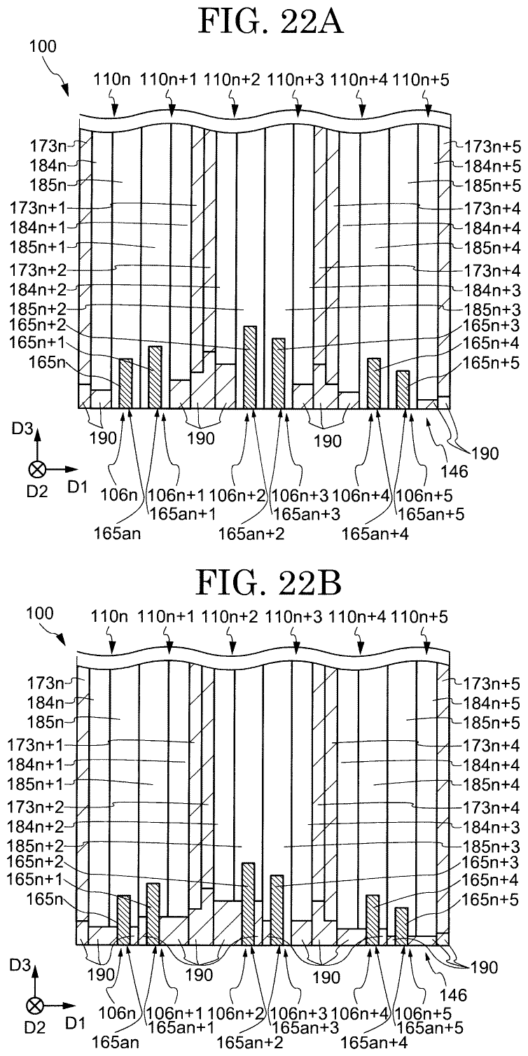

Here, a case in which the insulating layer in the semiconductor module 10 includes a low dielectric constant film will be described with reference to FIG. 22A and FIG. 22B. FIG. 22A and FIG. 22B are cross-sectional views showing a cross section configuration of the memory cube 100. In the semiconductor module 10, the insulating layer (the element isolation region 174) and the insulating layer 177 are sometimes referred to as insulating layers 184. Insulating layers 184 (184n, 184n+1, 184n+2, 184n+3, and 184n+4) are formed using, for example, a low dielectric constant film having a dielectric constant lower than that of the insulating film 190. In this case, after FIG. 6A, the insulating layers 184n to 184n+4 are selectively etched. Further, the insulating film 190 is provided in the step-like step at the joint surface between the memory chips and in the step-like step at the joint surface between the substrates 173n to 173n+5 of the memory chips. Subsequently, the surface of the memory cube 100 is polished, and the first side surface 146 of the memory cube 100 is planarized (see FIG. 22A).

In addition, in the semiconductor module 10, the insulating layer 179, the insulating layer 181, and the insulating layer 182 may be referred to as insulating layers 185. The insulating layers 185 (185n, 185n+1, 185n+2, 185n+3, and 185n+4) are formed using, for example, a low dielectric constant film having a dielectric constant lower than that of the insulating film 190. In the case where the insulating layers 184 to 184n+4 and the insulating layers 185n to 185n+4 are formed using a low dielectric constant film, the insulating layers 184 and the insulating layers 185 are selectively etched after FIG. 6A. Further, the insulating film 190 is provided in the step-like step at the joint surface between the memory chips and in the step-like step at the joint surface between the substrates 173n to 173n+5 of the memory chips. Subsequently, the surface of the memory cube 100 is polished, and the first side surface 146 of the memory cube 100 is planarized (see FIG. 22B).

In FIG. 5A to FIG. 6B, a method for manufacturing the first side 146 of the memory cube 100 is shown. Similar to the first side surface 146 of the memory cube 100, the second side surface 145, the third side surface 148, and the fourth side surface 147 of the memory cube 100 are planarized by steps 1 to 4, and the end surface 165a of the ground wiring 165, an end surface of the power wiring 164, or an end surface of the signal transmission wiring 166 is exposed to the respective side surfaces. Although an example is shown in which the method for manufacturing the memory cube 100 includes steps 1 to 4, the method for manufacturing the memory cube 100 is not limited to steps 1 to 4. For example, if the first side surface 146, the second side surface 145, the third side surface 148, and the fourth side surface 147 of the memory cube 100 are flattened using the same steps as those of step 1 to step 4, and the end surface of the ground wiring 165, the end surface of the power wiring 164, or the end surface of the signal transmission wiring 166 is exposed to each side surface, there is no restriction on the method for manufacturing the memory cube 100.

The memory cube 100 can be manufactured as described above. In the semiconductor module 10, capacity of the memory cube 100 can be increased by stacking the plurality of memory chips 110.

In the method for manufacturing the memory cube 100, the substrate 173 is etched, and the step-like step at the joint surface between the memory chips and the step-like step at the joint surface between the substrates of the memory chips can be filled with the insulating film 190. As a result, since the first side surface 146, the second side surface 145, the third side surface 148, and the fourth side surface 147 of the memory cube 100 are covered with the insulating film 190, it is possible to prevent the first side surface 106 of the substrate 173 from being contaminated by metal, and prevent corrosion and deterioration of each device in the memory cube 100 due to moisture absorption and intrusion of impurities. Therefore, in the semiconductor module 10, contamination from the side surface of the memory cube 100 is suppressed, and reliability can be maintained without impairing long-term reliability of the semiconductor module 10.

In addition, in the method for manufacturing the memory cube 100, since the first side surface 146, the second side surface 145, the third side surface 148, and the fourth side surface 147 of the memory cube 100 are covered with the insulating film 190, for example, it is possible to suppress short circuits between adjacent electrodes and memory chips caused by metal contamination of the first side surface 146, the second side surface 145, the third side surface 148, and the fourth side surface 147. Therefore, in the semiconductor module 10, it is possible to ensure insulation between adjacent electrodes and memory chips, and it is possible to maintain the reliability without impairing the long-term reliability of the semiconductor module 10.

Further, in the method for manufacturing the memory cube 100, for example, by polishing the first side surface 146, the second side surface 145, the third side surface 148, and the fourth side surface 147, the ground wiring 165, the power wiring 164, or the signal transmission wiring 166 can be exposed on the first side surface 146, the second side surface 145, the third side surface 148, and the fourth side surface 147 in a self-aligned manner. Therefore, in the method for manufacturing the memory cube 100, a side surface wiring can be formed on the wiring exposed on the side surface by a simple process, rather than the manufacturing method of forming each wiring using a complicated process while aligning. In addition, in the method for manufacturing the memory cube 100, since the side surface wiring can be formed on the exposed wiring, the exposed wiring is capped with the side surface wiring to prevent oxidation of the exposed wiring, and the side surface wiring can be formed on the side surface of the memory cube 100, so that corrosion, deterioration, and the like of each device in the memory cube 100 caused by moisture absorption, impurities, and the like can be suppressed. That is, the reliability can be maintained without impairing the long-term reliability of the semiconductor module 10.

In addition, since the method for manufacturing the memory cube 100 can form the side surface wiring on the side surface of the memory cube 100, it is possible to expand choices of electrical connection between the memory cube 100 and various sizes of logic chips, wiring substrates, external circuits, and the like. That is, the method for manufacturing the memory cube 100 can improve degree of freedom in design.

In addition, in the method for manufacturing the memory cube 100, the first side surface 146, the second side surface 145, the third side surface 148, and the fourth side surface 147 of the memory cube 100 can be made flat by using the insulating film 190. Therefore, in the method for manufacturing the memory cube 100, it is possible to allow positional deviation immediately after stacking of the plurality of memory chips 110, and it is possible to insulate the memory chips 110 adjacent to each other by using the insulating film 190. Therefore, in the semiconductor module 10, it is possible to ensure insulation between adjacent electrodes and memory chips, and it is possible to maintain the reliability without impairing the long-term reliability of the semiconductor module 10. In addition, since each side surface of the memory cube 100 is flattened, irregularities on the memory cube 100 are relaxed, for example, effective heat conduction from the memory cube 100 to the logic chip 200, the wiring substrate 400, and the like can be improved.

Further, in the method for manufacturing the memory cube 100, a length between the first side surface 106 of the memory chip 110 and the end surface of the insulating film 190 is different for each memory chip. Therefore, since a difference in contrast between adjacent memory chips can be easily recognized, for example, in the side formation of the side surface wiring after step 4, each layer of the plurality of memory chips 110 can be easily recognized.

### 1-3. Example of Method for Manufacturing Rewiring Layer 300

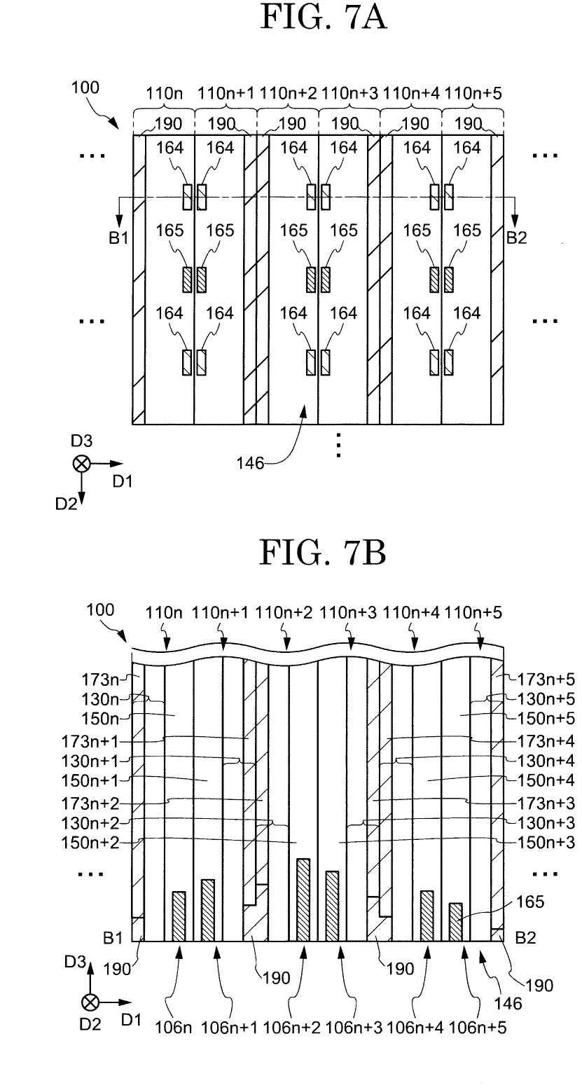

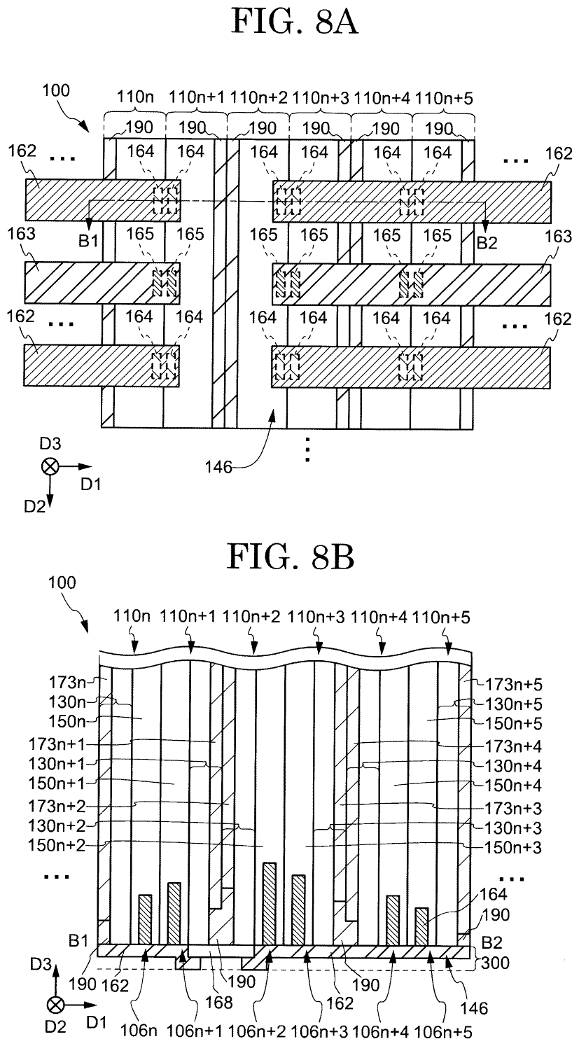

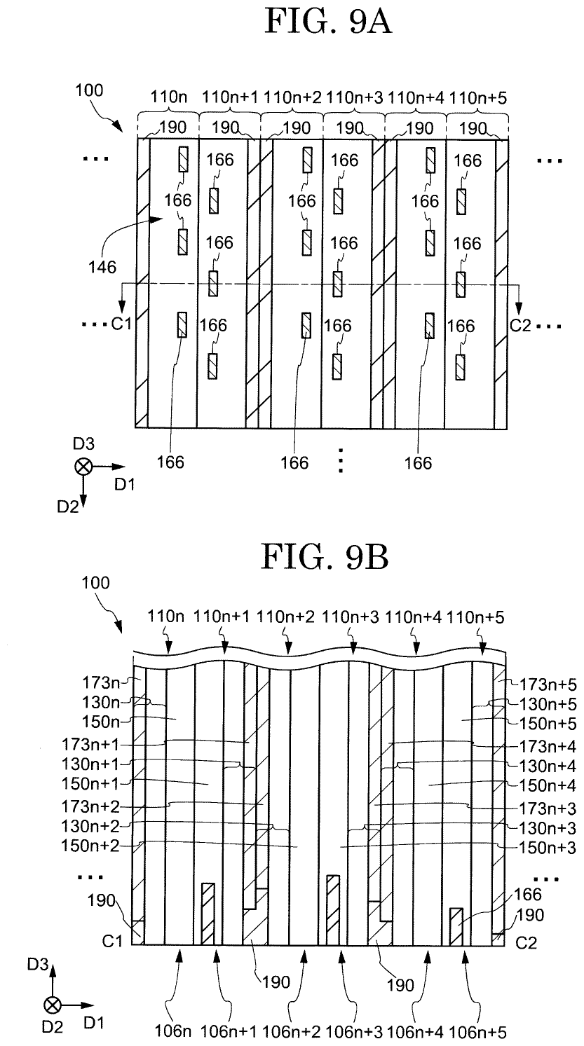

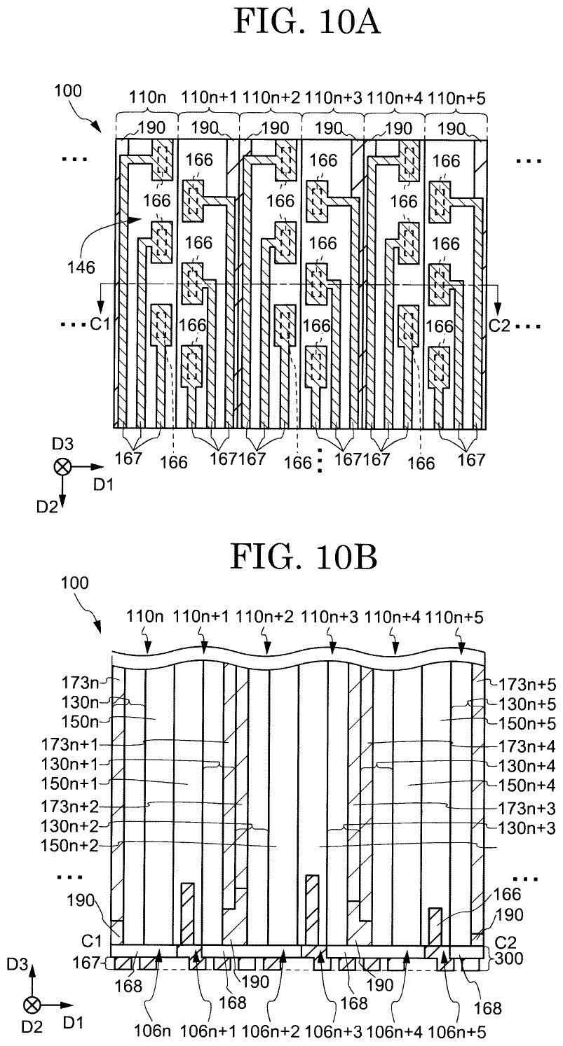

An example of a method for manufacturing the rewiring layer 300 will be mainly described referring to FIG. 7A to FIG. 10B. FIG. 7A is a schematic diagram showing a method for manufacturing the memory cube 100 and the rewiring layer 300 (a side power wiring 162 and a side ground wiring 163), and FIG. 7B is a cross-sectional view of the memory cube 100 taken along a line B1-B2 in FIG. 7A. Further, FIG. 7A and FIG. 7B are schematic diagrams showing a state similar to the state of FIG. 5A described in “1-2. Example of Manufacturing Method of Memory Cube 100”. Further, FIG. 7A is an enlarged view of the first side surface 146 of the memory cube 100 as viewed from the direction D3. FIG. 8A is a schematic diagram showing the configuration of the memory cube 100 and the rewiring layer 300 (the side power wiring 162 and the side ground wiring 163), and FIG. 8B is a cross-sectional view showing cross section configurations of the memory cube 100 and the rewiring layer 300 taken along a line B1-B2 of FIG. 8A. FIG. 9A is a schematic diagram showing the method for manufacturing the memory cube 100 and the rewiring layer 300 (a side signal transmission wiring 167), and FIG. 9B is a cross-sectional view of the memory cube 100 taken along a line C1-C2 of FIG. 9A. Further, FIG. 9A and FIG. 9B are schematic diagrams showing a state similar to the state of FIG. 5A described in “1-2. Example of Manufacturing Method of Memory Cube 100”. FIG. 9A is an enlarged view of the first side surface 146 of the memory 100 as viewed from the direction D3. FIG. 10A is a schematic diagram showing the configurations of the memory cube 100 and the rewiring layer 300 (the side signal transmission wiring 167), and FIG. 10B is a cross-sectional view showing the cross section structure of the memory cube 100 taken along a line C1-C2 of FIG. 10A. The same or similar configurations as those in FIG. 1 to FIG. 6B will not be described here.

First, referring to FIG. 7A and FIG. 8B, a method for forming the plurality of side power wirings 162 and the plurality of side surface ground wirings 163 included in the rewiring layers 300 will be described.

As shown in FIG. 7A, the insulating film 190, the plurality of power wirings 164, and the plurality of ground wirings 165 included in the plurality of memory chips 110n to 110n+5 are exposed to the first side surface 146 of the memory cube 100. As described above, FIG. 7B is a schematic diagram showing a state similar to the state of FIG. 5A described in “1-2. Example of Manufacturing Method of Memory Cube 100” (that is, a state in which the manufacturing method of step 4 is shown), and is a diagram in which the ground wiring 165 in FIG. 5A is replaced with the power wiring 164. Since other configurations are the same as those in FIG. 5A, detailed explanation is omitted here.

The method for manufacturing the rewiring layers 300 is shown in FIG. 8A and FIG. 8B. For the sake of clarity, an insulating film 168 is not shown in FIG. 8A. For example, in the manufacturing method of the rewiring layer 300, step 4 of the manufacturing method of the memory cube 100 is followed by step 5. In step 5, for example, the insulating film 168 is formed so that the insulating film 168 remains between the two side power wirings 162 and between the two ground wirings 165. For example, as shown in FIG. 8B, the insulating film 168 is formed on a part of the first side surfaces 106n+1 and 106n+2 of the memory chips 110n+1 and 110n+2 located between the two side power wirings 162 and between the two ground wirings 165.

In step 6, the side power wirings 162 are formed on the plurality of power wirings 164, and the side ground wirings 163 are formed on the plurality of ground wirings 165 as shown in FIG. 8A and FIG. 8B. For example, the side power wiring 162 is arranged so as to be in contact with portions of a side surface and an upper surface of the insulating film 168, the four power wirings 164 exposed to the first side surfaces 106n+2 to 106n+5 of the memory chips 110n+2 to 110n+5, and the first side surfaces 106n+2 to 106n+5 of the memory chips 110n+2 to 110n+5. Further, another side power wiring 162 is arranged so as to be in contact with portions of the side surface and the upper surface of the insulating film 168, the two power wirings 164 exposed to the first side surfaces 106n to 106n+1 of the memory chips 110n to 110n+1, and the first side surfaces 106n to 106n+1 of the memory chips 110n to 110n+1.

Further, for example, similar to the side power wiring 162, the side ground wiring 163 is arranged so as to be in contact with a part of the side surface and the upper surface of the insulating film 168, the four ground wirings 165 exposed to the first side surfaces 106n+2 to 106n+5 of the memory chips 110n+2 to 110n+5, and the first side surfaces 106n+2 to 106n+5 of the memory chips 110n+2 to 110n+5. Further, for example, similar to the other side power wiring 162, the side ground wiring 163 is arranged so as to be in contact with portions of the side surface and the upper surface of the insulating film 168, the two ground wirings 165 exposed to the first side surfaces 106n to 106n+1 of the memory chips 110n to 110n+1, and the first side surfaces 106n to 106n+1 of the memory chips 110n to 110n+1. That is, the memory chips that are F2F bonded to each other are electrically connected to each other by the same side power wiring 162 and the same side ground wiring 163.

The side power wirings 162 and the side ground wirings 163 extend in the direction D1, for example, and are alternately arranged along the direction D2 in parallel to the direction D1.

Next, referring to FIG. 9A to FIG. 10B, a method for forming a plurality of side signal transmission wirings 167 included in the rewiring layers 300 will be described. The method for forming the plurality of side signal transmission wirings 167 explained with reference to FIG. 9A to FIG. 10B is similar to the method for forming the plurality of side power wirings 162 and the plurality of side ground wirings 163 explained with reference to FIG. 7A to FIG. 8B, in which the configuration of the plurality of side power wirings 162 and the plurality of side ground wirings 163 are replaced with the configuration of the side signal transmission wirings 167. Therefore, in the method for forming the plurality of side signal transmission wirings 167 explained referring to FIG. 9A to FIG. 10B, the configurations of the plurality of side grounded wirings 163 differing from those described with reference to FIG. 7A to FIG. 8B will be mainly described.

The plurality of memory chips 110n to 110n+5 shown in FIG. 9A to FIG. 10B are enlarged views of regions of the first side surfaces 146 of the plurality of memory chips 110n to 110n+5 that differ from the plurality of memory chips 110n to 110n+5 shown in FIG. 7A to FIG. 8B.

The plurality of side surface signal transmission wirings 167 included in the rewiring layer 300 is formed in steps 5 and 6 in the same manner as the plurality of side power wirings 162 and the plurality of side ground wirings 163 included in the rewiring layer 300.

As shown in FIG. 9A, the insulating film 190 and the plurality of signal transmission wirings 166 included in the plurality of memory chips 110n to 110n+5 are exposed on the first side surface 146 of the memory cube 100. For the sake of clarity, the insulating film 168 is not shown in FIG. 9A. The plurality of signal transmission wirings 166 are arranged in a staggered manner. For example, the plurality of signal transmission wirings 166 exposed on the first side surfaces 106n and 106n+1 of the memory chips 110n and 110n+1 are arranged in a staggered manner, the plurality of signal transmission wirings 166 exposed on the first side surfaces 106n+2 and 106n+3 of the memory chips 110n+2 and 110n+3 are arranged in a staggered manner, and the plurality of signal transmission wirings 166 exposed on the first side surfaces 106n+4 and 106n+5 of the memory chips 110n+4 and 110n+5 are arranged in a staggered manner. Also, in the case where the plurality of signal transmission wirings 166 exposed on the first side surface 146 are viewed from the direction D3, the plurality of signal transmission wirings 166 are arranged in a staggered manner.

Therefore, as shown in FIG. 9B, in the cross-sectional view taken along a line C1-C2, the plurality of signal transmission wirings 166 are exposed on the first side surfaces (106n+1, 106n+3, and 106n+5) of the memory chips 110n+1, 110n+3, and 110n+5.

In step 5, for example, the insulating film 168 is formed so that the insulating film 168 remains between the two side surface signal transmission wirings 167. For example, as shown in FIG. 10B, the insulating film 168 is formed between the two side signal transmission wirings 167 on part of the first side surfaces 106n+1 to 106n+3 of the memory chips 110n+1 to 110n+3 and part of the first side surfaces 106n+3 to 106n+5 of the memory chips 110n+3 to 110n+5.

In step 6, as shown in FIG. 10A and FIG. 10B, the plurality of side signal transmission wirings 167 is formed on each of the plurality of signal transmission wirings 166. For example, the side signal transmission wiring 167 is provided so as to be in contact with portions of the side surface and the upper surface of the insulating film 168 and the signal transmission wiring 166 exposed on the first side surface 106n+1 of the memory chip 110n+1. Similar to the signal transmission wiring 166 exposed on the first side surface 106n+1 of the memory chip 110n+1, the signal transmission wirings 166 exposed on the first side surfaces 106n+1 to 106n+3 of the memory chips 110n, 110n+2 to 110n+5 are in contact with the side signal transmission wirings 167 corresponding to the respective signal transmission wirings 166.

Each of the plurality of side signal transmission wirings 167 is provided so as to cover, for example, the signal transmission wiring 166, and extends parallel to the direction D1, and then extends parallel to the direction D2.

The insulating film 168, the plurality of side power wirings 162, the plurality of side ground wirings 163, and the plurality of side signal transmission wirings 167 are formed, for example, by photolithography.

As described above, the plurality of power wirings 164, the plurality of ground wirings 165, and the plurality of signal transmission wirings 166 exposed in the memory cube 100 are electrically connected to the side power wirings 162, the plurality of side ground wirings 163, and the plurality of side signal transmission wirings 167 included in the rewiring layer 300. As a result, the memory cube 100 is electrically connected to the rewiring layer 300.

In addition, although an example is shown in which the method for manufacturing the memory cube 100 and the rewiring layer 300 includes steps 1 to 6, the method for manufacturing the memory cube 100 and the rewiring layer 300 is not limited to steps 1 to 6. For example, if the method in which the memory cube 100 and the rewiring layer 300 are formed using the same steps as steps 1 to 6, there is no restriction on the method for manufacturing the memory cube 100 and the rewiring layer 300.

In the method for manufacturing the memory cube 100 and the rewiring layer 300, wiring can be formed on a side surface by a simpler process than a manufacturing method for forming each wiring using a complicated process while aligning. In addition, in the method for manufacturing the memory cube 100 and the rewiring layer 300, since wiring can be formed on the side surface of the memory cube 100, it is possible to expand choices of electrical connection between the memory cube 100 and various sizes of logic chips, wiring substrates, external circuits, and the like. That is, the manufacturing method of the semiconductor module 10 can improve the degree of freedom in design.

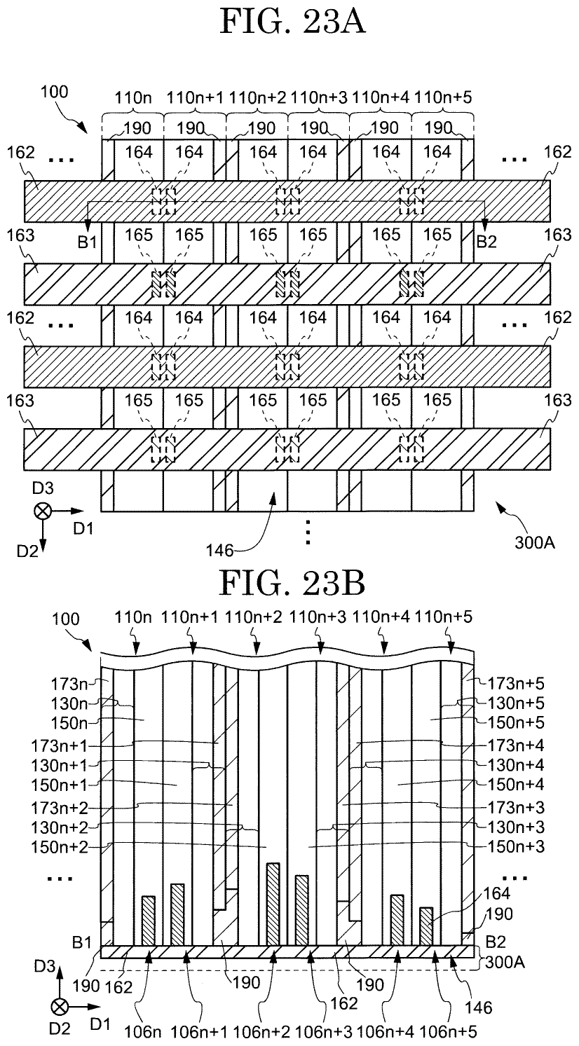

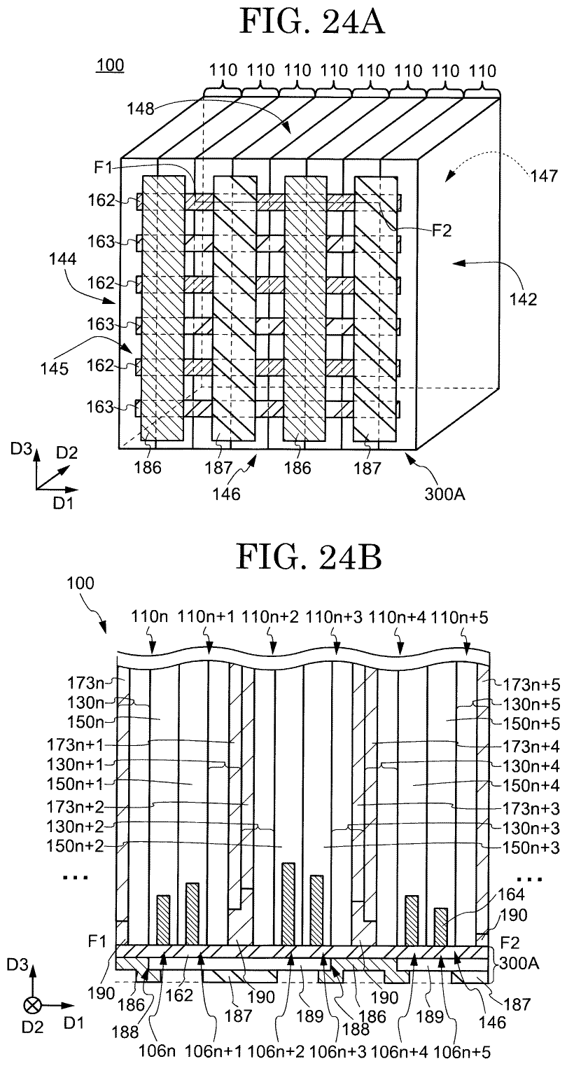

Here, a rewiring layer 300A having a configuration differing from the rewiring layer 300 shown in FIG. 8A to FIG. 10B will be described referring to FIG. 23A, FIG. 23B, FIG. 24A, and FIG. 24B. The rewiring layer 300A is formed using two wiring layers.

FIG. 23A is a schematic diagram showing configurations of the memory cube 100 and the rewiring layer 300A (side power wiring and side ground wiring), FIG. 23B is a cross-sectional view showing cross-sectional configurations of the memory cube 100 and the rewiring layer 300A taken along a line B1-B2 of FIG. 23A. FIG. 24A is a schematic diagram showing the configurations of the memory cube 100 and the rewiring layer 300A (side power wiring and side ground wiring), FIG. 24B is a cross-sectional view showing the cross-sectional configuration of the memory cube 100 and the rewiring layer 300A taken along a line F1-F2 of FIG. 24A. In the explanation of the rewiring layer 300A with reference to FIG. 23A to FIG. 24B, differences from the rewiring layer 300 with reference to FIG. 8A to FIG. 10B are mainly explained.

The rewiring layer 300A includes at least an insulating layer 189 including the side power wiring 162, the side ground wiring 163, a second side power wiring 186, a second side ground wiring 187, and an opening 188.

As shown in FIG. 23A and FIG. 23B, the side power wirings 162 and the side ground wirings 163 of the rewiring layer 300A extend in the direction D1, for example, and are alternately arranged along the direction D2 parallel to the direction D1. The side power wiring 162 and the side ground wiring 163 are formed in the same layer. For example, the side power wiring 162 of the rewiring layer 300A is arranged so as to be in contact with portions of the side surface and the upper surface of the insulating film 168 and the four power wirings 164 exposed to the first side surfaces 106n to 106n+5 of the memory chips 110n to 110n+5. Similar to the side power wiring 162 of the rewiring layer 300, for example, the side ground wiring 163 of the rewiring layer 300A is arranged so as to be in contact with the four ground wirings 165 exposed on portions of the side surface and the upper surface of the insulating film 168 and the first side surfaces 106n to 106n+5 of the memory chips 110n to 110n+5. The side power wiring 162 and the side ground wiring 163 include a conductor made of a metal material, and are, for example, a conductor containing copper, gold, silver, or the like. In the method for manufacturing the rewiring layer 300A, after the same configuration as that of the method for manufacturing the rewiring layer 300 is formed up to step 4, the side power wiring 162 and the side ground wiring 163 are formed (for example, a step 7).

After step 7, in step 8, the insulating layer 189 is formed between the side power wiring 162 and the side ground wiring 163, on the upper surfaces and the side surfaces of the side power wiring 162 and the side ground wirings 163, and on portions of the first side surfaces 106n to 106n+5 where the side power wiring 162 and the side ground wiring 163 are not formed.

After step 8, in step 9, the opening 188 is formed in the insulating layer 189, and a portion of the side power wiring 162 and a portion of the side ground wiring 163 are exposed. After step 9, in step 10, the second side power wiring 186 and the second side ground wiring 187 extend in the direction D3 for example, and are alternately arranged in the direction D1 parallel to the direction D3. The second side power wiring 186 and the second side ground wiring 187 are formed in the same layer. The second side power wiring 186 and the second side ground wiring 187 include a conductor made of metal, and are, for example, a conductor containing copper, gold, silver, tin, nickel, or the like.

In addition, the opening 188 is formed on the side power wiring 162 connected to the second side power wiring 186, and is formed on the side ground wiring 163 connected to the second side ground wiring 187. The opening 188 is not formed on the side ground wiring 163 intersecting the second side power wiring 186 and is not formed on the side power wiring 162 intersecting the second side ground wiring 187, and the insulating layer 189 remains formed on the side ground wiring 163 intersecting the second side power wiring 186 and on the side power wiring 162 intersecting the second side ground wiring 187.

In the semiconductor module 10 using the rewiring layer 300A, for example, a signal can be input/output from the first side surface 146 (the bottom surface of the memory cube 100), and a voltage such as a power supply voltage or a ground voltage can be supplied from, for example, the second side surface 145 and the fourth side surface 147 (the side surface of the memory cube 100). Therefore, the semiconductor module 10 can use the bottom surface only for signal transmission to other chips such as the logic chip 200. As a result, the semiconductor module 10 can suppress the number of input/output signals related to signal transmission, and can increase a plurality of free input/output terminals. In addition, a power supply or the like from the outside can be supplied to a plurality of input/output terminals conventionally used as input/output of signals related to signal transmission.

In addition, in the semiconductor module 10 using the rewiring layer 300A, a voltage such as the power supply voltage or the ground voltage can be directly supplied to the second side surface 145 and the fourth side surface 147 (the side surface of the memory cube 100) without passing through a chip other than the memory chip. That is, the semiconductor module 10 can stabilize the power supply voltage by performing the low-impedance power supply connection from both side surfaces (the second side surface 145 and the fourth side surface 147) of the memory cube 100.

### 1-4. Example of Seal Ring 160

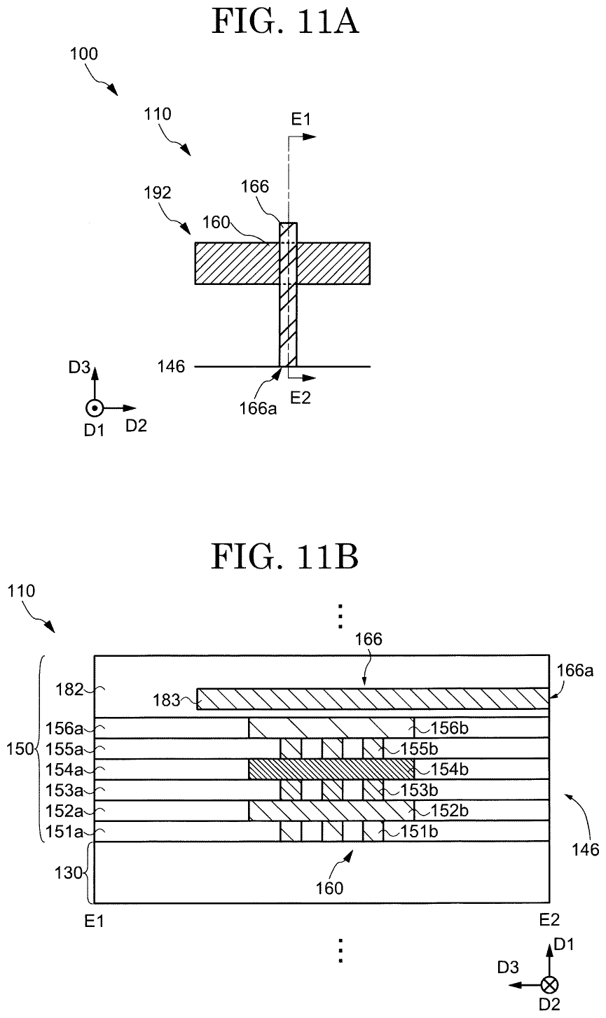

A seal ring 160 of the semiconductor module 10 will be described with respect to FIG. 11A and FIG. 11B. FIG. 11A is a plan view showing the configuration of the signal transmission wiring 166 included in the seal ring 160 and the memory chip 110, and FIG. 11B is a cross-sectional view showing a cross section of the signal transmission wiring 166 included in the seal ring 160 and the memory chip 110 taken along a line D1-D2 of FIG. 11A. The same or similar configurations as those in FIG. 1 to FIG. 10B will not be described here.

As shown in FIG. 11A and FIG. 11B, the memory cube 100 includes a seal ring 160. The seal ring 160 is provided in an outer periphery 192 and is formed in the wiring layer 150. The signal transmission wiring 166 is formed so as to overlap the seal ring 160. The outer periphery 192 is a peripheral portion of the memory chip 110 and is a portion close to each side surface of the memory chip 110 (for example, the first side surface 106, the second side surface 105, the third side surface 108, and the fourth side surface 107 shown in FIG. 2). A portion of the signal transmission wiring 166 is arranged outside the outer periphery 192. As described in “1-1. Overview of Semiconductor Module 10”, the wiring layer 150 includes a multilayer wiring structure. In addition, similar to the signal transmission wiring 166, the power wiring 164 (for example, FIG. 8A) and the ground wiring 165 (for example, FIG. 8A) are formed so as to overlap the seal ring 160, and a portion of the power wiring 164 and a portion of the ground wiring 165 are arranged on the outer side of the outer periphery 192.

As shown in the cross-sectional view of FIG. 11B, the wiring layer 150 includes, for example, a multilayer wiring structure of seven layers (first to seventh layers). The seven-layer multilayer wiring structure includes an insulating layer 151a, a via 151b, an insulating layer 152a, a wiring 152b, an insulating layer 153a, a via 153b, an insulating layer 154a, a wiring 154b, an insulating layer 155a, a via 155b, an insulating layer 156a, a wiring 156b, the insulating layer 182, and a wiring 183. The first insulating layer 151a is formed on the transistor layer 130, and the first via 151b is formed on the transistor layer 130 through the insulating layer 151a. The second insulating layer 152a is formed on the insulating layer 151a and the via 151b, and the second wiring 152b is formed on the via 151b through the insulating layer 152a. In the same manner as in the first and second layers of the multilayer wiring structure, the third insulating layer 153a and the via 153b, the fourth insulating layer 154a and the wiring 154b, the fifth insulating layer 155a and the via 155b, the sixth insulating layer 156a and the wiring 156b, and the seventh insulating layer 182 and the wiring 183 are formed in this order from a lower side to an upper side in the direction D1. For example, the signal transmission wiring 166, the power wiring 164, and the ground wiring 165 are formed using the wiring 183.

The insulating layers 182, 156a, 155a, and 154a are formed using, for example, an insulating material that differs from a material having a lower dielectric constant (low-k material). The insulating layers 182, 156a, 155a, and 154a are formed of, for example, SiO₂, SiCN, SIN, SION, or the like.

The seal ring 160 has a function of suppressing moisture absorption, impurities, and the like from, for example, the second side surface 145, the third side surface 148, and the fourth side surface 147 of the memory cube 100. The semiconductor module 10 can suppress corrosion, deterioration, and the like of the wiring caused by moisture absorption and intrusion of impurities and the like by the seal ring 160.

### 1-5. Mounting Example of Semiconductor Module 10

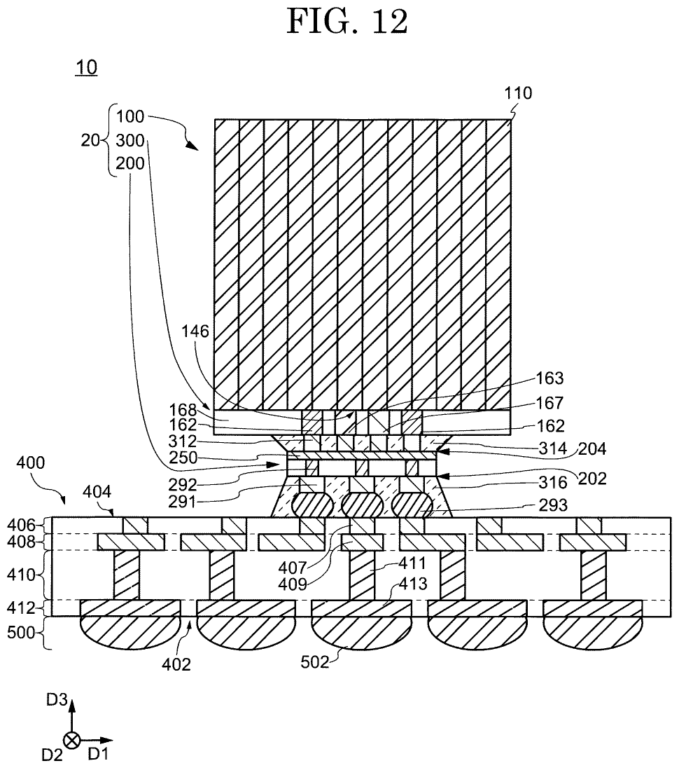

A mounting example of the semiconductor module 10 will be described with reference to FIG. 12. FIG. 12 is a cross-sectional view showing a mounting example of the semiconductor module 10 according to the first embodiment of the present invention. The same or similar configurations as those in FIG. 1 to FIG. 11B will not be described here.

As shown in FIG. 12, the semiconductor module 10 includes the structure 20, an electrode pad 291, a bump 293, a UF agent 316, the circuit substrate 400, and the bump layers 500. The structure 20 is configured to include the memory cube 100, the rewiring layer 300, the logic chip 200, the plurality of pillars 312, and a UF agent 314. As described in “1-1. Overview of Semiconductor Module 10”, a size of the memory cube 100 is larger than a size of the logic chip 200.

In the semiconductor module 10, the memory cube 100, the rewiring layer 300, and the logic chip 200 are electrically connected by the plurality of pillars 312 using, for example, a flip chip (Flip-Chip (FC)) mounting technique, and the memory cube 100, the rewiring layer 300, and the logic chip 200 are fixed to each other by the UF agent 314. In the semiconductor module 10, for example, the structure 20 and the wiring substrate 400 are electrically connected to each other by the electrode pad 291 and the bump 293, and the structure 20 and the wiring substrate 400 are fixed to each other by the UF agent 316 using the flip-chip (Flip-Chip (FC)) mounting technique.

More specifically, the first side surface 146 of the memory cube 100 is electrically connected to the side power wiring 162, the side ground wiring 163, and the side signal transmission wiring 167 of the rewiring layer 300. The side power wiring 162, the side ground wiring 163, and the side signal transmission wiring 167 of the rewiring layer 300 are electrically connected to the wiring layer 250 (a plurality of wirings) on the second surface 204 side of the logic chip 200 by using the pillar 312, and the rewiring layer 300 and the logic chip 200 are fixed to each other by using the UF agent 314. The wiring layer 250 includes a plurality of wirings. The logic chip 200 includes the wiring layer 250, a through-hole electrode 292, and the electrode pad 291. The wiring layer 250 is electrically connected to the electrode pad 291 formed on the first surface 202 via the through-hole electrode 292. The logic chip 200 (the electrode pad 291) is electrically connected to the wiring substrate 400 using the bump 293, and the logic chip 200 and the wiring substrate 400 are fixed to each other using the UF agent 316.

Further, for example, the power supply voltage VDD, the voltage VSS, various types of signals, and the like are supplied from an external circuit (not shown) to the logic chip 200 via the wiring substrate 400, the bump 293, and the electrode pad 291. Further, the power supply voltage VDD, the voltage VSS, various types of signals, and the like are supplied from an external circuit (not shown) to the memory cube 100 via the wiring substrate 400, the bump 293, the electrode pad 291, the through-hole electrode 292, the wiring layer 250, the pillar 312, and the rewiring layer 300. The plurality of power wirings 164 and the plurality of ground wirings 165 are electrically connected to the logic chip 200 and the external circuit using, for example, the wiring substrate 400, the bump 293, the electrode pad 291, the through-hole electrode 292, the wiring layer 250, the pillar 312, and the rewiring layer 300, and the power supply voltage VDD, the voltage VSS, and the like are supplied from the external circuit. Further, the plurality of signal transmission wirings 166 are electrically connected to the logic chip 200 and an external circuit (not shown) using, for example, the wiring substrate 400, the bump 293, the electrode pad 291, the through-hole electrode 292, the wiring layer 250, the pillar 312, and the rewiring layer 300, and an address signal, an enable signal, and the like for controlling the memory chip 110 are supplied from the logic chip 200 and the external circuit.

The flip-chip (Flip-Chip (FC)) mounting technique is one technique for mounting a semiconductor chip and a substrate via bumps, pillars, and the like. The substrate is, for example, an interposer, a printed circuit substrate capable of high-density interconnection (High-density interconnect (HDI)), or the like. By using flip-chip (Flip-Chip (FC)) mounting techniques, the semiconductor chip and the substrate can be electrically connected, for example, using pillars or bumps, and secured together using adhesives such as under fill (Under Fill (UF)) agents, and anisotropic conductive adhesives (Anisotropic Conductive Adhesives (ACA)). The UF agent is, for example, an insulating adhesive.

The through-hole electrode 292, the electrode pad 291, and the pillar 312 are formed using, for example, a conductor made of metal. The conductor made of metal is, for example, a conductor containing copper, tin, or the like.

The rewiring layer 300 of the semiconductor module 10 is, for example, a fan-in type rewiring layer. The fan-in type is a mounting type in which, in a chip including a plurality of input/output terminals arranged in an array on a surface of the chip, a wiring group electrically connected to the chip is routed from the outside of the chip toward the plurality of input/output terminals inside the chip. Although not shown in the drawings, for example, the wiring group is electrically connected to the input/output terminal so as to collapse inward from the periphery (outer side) of the chip in a plan view.

The wiring substrate 400 includes a multilayer wiring structure in which wirings and insulating layers are alternately stacked. The wiring substrate 400 includes, for example, a second surface 404, a first surface 402, and a plurality of wiring layers 406, 408, 410, and 412, and includes a function of connecting the memory cube 100, the logic chip 200, and the like to an external substrate, an external circuit, and the like. In FIG. 12, the insulating layers alternately stacked with the wiring are not shown. The circuit substrate 400 is, for example, a printed circuit substrate capable of high-density interconnection (High-density interconnect (HDI)). For example, the wiring layers 406, 408, 410, and 412 are arranged parallel to the direction D1 and the direction D2 and stacked in this order in the direction D3. The plurality of wiring layers 406, 408, 410, and 412 includes a plurality of wirings 407, a plurality of wirings 409, a plurality of wirings 411, and a plurality of wirings 413. For example, the wiring 407 is electrically connected to the wiring 409, the wiring 409 is electrically connected to the wiring 411, and the wiring 411 is electrically connected to the wiring 413. In addition, the number of stacked layers of the multilayer wiring structure of the wiring substrate 400 is not limited to the number of stacked layers (four layers) shown in FIG. 12. The number of layers of the multilayer wiring structure of the wiring substrate 400 can be appropriately changed based on the application or specification of the semiconductor module 10.

The bump layer 500 includes a plurality of bumps 502, and has a function of connecting the wiring substrate 400 to an external substrate, an external circuit, or the like.

The semiconductor module 10 may be implemented as described above. In the method for manufacturing the memory cube 100 and the rewiring layer 300, a wiring (side wiring) can be formed on a side surface by a simpler process than a manufacturing method for forming each wiring using a complicated process while aligning. In addition, the memory cube 100 and the fan-in type rewiring layer 300 can be electrically connected to each other by using side wiring of each other. Further, in the semiconductor module 10, the memory cube 100 in which the plurality of memory chips 110 are stacked can be vertically arranged (arranged in the direction D3) on the logic chip 200 by using the wirings (side wirings) formed in the memory cube 100 and the rewiring layer 300. In the semiconductor module 10, by vertically mounting the memory cube 100 on the logic chip 200, it is possible to keep the distance between the respective memory chips 110 and the logic chip 200 close and constant, rather than stacking the plurality of memory chips 110 and the logic chip 200 in parallel. By using the semiconductor module 10, a memory with low power consumption and large capacity can be realized.

Further, in the semiconductor module 10, the memory cube 100, the fan-in type rewiring layer 300, the logic chip 200 having a size smaller than that of the memory cube 100, and the wiring substrate 400 can be electrically connected using the wiring (side wiring) formed in the memory cube 100 and the rewiring layer 300 and the flip-chip technology. That is, in the semiconductor module 10, the side surface wiring and the flip-chip technology can be used in combination based on the wiring (side surface wiring) formed in the memory cube 100 and the rewiring layer 300, and thus the degree of freedom in design of the memory cube 100 is improved.

### 2. Second Embodiment

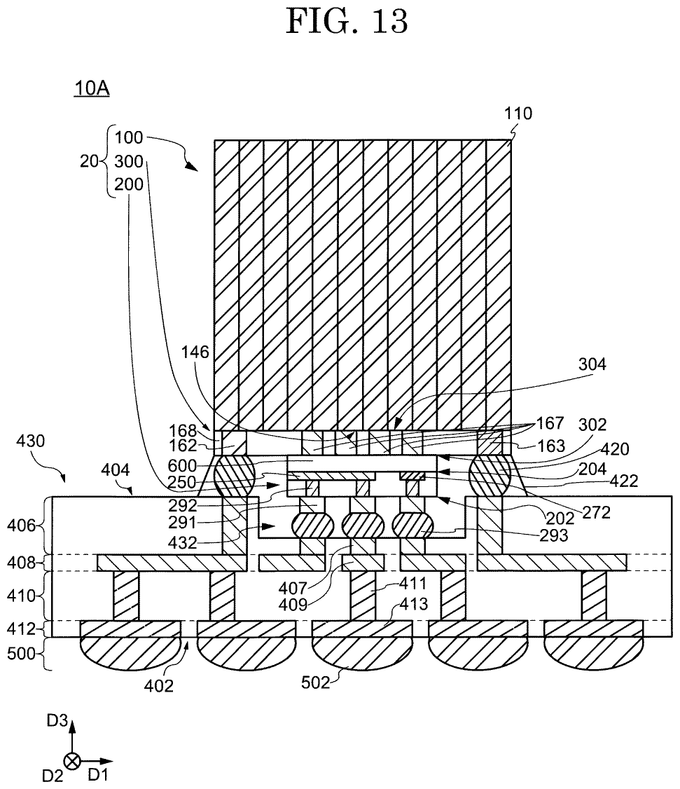

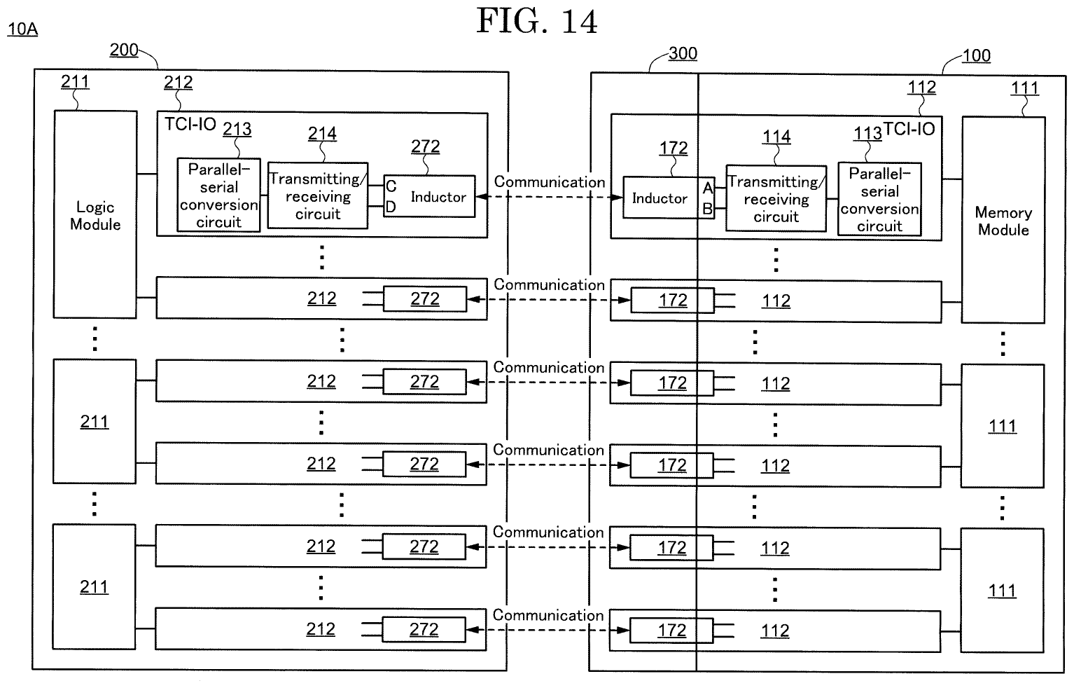

An exemplary implementation of a semiconductor module 10A will be described referring to FIG. 13 and FIG. 14. FIG. 13 is a cross-sectional view of the semiconductor module 10A according to a second embodiment of the present disclosure. FIG. 14 is a diagram showing a configuration of the semiconductor module 10A according to the second embodiment of the present disclosure. The same or similar configurations as those in FIG. 1 to FIG. 12 will not be described here.

First, the configuration of the semiconductor module 10A will be described. As shown in FIG. 13, the semiconductor module 10A includes the structure 20 and a cavity substrate 430. The structure 20 includes the memory cube 100, the rewiring layer 300, the logic chip 200, and an adhesive layer 600.

The memory cube 100 has the structure and function described in the first embodiment. A detailed description of the memory cube 100 is omitted here.

The rewiring layer 300 is a fan-in type rewiring layer including the same functions and configurations as those of the first embodiment. The side signal transmission wiring 167 included in the rewiring layer 300 includes, for example, an inductor 172 (see FIG. 14). The rewiring layer 300 according to the second embodiment includes the plurality of side signal transmission wirings 167 and the plurality of inductors 172. For example, each of the side power wiring 162 and the side ground wiring 163 included in the rewiring layer 300 is electrically connected to a bump 420. In addition, the rewiring layer 300 according to the second embodiment has the same structure and function as those described in the first embodiment. A detailed description of the rewiring layer 300 will be omitted here.

The adhesive layer 600 is arranged between a first surface 302 of the rewiring layer 300 and the second surface 204 of the logic chip 200, and adheres the memory cube 100, the rewiring layer 300, and the logic chip 200 to each other. The adhesive layer 600 may be, for example, an adhesive containing an epoxy resin, an acrylic polymer, or the like, a die bonding film (Die Bonding Film (DBF)) containing an epoxy resin or an acrylic polymer, or an adhesive film such as a die attach film (Die Attached Film (DAF)).

The logic chip 200 includes, for example, a plurality of wirings (not shown) included in the wiring layer 250 and a plurality of inductors 272. Further, the logic chip 200 includes a plurality of through-hole electrodes 292 and a plurality of electrode pads 291. The plurality of wirings and the plurality of inductors 272 are provided in the same process, for example. Each of the plurality of wirings and the plurality of inductors 272 is electrically connected to the electrode pad 291 using the through-hole electrode 292. Each of the plurality of electrode pads 291 is electrically connected to the corresponding bump 293. In the semiconductor module 10A, similar to the semiconductor module 10, for example, the substrate 273 (the first surface 202) of the logic chip 200 is arranged on the cavity substrate 430, and the logic chip 200 is mounted face-up on the cavity substrate 430. In addition, for example, a mounting configuration in which the wiring layers 250 (second surfaces 204) of the logic chip 200 are arranged on the cavity substrate 430 and the stacking direction is downward in the direction D3 is referred to as face-down mounting.

The cavity substrate 430 includes a cavity part 432. The cavity part 432 may be referred to as a recess. The cavity substrate 430 can absorb a height DH of a portion including the adhesive layer 600 and the logic chip 200 which are convexly arranged in the memory cube 100 in the cavity part 432. In addition, the cavity substrate 430 includes a multilayer wiring structure in which wirings and insulating layers are alternately stacked, similar to the wiring substrate 400 according to the first embodiment. In the description of the cavity substrate 430, description which are the same as or similar to that of the wiring substrate 400 will be omitted here.

The bump layer 500 includes the plurality of bumps 502, is electrically connected to the plurality of wirings 413 included in the cavity substrate 430, and has a function of connecting the cavity substrate 430 to an external substrate, an external circuit, or the like.

The structure 20 is electrically connected to the cavity substrate 430 using the plurality of bumps 420 and the plurality of bumps 293, and the structure 20 and the cavity substrate 430 are fixed to each other using a UF agent 422. Specifically, the structure 20 is electrically connected to the wiring 407 exposed to the cavity part 432 by using the plurality of bumps 420, and is electrically connected to the wiring 407 exposed to the second surface 404 by using the plurality of bumps 293. In addition, a portion of the rewiring layer 300, the adhesive layer 600, the logic chip 200, the plurality of bumps 293, and the plurality of bumps 420 are fixed to the cavity part 432 and a portion of the second surface 404 of the cavity substrate 430 using the UF agent 422.

Further, for example, the power supply voltage VDD, the voltage VSS, various types of signals, and the like are supplied from an external circuit (not shown) to the logic chip 200 via the cavity substrate 430, the bumps 293, and the electrode pads 291. Further, the power supply voltage VDD, the voltage VSS, various types of signals, and the like are supplied from an external circuit (not shown) to the memory cube 100 via the cavity substrate 430, the bumps 420, and the rewiring layers 300. The plurality of power wirings 164 and the plurality of ground wirings 165 are electrically connected to the external circuit using, for example, the cavity substrate 430, the bumps 420, and the rewiring layers 300, and the power supply voltage VDD, the voltage VSS, and the like are supplied from the external circuit. Further, the plurality of signal transmission wirings 166 may be electrically connected to an external circuit (not shown) using, for example, the cavity substrate 430, the bump 420, and the rewiring layer 300, and a part of the signals for controlling the memory chip 110 may be supplied from the external circuit.

Next, FIG. 14 is a schematic diagram showing the configuration of the semiconductor module 10A. As shown in FIG. 14, the memory cube 100 includes a plurality of magnetic field coupled chip-to-chip interfaces (Through Chip Interface-IO (TCI-IO)) 112 and the plurality of memory modules 111. The plurality of TCI-IO 112 is electrically connected to the memory module 111.

The TCI-IO 112 includes the inductor 172, a transmitting/receiving circuit 114, and a parallel-serial conversion circuit 113. The inductor 172 is electrically connected to the transmitting/receiving circuit 114 using a terminal A and a terminal B. The transmitting/receiving circuit 114 is electrically connected to the parallel-serial conversion circuit 113. The parallel-serial conversion circuit 113 is electrically connected to the memory module 111.

The inductor 172 has a function of performing inductor communication with the inductor 272 of the logic chip 200 in a non-contact manner.

The transmitting/receiving circuit 114 has, for example, a function of amplifying a signal (data) received by the inductor 172 and a function of removing noise from the received signal (data). The transmitting/receiving circuit 114, for example, has a function of placing a desired signal (data) converted by using the parallel-serial conversion circuit 113 on a radio wave. The signal received by inductor 172 includes a number of parallel signals from the logic chip 200. The desired signal includes a number of parallel signals from the memory module 111.

For example, in step 10, the parallel-serial conversion circuit 113 performs parallel-serial conversion on a large number of parallel signals from the logic chip 200 to convert them into serial signals (serial signals). The serial signal is transferred at high speed using one signal path (wiring). In step 11, the parallel-serial conversion circuit 113 performs parallel-serial conversion on a serial signal described above immediately before the memory module 111, returns the serial signal to a number of parallel signals, and then transmits the plurality of parallel signals to the memory module 111. In the case where a signal (data) is transmitted from the memory module 111 to the logic chip 200, the parallel-serial conversion circuit 113 executes, for example, step 10 following step 11. The parallel-serial conversion circuit 113 is referred to as, for example, a SerDes circuit (Serialize and Deserialise Circuit).

The memory module 111 includes, for example, a function of generating a plurality of parallel signals to be transmitted and a function of controlling a plurality of received parallel signals and storing them in the memory cell array 115 (see FIG. 4).

The logic chip 200 includes a plurality of field coupled chip-to-chip interfaces (Through Chip Interface-IO (TCI-IO)) 212 and a plurality of logic modules 211. The plurality of TCI-IO 212 is electrically connected to the logical module 211.

The TCI-IO 212 includes the inductor 272, a transmitting/receiving circuit 214, and a parallel-serial conversion circuit 213. The inductor 272 is electrically connected to the transmitting/receiving circuit 214 using a terminal C and a terminal D. The transmitting/receiving circuit 214 is electrically connected to the parallel-serial conversion circuit 213. The parallel-serial conversion circuit 213 is electrically connected to the logic module 211.

The configurations and functions of the inductor 272, the transmitting/receiving circuit 214, the parallel-serial conversion circuit 213, and the logic module 211 are the same as those of the inductor 172, the transmitting/receiving circuit 114, the parallel-serial conversion circuit 113, and the memory module 111. Therefore, the configurations and functions of the inductor 272, the transmitting/receiving circuit 214, the parallel-serial conversion circuit 213, and the logic module 211 will not be described here.

The plurality of inductors 172, the circuits included in the plurality of TCI-IO 112, and the circuits included in the plurality of memory modules 111 are formed using the transistor layer 130 and the wiring layer 150. Further, the plurality of inductors 272, the respective circuits included in the plurality of TCI-IO 212, and the respective circuits included in the plurality of logic modules 211 are formed using the transistor layer 230 and the wiring layer 250.

Next, an outline of inductor communication between the inductor 172 and the inductor 272 of the semiconductor module 10A will be described. As described above, the inductor 172 is included in the rewiring layer 300, and the inductor 272 is provided together with a plurality of wirings (not shown) included in the wiring layer 250. Generally, only the adhesive layer 600 is arranged between the inductor 172 and the inductor 272. Therefore, since the inductor 172 and the inductor 272 are arranged close to each other, good communication at a short distance is possible. A shape of the inductor 172 and a shape of the inductor 272 may be, for example, a triangular shape, a square shape, a trapezoidal shape, or a pentagonal shape. There is no limitation on the shape of the inductor 172 and the inductor 272 as long as the inductor 172 and the inductor 272 can communicate with each other in a one-to-one manner by magnetic field coupling. In addition, the communication between the inductors associated with the magnetic field coupling is referred to as, for example, inductor communication, signal communication, data communication, and the like.

The semiconductor module 10A is implemented as described above. In the method for manufacturing the memory cube 100 and the rewiring layer 300 included in the semiconductor module 10A, the wiring can be formed on the side surface by a simpler process than the manufacturing method for forming the wiring using a complicated process while aligning. Further, in the semiconductor module 10A, the memory cube 100, the fan-in type rewiring layer 300, and the cavity substrate 430 can be electrically connected by using the wiring (side wiring) formed on the side surface of the memory cube 100. In the semiconductor module 10A, by vertically mounting the memory cube 100 on the logic chip 200, a distance between the respective memory chips 110 and the logic chip 200 can be kept close and constant, rather than the plurality of memory chips 110 and the logic chip 200 being stacked in parallel. By using the semiconductor module 10A, a low power consumption and large capacity memory can be realized.

Further, the semiconductor module 10A includes the functions and configurations described above, and the memory cube 100 connected to the fan-in type rewiring layer 300 using the wiring (side wiring) formed on the side of the memory cube 100, and the logic chip 200, which is smaller than the memory cube 100, can communicate with each other in a non-contact manner using inductor communication without being directly electrically connected. In the semiconductor module 10A, by using the contactless inductor communication, a load caused by wiring resistance and parasitic capacitance between the memory chip 110 and the logic chip 200 is suppressed, so that the power consumption of the semiconductor module 10A can be further suppressed.

Further, in the semiconductor module 10A, the structure 20 and the cavity substrate 430 can be electrically connected to each other and fixed to each other by using the wiring (side wiring) formed in the memory cube 100 and the rewiring layer 300, the electrode pads 291, the bumps 420 and the bumps 293, and UF agent 422. That is, in the semiconductor module 10A, the degree of freedom in design of the memory cube 100 is improved based on the wirings (side wirings) formed in the memory cube 100 and the rewiring layer 300, and unlike the semiconductor module 10 according to the first embodiment, the memory module can be mounted on the cavity substrate 430.

In addition, in the semiconductor module 10A, although the logic chip 200 is mounted face-up on the cavity substrate 430, the method for mounting the logic chip 200 is not limited to face-up mounting. For example, even if the rewiring layer 300 (inductor 172) and the inductor 272 are separated from each other, inductor communication between the inductor 172 and the inductor 272 can be performed if a distance between the inductor 172 and the inductor 272 along the direction D3 is a constant distance. That is, the constant distance may be any distance that enables inductor communication between the inductor 172 and the inductor 272. In this case, the implementation of the logic chip 200 may be a face-down implementation.

### 3. Third Embodiment

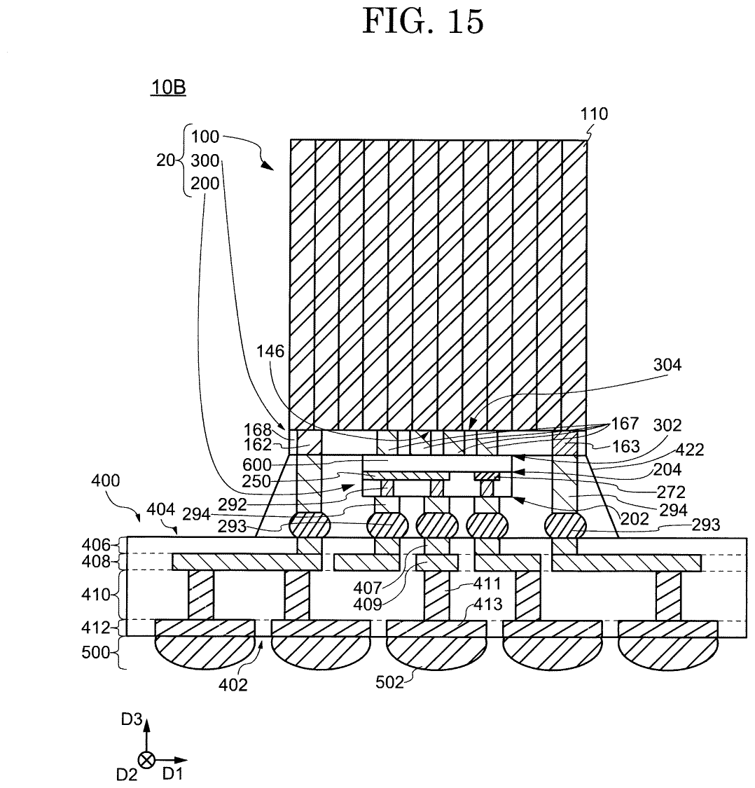

FIG. 15 is a block diagram showing an exemplary embodiment of a semiconductor module 10B. FIG. 15 is a cross-sectional view showing the semiconductor module 10B according to a third embodiment of the present disclosure. Descriptions of the same or similar configurations as those in FIG. 1 to FIG. 14 will be omitted.

As shown in FIG. 15, the semiconductor module 10B includes the structure 20, the wiring substrate 400, pillars 294, the bumps 293, the UF agent 422, and bump layer 500. The structure 20 includes the memory cube 100, the rewiring layer 300, the logic chip 200, and the adhesive layer 600.

In the semiconductor module 10B, the structure 20 and the wiring substrate 400 are directly electrically connected to each other by using the pillars 294 and the bumps 293, and the structure 20 and the wiring substrate 400 are fixed to each other by using the UF agent 422. More specifically, the through-hole electrode 292 exposed on the first surface 202 of the logic chip 200 included in the structure 20 is directly electrically connected to the wiring layer 406 (wiring 407) exposed on the first surface 402 of the wiring substrate 400 by using the pillar 294 and the bump 293. Further, the side power wiring 162, the side ground wiring 163, and the side signal transmission wiring 167 exposed on the first surface 302 of the rewiring layer 300 included in the structure 20 are directly electrically connected to the wiring layer 406 (the wiring 407) exposed on the first surface 402 of the wiring substrate 400 by using the pillar 294 and the bump 293. On the other hand, in the semiconductor module 10A, the structure 20 is electrically connected to the cavity substrate 430 by using the plurality of bumps 420 and the plurality of bumps 293, and the structure 20 and the cavity substrate 430 are fixed to each other by using the UF agent 422. The semiconductor module 10B has the same configuration and function as those of the semiconductor module 10A except for the electric coupling described above and the fixing using the UF agent 422. Therefore, in the explanation of the semiconductor module 10B, differences from the semiconductor module 10A are mainly explained. In addition, the wiring substrate 400 may be referred to as an external substrate.

The memory cube 100 has the structure and function described in the first embodiment. The memory cube 100 is electrically connected to the rewiring layer 300 using the side power wiring 162, the side ground wiring 163, and the side surface signal transmission wiring 167. A detailed description of the memory cube 100 is omitted here.

The rewiring layer 300 is a fan-in type rewiring layer including the same functions and configurations as those of the first embodiment. The side signal transmission wiring 167 included in the rewiring layer 300 includes, for example, an inductor 172. The rewiring layer 300 according to the third embodiment includes the plurality of side signal transmission wirings 167 and the plurality of inductors 172. For example, each of the side power wiring 162 and the side ground wiring 163 included in the rewiring layer 300 is electrically connected to the bump 420. In addition, the rewiring layer 300 has the same structure and function as those described in the first embodiment. A detailed description of the rewiring layer 300 will be omitted here.

The logic chip 200 and the adhesive layers 600 have the same configuration and function as those of the semiconductor module 10A described in the second embodiment. The wiring substrate 400 and the bump layer 500 have the same configuration and function as those of the first embodiment. Detailed description of the logic chip 200, the wiring substrate 400, and the bump layer 500 will be omitted here. In the semiconductor module 10B, similar to the semiconductor module 10A, although an example is shown in which the logic chip 200 is mounted face-up on the wiring substrate 400, the logic chip 200 may be mounted face-down as long as the inductor 172 and the inductor 272 can communicate with each other.

Further, for example, the power supply voltage VDD, the voltage VSS, various types of signals, and the like are supplied from an external circuit (not shown) to the logic chip 200 via the wiring substrate 400, the bumps 293, and the pillars 294. In addition, the power supply voltage VDD, the voltage VSS, various types of signals, and the like are supplied from an external circuit (not shown) to the memory cube 100 via the wiring substrate 400, the bumps 293, the pillars 294, and the rewiring layer 300. The plurality of power wirings 164 and the plurality of ground wirings 165 are electrically connected to the external circuit using, for example, the wiring substrate 400, the bumps 293, the pillars 294, and the rewiring layers 300, and the power supply voltage VDD, the voltage VSS, and the like are supplied from the external circuit. Further, the plurality of signal transmission wirings 166 may be electrically connected to an external circuit (not shown) by using the wiring substrate 400, the bumps 293, the pillars 294, and the rewiring layer 300, and a part of the signals for controlling the memory chip 110 may be supplied from the external circuit.

The semiconductor module 10B is implemented as described above. In the semiconductor module 10B, similar to the semiconductor module 10, a wiring (side wiring) can be formed on the side surface in a simple process, and a distance between each memory chip 110 and the logic chip 200 can be kept close and constant. Therefore, a low power consumption and large capacity memory can be realized by using the semiconductor module 10B.

In addition, the semiconductor module 10B, the memory cube 100 and the logic chip 200 can communicate (electrically connected) using inductor communication, similar to the semiconductor module 10A. Therefore, in the semiconductor module 10B, by using the contactless inductor communication, the load caused by wiring resistance and parasitic capacitance between the memory chip 110 and the logic chip 200 is suppressed, so that the power consumption of the semiconductor module 10B can be further suppressed.

Further, in the semiconductor module 10B, the structure 20 and the wiring substrate 400 can be electrically connected to each other and fixed to each other by using the wiring (side wiring) formed in the memory cube 100 and the rewiring layer 300, the pillar 294 and the bump 293, and the UF agent 422. That is, in the semiconductor module 10B, the degree of freedom in design of the memory cube 100 is improved based on the wiring (side wiring) formed in the memory cube 100 and the rewiring layer 300, and can be implemented differently from the first embodiment and the second embodiment. In addition, for example, the pillar 294 may be constructed using similar materials as the pillar 312 and may be referred to as copper pillars, solder balls, solder bumps, gold stud bumps, copper stud bumps, and the like.

### 4. Fourth Embodiment

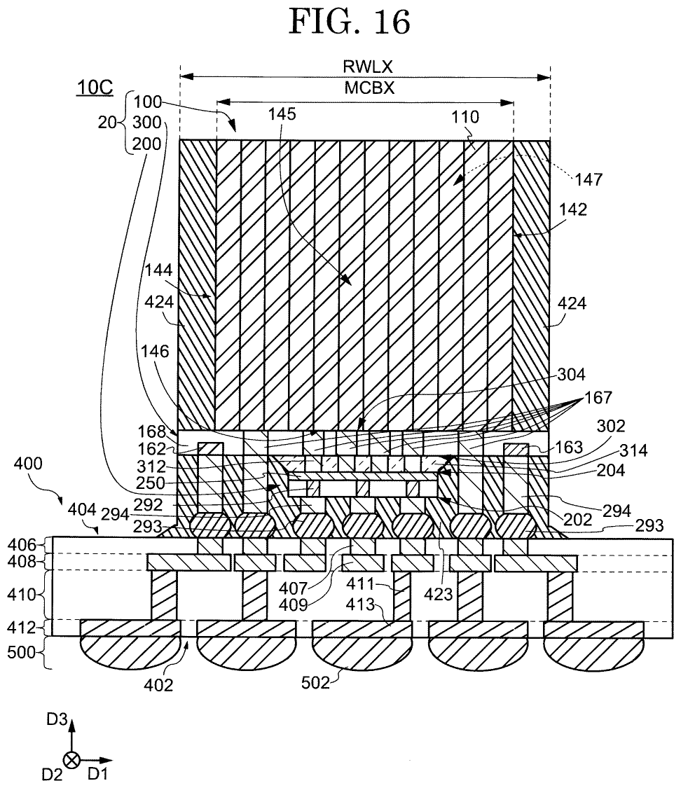

FIG. 16 is a diagram showing a mounting example of a semiconductor module 10C. FIG. 16 is a cross-sectional view of the semiconductor module 10C according to a fourth embodiment of the present disclosure. The same or similar configurations as those in FIG. 1 to FIG. 15 will not be described here.

The semiconductor module 10C includes the structure 20, the wiring substrate 400, the pillars 294, the bumps 293, a molding material 423, a molding material 424, and the bump layer 500. The structure 20 is configured to include the memory cube 100, the rewiring layer 300, and the logic chip 200. A length RWLX of the rewiring layer 300 in the direction D1 is longer than a length MCBX of the memory cube 100 in the direction D1. The molding material is an insulating resin material, and includes, for example, a resin material such as epoxy, a curing agent, a filler, an additive, and the like. In addition, the molding material 423 or the molding material 424 may be referred to as a second insulating film.

In the semiconductor module 10C, the memory cube 100, the rewiring layer 300, and the logic chip 200 are electrically connected to each other, and the memory cube 100, the rewiring layer 300, and the logic chip 200 are fixed to each other by using a FC mounting technique. For example, the plurality of side surface signal transmission wirings 167 included in the rewiring layer 300 is electrically connected to the plurality of wirings (not shown) included in the wiring layer 250 of the logic chip 200 by using the plurality of pillars 312, and the rewiring layer 300 and the logic chip 200 are fixed to each other by using the UF agent 314.

In addition, the semiconductor module 10C, the structure 20 and the wiring substrate 400 are electrically connected to each other using the pillars 294 and the bumps 293, and the structure 20 and the wiring substrate 400 are fixed to each other using the molding material 423 and the molding material 424. More specifically, the through-hole electrode 292 exposed on the first surface 202 of the logic chip 200 included in the structure 20 is directly electrically connected to the wiring layer 406 (wiring 407) exposed on the first surface 402 of the wiring substrate 400 by using the pillar 294 and the bump 293. Further, the side power wiring 162, the side ground wiring 163, and the side signal transmission wiring 167 exposed on the first surface 302 of the rewiring layer 300 included in the structure 20 are directly electrically connected to the wiring layer 406 (the wiring 407) exposed on the first surface 402 of the wiring substrate 400 by using the pillar 294 and the bump 293.

In addition, in the memory cube 100, the first surface 142, the second surface 144, the second side surface 145, and the fourth side surface 147 are fixed to the rewiring layer 300 and are protected by using the molding material 424. Further, the logic chip 200 electrically connected to and fixed to the rewiring layer 300 using the FC mounting technique, and the plurality of pillars 294 and the plurality of bumps 293 electrically connecting the rewiring layer 300 and the logic chip 200 to the wiring substrate 400 are fixed to the rewiring layer 300 and the wiring substrate 400 and are protected by using the molding material 423.

The molding materials 423 and 424 can suppress vibrations and impacts that the semiconductor module 10 receives from the outside and can suppress the intrusion of water from the outside into the semiconductor module 10C. Further, the semiconductor module 10C can efficiently discharge the heat generated in the semiconductor module to the outside by the molding materials 423 and 424.

On the other hand, in the semiconductor module 10C, the structure 20 and the wiring substrate 400 are electrically connected by using the pillars 294 and the bumps 293, and the structure 20 and the wiring substrate 400 are fixed to each other by using the UF agent 422. The semiconductor module 10C has the same configuration and functions as those of the semiconductor module 10 except for the electric connection described above and the fixing using the molding materials 423 and 424. Therefore, in the explanation of the semiconductor module 10C, differences from the semiconductor module 10 are mainly explained.

The memory cube 100 has the structure and function described in the first embodiment. A detailed description of the memory cube 100 is omitted here.

The rewiring layer 300 of the semiconductor module 10C is a fan-out type rewiring layer. The fan-out type is a mounting type in which, in a chip including a plurality of input/output terminals arranged in an array on a surface of the chip, a wiring group electrically connected to the chip is routed from the plurality of input/output terminals toward the outside (peripheral side) of the chip. Although not shown in the drawings, for example, in a plan view, the plurality of input/output terminals is electrically connected to the wiring group so as to spread around (outside) the chip from the plurality of input/output terminals arranged in an array on the inside of the chip. The wiring group is, for example, the side power wiring 162, the side ground wiring 163, the side surface signal transmission wiring 167, or the like included in the rewiring layer 300.

The logic chip 200, the wiring substrate 400, and the bump layer 500 have the same configurations and functions as those of the first embodiment. Detailed description of the logic chip 200, the wiring substrate 400, and the bump layer 500 will be omitted here. In the semiconductor module 10C, similar to the semiconductor module 10, for example, the semiconductor module is mounted face-up on the circuit substrate 400.

Further, for example, the power supply voltage VDD, the voltage VSS, various types of signals, and the like are supplied from an external circuit (not shown) to the logic chip 200 via the wiring substrate 400, the bumps 293, and the pillars 294. In addition, the power supply voltage VDD, the voltage VSS, various types of signals, and the like are supplied from an external circuit (not shown) to the memory cube 100 via the wiring substrate 400, the bumps 293, the pillars 294, and the rewiring layer 300. The plurality of power wirings 164 and the plurality of ground wirings 165 are electrically connected to the external circuit using, for example, the wiring substrate 400, the bumps 293, the pillars 294, and the rewiring layer 300 (the side power wiring 162 and the side ground wiring 163), and the power supply voltage VDD, the voltage VSS, and the like are supplied from the external circuit. Further, the plurality of signal transmission wirings 166 may be electrically connected to an external circuit (not shown) by using the wiring substrate 400, the bump 293, the pillar 294, and the rewiring layer 300 (side signal transmission wiring 167), and a part of the signals for controlling the memory chip 110 may be supplied from the external circuit.

The semiconductor module 10C is implemented as described above. In the semiconductor module 10C, similar to the semiconductor module 10, the wiring (side wiring) can be formed on the side surface in a simple process, and a distance between each memory chip 110 and the logic chip 200 can be kept close and constant. Therefore, by using the semiconductor module 10C, a low power consumption and large capacity memory can be realized.

Further, in the semiconductor module 10C, the structure 20 and the wiring substrate 400 can be electrically connected to each other and fixed to each other using the wiring (side wiring) formed in the memory cube 100 and the fan-out type rewiring layer 300, the pillars 294 and the bumps 293, and the molding materials 423 and 424. That is, in the semiconductor module 10C, the degree of freedom in design of the memory cube 100 is improved based on the wiring (side wiring) formed in the memory cube 100 and the rewiring layer 300, and implementations different from those of the first to third embodiments are possible.

### 5. Fifth Embodiment

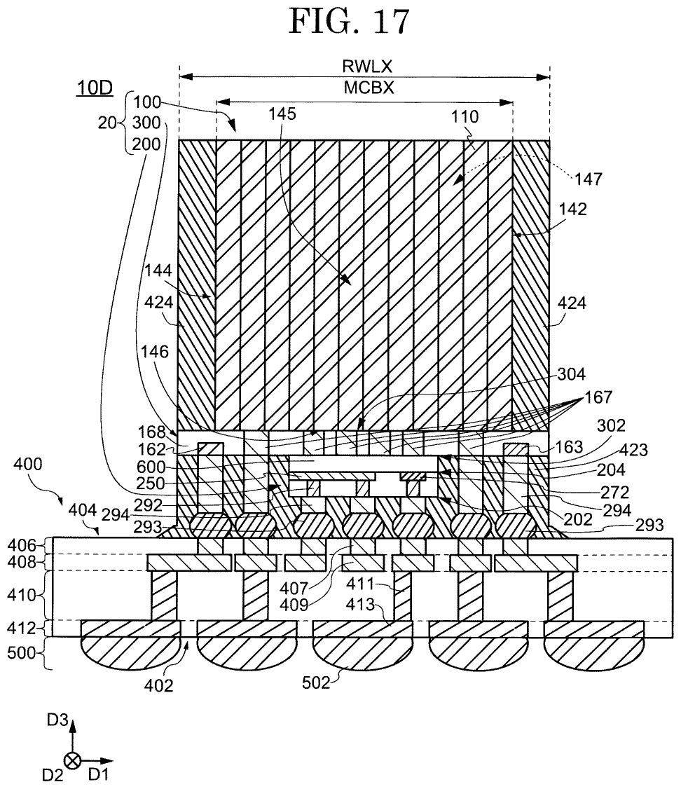

FIG. 17 is a diagram showing an exemplary embodiment of a semiconductor module 10D. FIG. 17 is a cross-sectional view showing a mounting example of the semiconductor module 10D according to a fifth embodiment of the present disclosure. Descriptions of the same or similar configurations as those in FIG. 1 to FIG. 16 will be omitted.

As shown in FIG. 17, the semiconductor module 10D includes the structure 20, the wiring substrate 400, the pillars 294, the bumps 293, the molding material 423, the molding material 424, and the bump layer 500. The structure 20 includes the memory cube 100, the rewiring layer 300, the logic chip 200, and the adhesive layer 600. The length RWLX of the rewiring layer 300 in the direction D1 is longer than the length MCBX of the memory cube 100 in the direction D1.

In the semiconductor module 10D, the second surface 204 of the logic chip 200 and the first surface 302 of the fan-out type rewiring layer 300 are bonded using the adhesive layer 600. In addition, the logic chip 200 includes a configuration and a function similar to those of the semiconductor module 10A. The semiconductor module 10D has the same configuration and function as the semiconductor module 10C except for the configuration using the adhesive layers 600 and the configuration and function of the logic chip 200. Therefore, in the description of the semiconductor module 10D, the description of the same configuration and function as those of the semiconductor modules 10B and 10C will be omitted.

The semiconductor module 10D may be implemented as described above. In the semiconductor module 10D, as in the case of the semiconductor module 10C, the wiring (side wiring) can be formed on the side surface in a simple process, and a distance between each memory chip 110 and the logic chip 200 can be kept close and constant. Therefore, by using the semiconductor module 10D, a low power consumption and large capacity memory can be realized.

In addition, in the semiconductor module 10D, the memory cube 100 and the logic chip 200 can communicate (electrically connected) using inductor communication, similar to the semiconductor module 10A. Therefore, in the semiconductor module 10D, by using the contactless inductor communication, the load caused by the wiring resistance and the parasitic capacitance between the memory chip 110 and the logic chip 200 is suppressed, so that the power consumed by the semiconductor module 10D can be further suppressed.

Further, in the semiconductor module 10D, the memory cube 100, the rewiring layer 300, and the logic chip 200 are bonded to each other using the adhesive layer 600, and the structure 20 and the wiring substrate 400 can be electrically connected to each other and fixed to each other using the wiring (side wiring) formed in the memory cube 100 and the fan-out type rewiring layer 300, the pillars 294 and the bumps 293, and the molding materials 423 and 424. That is, in the semiconductor module 10C, the degree of freedom in design of the memory cube 100 is improved based on the wiring (side wiring) formed in the memory cube 100 and the rewiring layer 300, and can be implemented differently from the first embodiment to the fourth embodiment.

### 6. Sixth Embodiment

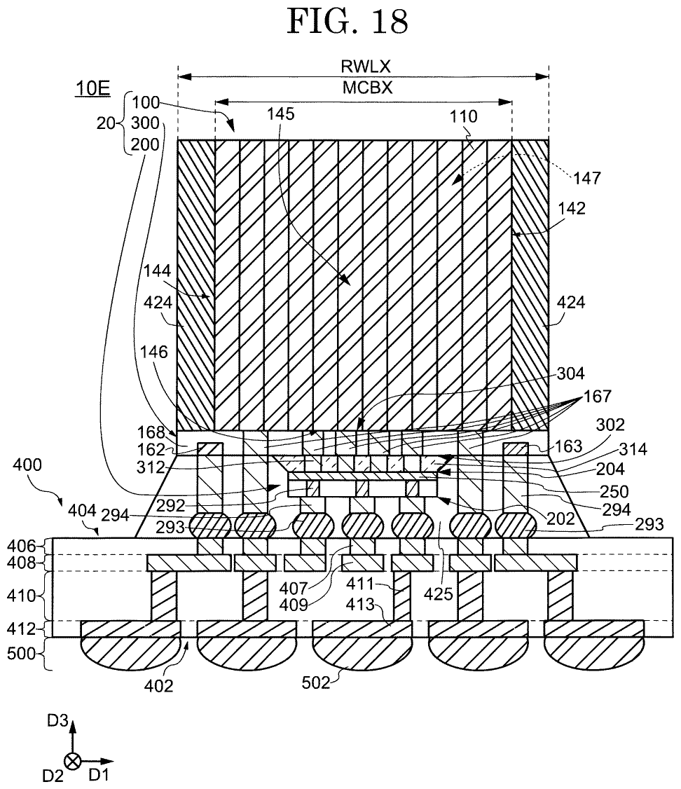

FIG. 18 is a diagram showing a mounting example of a semiconductor module 10E. FIG. 18 is a cross-sectional view of the semiconductor module 10E according to a sixth embodiment of the present disclosure. The same or similar configurations as those in FIG. 1 to FIG. 17 will not be described here.

The semiconductor module 10E includes the structure 20, the wiring substrate 400, the pillars 294, the bumps 293, a UF agent 425, and the bump layer 500. The structure 20 is configured to include the memory cube 100, the rewiring layer 300, the logic chip 200, the plurality of pillars 312, and the UF agent 314. The length RWLX of the rewiring layer 300 in the direction D1 is longer than the length MCBX of the memory cube 100 in the direction D1.

In the semiconductor module 10E, the structure 20 and the wiring substrate 400 are electrically connected by using the pillars 294 and the bumps 293, and the structure 20 and the wiring substrate 400 are fixed to each other by using the UF agent 425. More specifically, the logic chip 200 electrically connected to and fixed to the rewiring layer 300 using the FC mounting technique, and the plurality of pillars 294 and the plurality of bumps 293 electrically connecting the rewiring layer 300 and the logic chip 200 to the wiring substrate 400 are fixed to the rewiring layer 300 and the wiring substrate 400 and are protected by using the UF agent 425. The semiconductor module 10E has the same configuration and function as those of the semiconductor module 10C except for the electric coupling described above and fixing using the UF agent 425. Therefore, in the description of the semiconductor module 10E, the description of the same configuration and function as those of the semiconductor module 10C will be omitted.

The semiconductor module 10E is implemented as described above. In the semiconductor module 10E, as in the case of the semiconductor module 10C, the wiring (side wiring) can be formed on the side surface in a simple process, and a distance between each memory chip 110 and the logic chip 200 can be kept close and constant. Therefore, by using the semiconductor module 10E, a low power consumption and large capacity memory can be realized.

Further, in the semiconductor module 10E, the structure 20 and the wiring substrate 400 can be electrically connected to each other and fixed to each other by using the wiring (side wiring) formed in the memory cube 100 and the fan-out type rewiring layer 300, the pillar 294, the bump 293, the molding material 424, and the UF agent 425. That is, in the semiconductor module 10E, the degree of freedom in design of the memory cube 100 is improved based on the memory cube 100 and the wiring (side wiring) formed in the rewiring layer 300, and can be implemented differently from the first embodiment to the fifth embodiment.

### 7. Seventh Embodiment

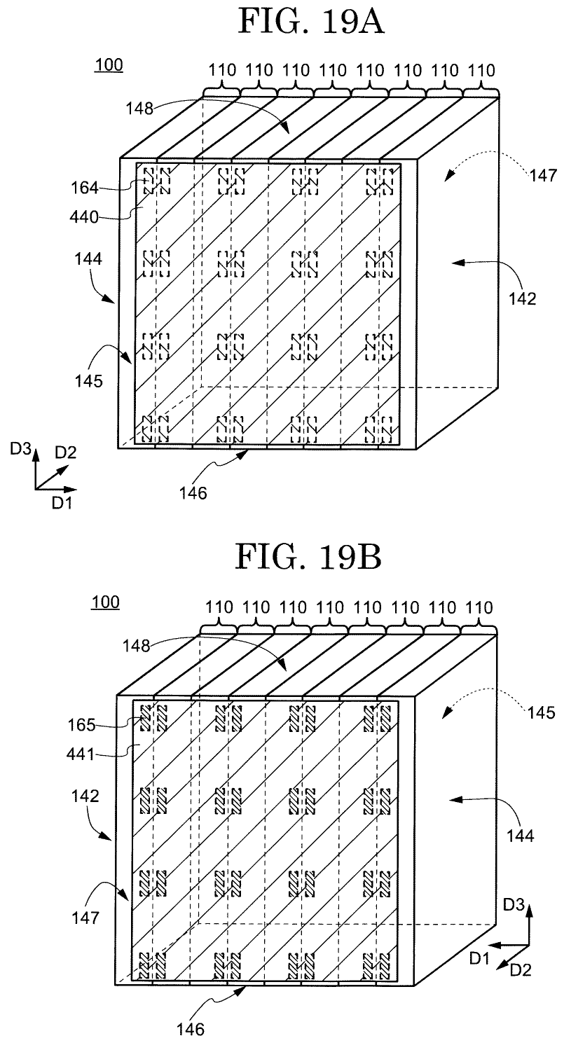

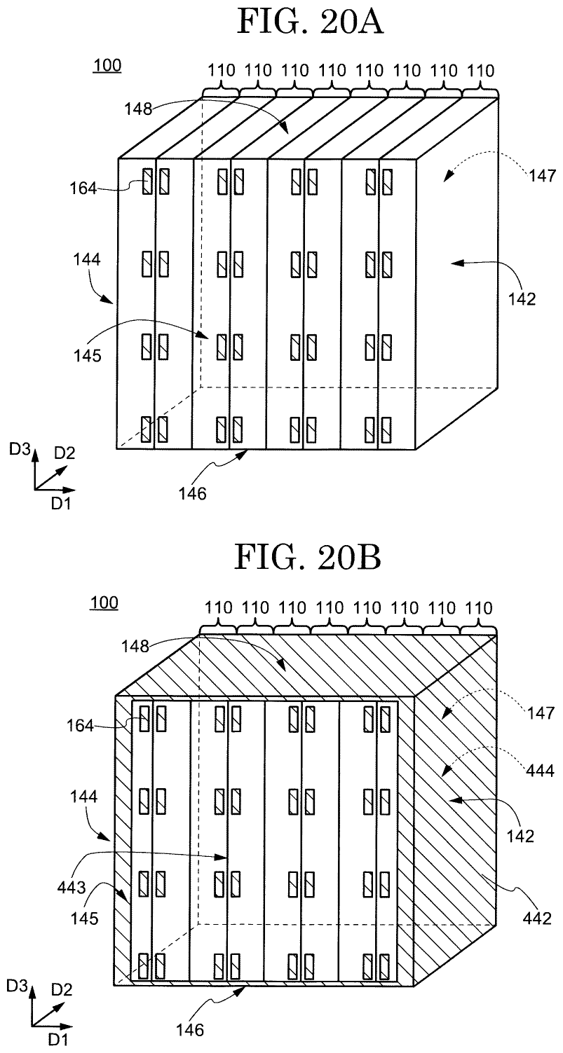

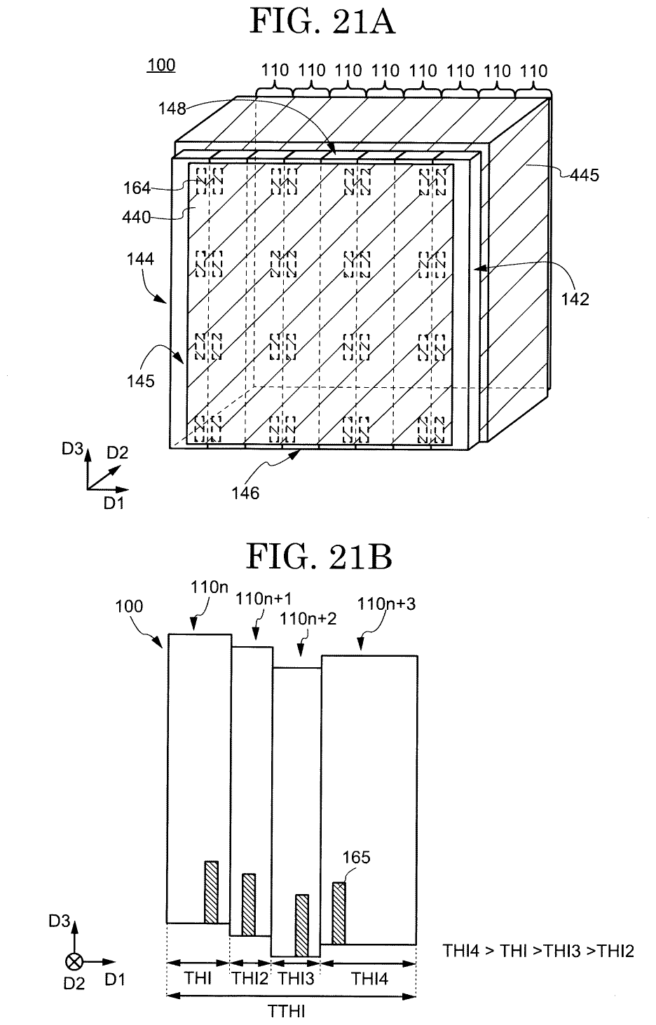

A method for manufacturing a conductive film on a side surface of the semiconductor module 10 will be described referring to FIG. 19A and FIG. 21A. FIG. 19A is a perspective view showing a conductive film 440 formed on the second side surface 145 of the memory cube 100 according to a seventh embodiment of the present invention. FIG. 19B is a perspective view showing a conductive film 441 formed on the fourth side surface 147 of the memory cube 100. FIG. 20A to FIG. 21A are perspective views showing a method for manufacturing the conductive film 440 on the second side surface 145 of the memory cube 100 according to the seventh embodiment of the present disclosure. The same or similar configurations as those in FIG. 1 to FIG. 18 will not be described here.

The memory cube 100 includes a configuration similar to the configuration described in “1-1. Overview of Semiconductor Module 10” and “1-2. Example of Manufacturing Method of Memory Cube 100”. As shown in FIG. 19A or FIG. 19B, the memory cube 100 includes the conductive film 440 arranged on the second side surface 145 and the conductive film 441 arranged on the fourth side surface 147. The conductive film 440 arranged on the second side surface 145 is electrically connected to the plurality of power wirings 164 exposed on the second side surfaces 145 of the plurality of memory chips 110, and is in contact with the second side surfaces 145 of the plurality of memory chips 110. The conductive film 441 arranged on the fourth side surface 147 is electrically connected to the plurality of ground wirings 165 exposed on the fourth side surfaces 147 of the plurality of memory chips 110, and is in contact with the fourth side surfaces 147 of the plurality of memory chips 110. The conductive film 440 and the conductive film 441 include a conductor made of a metal material, and are, for example, a conductor containing copper, tin, or the like.

The conductive film 440 and the conductive film 441 are formed on the second side surface 145 and the fourth side surface 147 using a similar manufacturing method. Therefore, in the following description, a method for manufacturing the conductive film 440 is mainly described.

As described in “1-2. Example of Manufacturing Method of Memory Cube 100”, the first side surface 146, the second side surface 145, the third side surface 148, and the fourth side surface 147 of the memory cube 100 are polished. In the memory cube 100 according to the seventh embodiment, the end surfaces of the plurality of power wirings 164 are exposed on the second side surface 145 (see FIG. 20A), and the end surfaces of the plurality of ground wirings 165 are exposed on the fourth side surface 147.

Next, a resist 442 is applied to the first surface 142, the second surface 144, the first side surface 146, the second side surface 145, the third side surface 148, and the fourth side surface 147. Further, resists 442 of opening regions 443 and 444 are removed, the end surfaces of the plurality of power wirings 164 are exposed on the second side surface 145, and the end surfaces of the plurality of ground wirings 165 are exposed on the fourth side surface 147 (see FIG. 20B).

Next, for example, the conductive film 440 is formed on the end surfaces of the second side surface 145 and the plurality of power wirings 164 exposed in the opening region 443 by electric field plating (plating method), the conductive film 441 is formed on the end surfaces of the fourth side surface 147 and the plurality of ground wirings 165 exposed in the opening region 444, and the resist 442 is removed (see FIG. 19A or FIG. 19B).

Next, a conductive film 445 may be formed so as to be in contact with the first surface 142, the second surface 144, and the third side surface 148 except for the first side surface 146, the second side surface 145, and the fourth side surface 147 by using the same manufacturing methods as the conductive film 440 and the conductive film 441 (see FIG. 21A). Further, although not shown, the conductive film 445 may be formed on the first surface 142 and the second surface 144.

Although not shown, the conductive films 440, 441, or 445 are electrically connected by using the plurality of side power wirings 162 (see, for example, FIG. 8B and FIG. 16 to FIG. 18) or the plurality of side ground wirings 163 (see, for example, FIG. 8B and FIG. 16 to FIG. 18) formed in the rewiring layers 300 (see, for example, FIG. 8B and FIG. 16 to FIG. 18). The conductive films 440, 441, or 445 are electrically connected to, for example, an external circuit (not shown) and are supplied with the power supply voltage VDD, the voltage VSS, and the like.

By using the method for manufacturing the conductive film on the side surface of the semiconductor module 10 described above, it is possible to form the wiring on the side surface in a simpler process than the manufacturing method for forming each wiring using a complicated process Further, by using the method for manufacturing the while aligning. conductive film on the side surface of the semiconductor module 10, the conductive film can be formed on substantially the entire side surface of the memory cube 100. Consequently, a volume of the supply path such as the power supply voltage VDD and the voltage VSS to the memory cube 100 can be increased, and thus the power supply capability to the memory cube 100 is improved. In addition, since the volume of the conductive film on the surface of the semiconductor module 10 can be increased, a heat dissipation path of the semiconductor module 10 can be increased, and improvement of thermal resistance can be suppressed. That is, heat from the semiconductor module 10 is easily dissipated.

### 8. Eighth Embodiment

An example of the memory cube 100 including a plurality of memory chips of differing thicknesses will be described with respect to FIG. 21B. FIG. 21B is a schematic diagram showing the memory cube 100 according to an eighth embodiment of the present disclosure. The same or similar configurations as those in FIG. 1 to FIG. 21A will not be described here. The memory cube 100 includes, for example, the memory chips 110n to 110n+3, and has a configuration similar to that described in “1-2. Example of Manufacturing Method of Memory Cube 100”. That is, in the memory cube 100, the memory chip 110n and the memory chip 110n+1 are F2F bonded, the memory chip 110n+2 and the memory chip 110n+3 are F2F bonded, and the memory chip 110n+1 and the memory chip 110n+2 are B2B bonded (see FIG. 21B).

As shown in FIG. 21B, a thickness of each chip of the memory chips 110n to 110n+3 may be different when the memory chips 110n to 110n+3 are stacked. For example, a thickness THI4 of the memory chip 110n+3 is larger than a thickness THI of the memory chip 110n, the thickness THI of the memory chip 110n is larger than a thickness THI3 of the memory chip 110n+2, and the thickness THI3 of the memory chip 110n+2 is larger than a thickness THI2 of the memory chip 110n+1. In the example shown in FIG. 21B, although the thickness of each chip of the memory chips 110n to 110n+3 is different, it is sufficient that the thickness of at least one of the plurality of memory chips is different from the thickness of the other memory chips.

In the semiconductor module 10, the memory cube 100 can be manufactured by stacking the plurality of memory chips 110 having different thicknesses. Consequently, a total thickness TTHI of the memory cubes 100 can be aligned between the different memory cubes 100. That is, in the semiconductor module 10, variations in the total thickness TTHI between the memory cubes 100 can be suppressed.

### 9. Ninth Embodiment

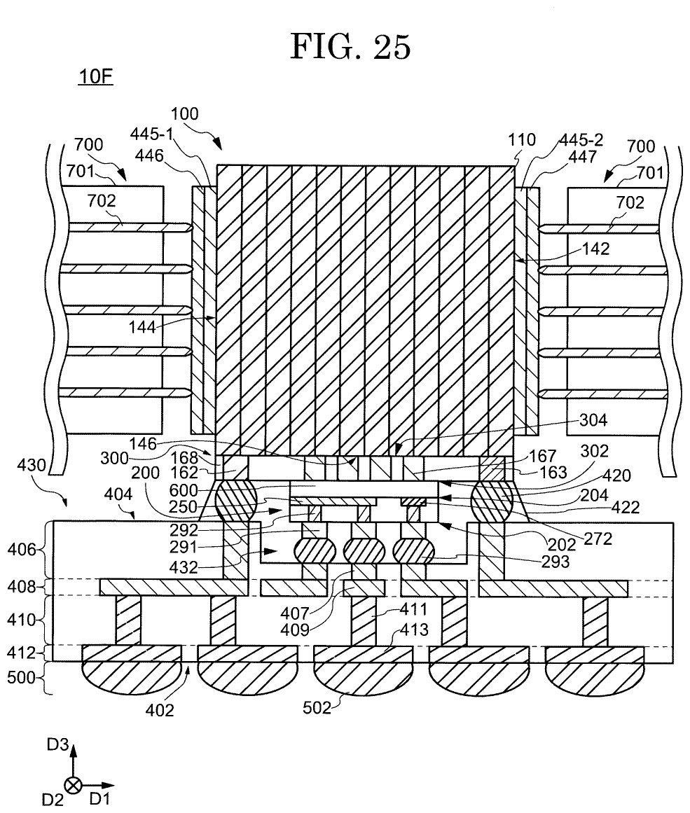

A mounting example of a semiconductor module will be described with reference to FIG. 25 to FIG. 27. FIG. 25 to FIG. 27 are cross-sectional views showing a mounting example of semiconductor modules 10F to 10H according to a ninth embodiment of the present disclosure. The diagram of the semiconductor modules 10F to 10H shown in FIG. 25 to FIG. 27 is a diagram showing, by way of example, an implementation format of power supply to the conductive film 445 arranged on the first surface 142 and the conductive film 445 arranged on the second surface 144 of the memory cube 100 described with reference to FIG. 21A of the semiconductor module 10A described with reference to FIG. 13. Descriptions of the same or similar configurations as those in FIG. 1 to FIG. 24B will be omitted. Except for the implementation format of the power supply of the semiconductor modules 10F to 10H, the configuration is the same as the configuration of the semiconductor module 10A and the like described with reference to FIG. 13, FIG. 19A and FIG. 19B, and therefore, an implementation format of the power supply of the semiconductor modules 10F to 10H is mainly described here.

As shown in FIG. 25, the semiconductor module 10F includes a conductive film 445-1, a conductive film 445-2, a conductive film 446, a conductive film 447, and a pogo pin pressure bonding mechanism 700. The semiconductor module 10F supplies power to the memory cube 100, for example, using the pogo pin pressure bonding mechanism 700.

As an example, the conductive film 445-1 is formed on the first surface 142, and the conductive film 445-2 is formed on the second surface 144. The conductive film 446 is formed on the conductive film 445-1, and the conductive film 447 is formed on the conductive film 445-2. The conductive films 445-1 and 445-2 and the conductive films 446 and 447 are formed by, for example, electric field plating (plating method). The conductive films 445-1 and 445-2 include a conductor made of a metal material, and include, for example, a conductor containing copper, silver, nickel, or the like. The conductive films 446 and 447 include a conductor made of a metal material, and include, for example, a conductor containing gold, tin, nickel, or the like.

As an example, the conductive film 445 is formed on the first surface 142 and the second surface 144 by electric field plating (plating method). The conductive film 445 includes a conductor made of a metal material, and includes, for example, a conductor containing copper, silver, nickel, or the like.

The pogo pin pressure bonding mechanism 700 includes a pogo pin support part 701 and a plurality of pogo pins 702. The pogo pin support part 701 includes the plurality of pogo pins 702 and has a function of supporting the plurality of pogo pins 702. Each of the plurality of pogo pins 702 is a connector composed of a terminal part, a cylindrical member connected to the terminal part, and an elastic member inserted into the cylindrical member, and the like.

The pogo pin pressure bonding mechanism 700 crimps each of the plurality of pogo pins 702 to the conductive film 446 and the conductive film 447, and connects each of the plurality of pogo pins 702 to the conductive film 446 and the conductive film 447. Consequently, the pogo pin pressure bonding mechanism 700 can externally supply voltages (for example, the power supply voltage VDD and the voltage VSS) to the plurality of pogo pins 702 and supply voltages to the memory cube 100 through the plurality of pogo pins 702.

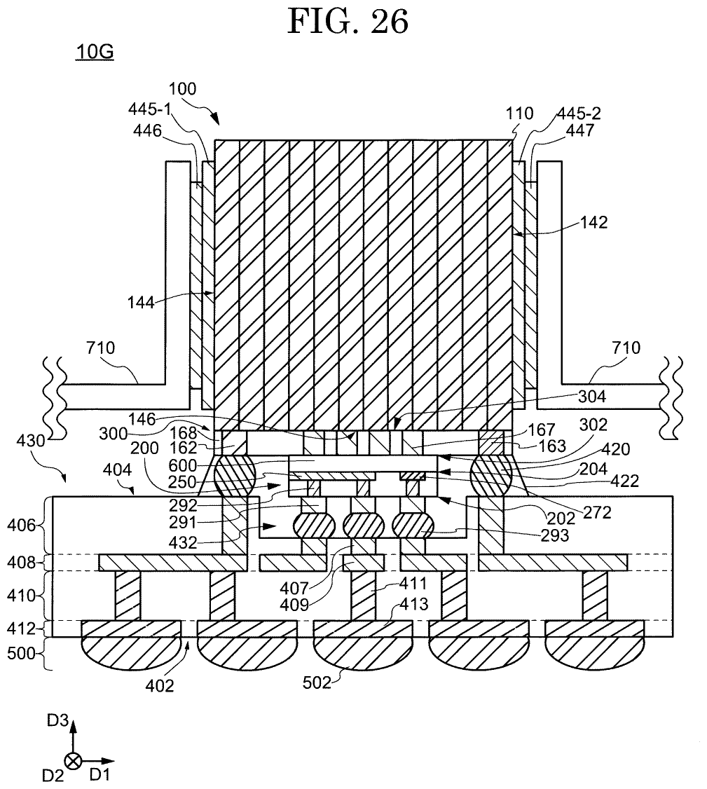

As shown in FIG. 26, the semiconductor module 10G includes the conductive film 445-1, the conductive film 445-2, the conductive film 446, the conductive film 447, and an L-shaped member 710. For example, in the semiconductor module 10G, the conductive film 445-1, the conductive film 445-2, the conductive film 447, and the conductive film 446 are formed in the same manner as in the semiconductor module 10F. The L-shaped member 710 includes a conductor made of a metal material, and includes, for example, a conductor including copper or the like.

The L-shaped member 710 is connected to the conductive film 446 and the conductive film 447. Consequently, in the semiconductor module 10G, a voltage (for example, the power supply voltage VDD and the voltage VSS) is supplied from the outside to a plurality of L-shaped members 710, and the memory cube 100 is supplied with the voltage through the plurality of L-shaped members 710.

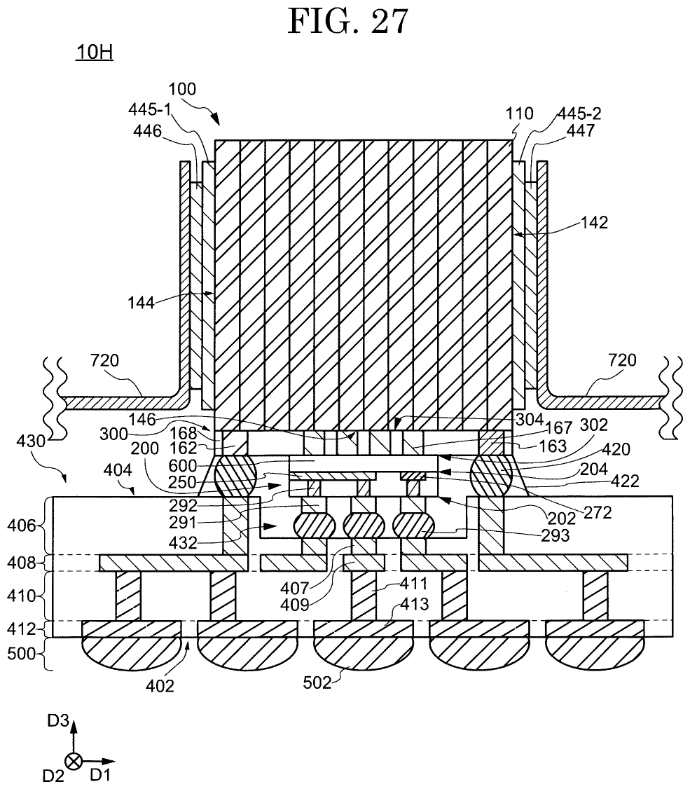

As shown in FIG. 27, the semiconductor module 10H includes the conductive film 445-1, the conductive film 445-2, the conductive film 446, the conductive film 447, and a flexible substrate 720. For example, in the semiconductor module 10H, the conductive film 445-1, the conductive film 445-2, the conductive film 447, and the conductive film 446 are formed in the same manner as in the semiconductor modules 10F and 10G.

The flexible substrate 720 is connected to the conductive film 446 and the conductive film 447. Consequently, in the semiconductor module 10H, the voltage (for example, the power supply voltage VDD and the voltage VSS) is supplied from the outside to the flexible substrate 720, and the memory cube 100 is supplied with the voltage through the flexible substrate 720.

### 10. Tenth Embodiment

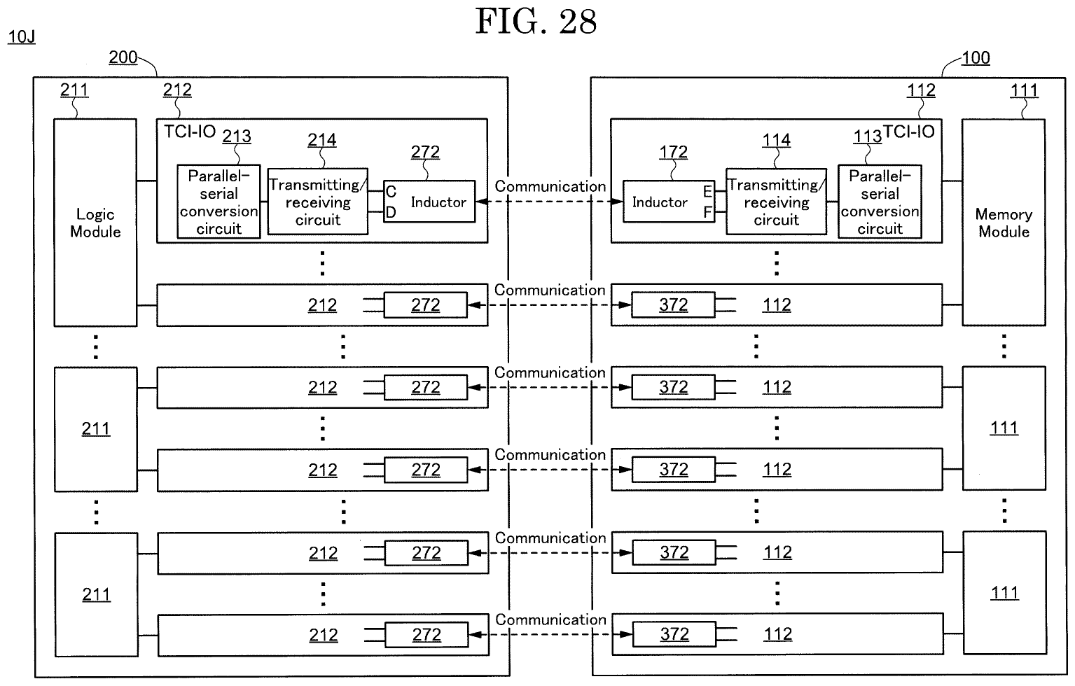

A mounting example of a semiconductor module 10J according to a tenth embodiment, an example of a configuration of signal transmission wirings 166b included in the seal ring 160 and the memory chip 110 of the semiconductor module 10J, and an example of the configuration of inductors 372, 372f, and 372g included in the seal ring 160 and the memory chip 110 of the semiconductor module 10J will be described referring to FIG. 28 to FIG. 40.

### 10-1. Mounting Example of Semiconductor Module 10J

A mounting example of the semiconductor module 10J will be described referring to FIG. 28. FIG. 28 is a diagram showing a configuration of the semiconductor module 10J according to the tenth embodiment of the present disclosure. The explanation of the mounting example of the semiconductor module 10J with reference to FIG. 28 mainly describes differences from the semiconductor module 10B described with reference to FIG. 14. Configurations that are the same as or similar to those in FIG. 1 to FIG. 27 will be described as necessary.

The inductor 172 of the semiconductor module 10B is mainly included in the rewiring layer 300, and the inductor 172 is electrically connected to the transmitting/receiving circuit 114 using the terminal A and the terminal B, whereas the inductor 372 of the semiconductor module 10J is mainly included in the memory cube 100, and the inductor 372 is electrically connected to the transmitting/receiving circuit 114 using a terminal E and a terminal F. Similar to the inductor 172, the inductor 372 has a function of performing inductor communication with the inductor 272 of the logic chip 200 in a non-contact manner. Configurations of the semiconductor module 10J other than the inductor 372 with reference to FIG. 28 are the same as the configurations of the semiconductor module 10B described with reference to FIG. 14, and will not be described here.

### 10-2. Example of Signal Transmission Wiring 166b and Inductor 372

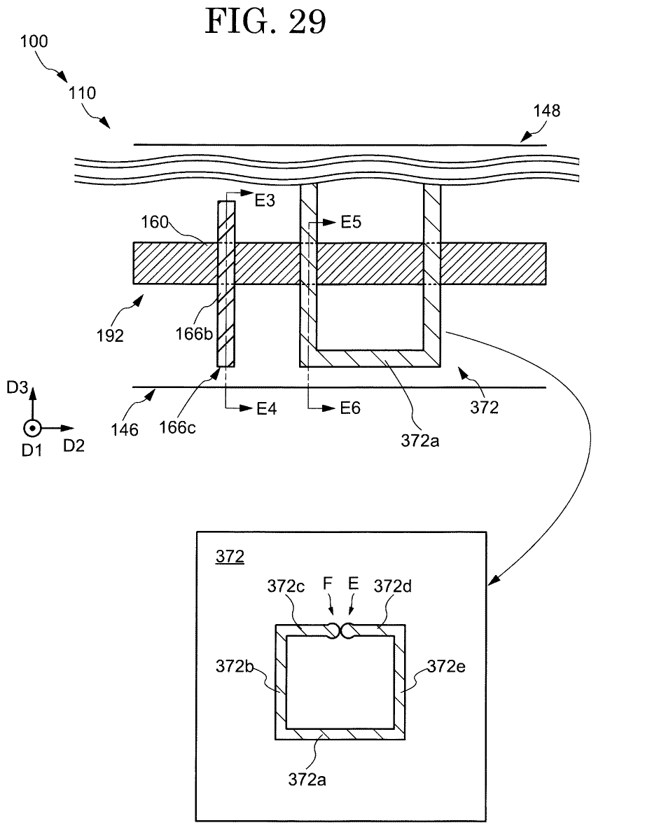

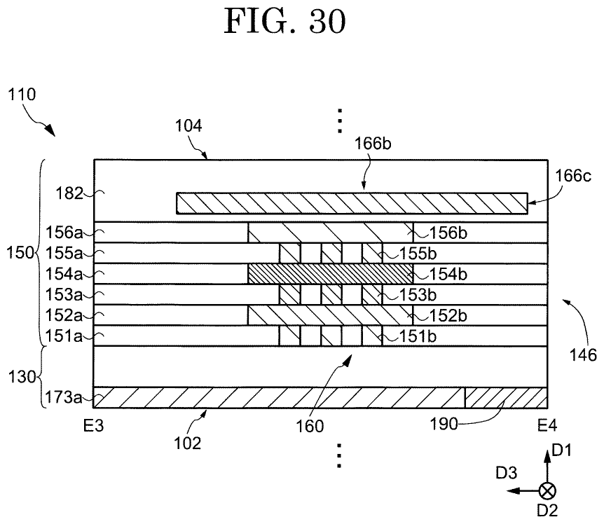

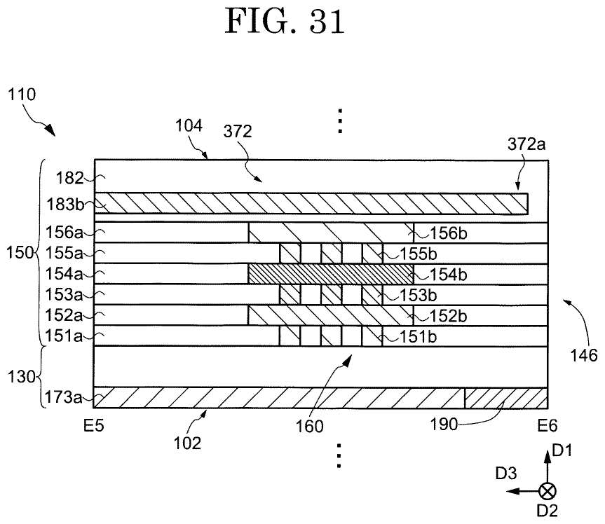

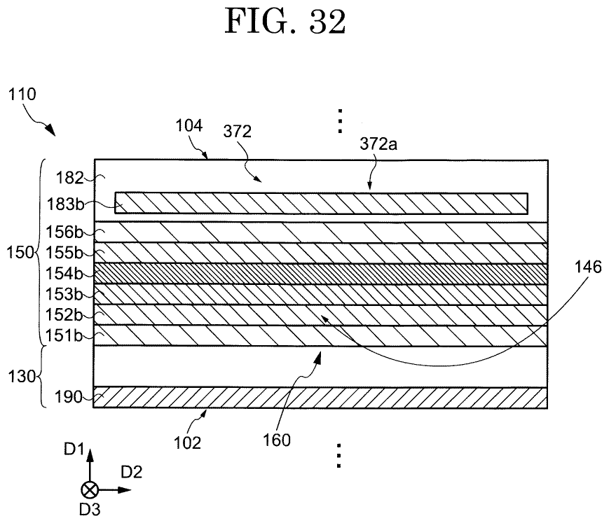

Examples of the signal transmitting wiring 166b and an inductor 372 of the semiconductor module 10J will be described referring to FIG. 29 to FIG. 32. FIG. 29 is a plan view showing configurations of the seal ring 160, the signal transmission wiring 166b, and the inductor 372. FIG. 30 is a cross-sectional view of the seal ring 160 and the signaling wiring 166b taken along a line E3-E4 of FIG. 29. FIG. 31 is a cross-sectional view of the seal ring 160 and the inductor 372 taken along a line E5-E6 of FIG. 29. FIG. 32 is a cross-sectional view of the seal ring 160 and the inductor 372 shown in FIG. 29 when viewed from a depth direction from the first side surface 146 toward the third side surface 148. Configurations that are the same as or similar to those in FIG. 1 to FIG. 28 will be described as necessary.

First, a signal transmission wiring 166b of the semiconductor module 10J will be described. The signal transmission wiring 166b is parallel to the first surface 102 and the second surface 104. An end part 166a of the signal transmission wiring 166 may include a portion exposed to the first side surface 146 (the insulating layer 182), and may include a portion not exposed to the first side surface 146 (the insulating layer 182). For example, although the end part 166a of the signal transmission wiring 166 described in FIG. 11A and FIG. 11B is shown to include a portion exposed to the first side surface 146 (insulating layer 182), an end part 166c of the signal transmission wiring 166b shown in FIG. 29 and FIG. 30 includes a portion not exposed to the first side surface 146 (insulating layer 182). Further, the signal transmission wiring 166b is formed by using a wiring 183b so as to overlap the seal ring 160 and straddle the seal ring 160. The wiring 183b is formed on the same surface as the wiring 183 (see FIG. 11A).

The configuration shown in FIG. 29 and FIG. 30 is the same as the configuration shown in FIG. 11A and FIG. 11B except that the end part 166c of the signal transmission wiring 166b is not exposed to the first side surface 146, and therefore, the explanation thereof will be omitted. Similar to the signal transmission wiring 166b, a portion of the ground wiring 165 (see FIG. 8A or FIG. 8B) of the memory chip 110 and a portion of the power wiring 164 (see FIG. 8A or FIG. 8B) may include a portion exposed to the first side surface 146, and may include a portion not exposed to the first side surface 146. For example, the ground wiring 165 and the power wiring 164 that are not connected to the wiring layer (wiring) formed in the rewiring layer 300 are not exposed to the first side surface 146.

Next, the inductor 372 of the semiconductor module 10J will be described. The inductor 372 shown in FIG. 29 includes the terminal E, the terminal F, a first part 372a, a second part 372b, a third part 372c, a fourth part 372e, and a fifth part 372d. The inductor 372 is an example of a one-turn inductor when viewed from the second surface 104 of the memory chip 110 through the memory chip 110 along the direction D1. The fifth part 372d extends in the direction D2, one end of the fifth part 372d is electrically connected to the terminal E, and the other end of the fifth part 372d is electrically connected to one end of the fourth part 372e. The fourth part 372e extends in the direction D3 and the other end of the fourth part 372e is electrically connected to one end of the first part 372a. The first part 372a extends in the direction D2 and the other end of the first part 372a is electrically connected to one end of the second part 372b. The second part 372b extends in the direction D3 and the other end of the second part 372b is electrically connected to one end of the third part 372c. The third part 372c extends in the direction D2 and the other end of the third part 372c is electrically connected to the terminal F.

As shown in FIG. 29 and FIG. 31, the inductor 372 is parallel to the first surface 102 and the second surface 104. The first part 372a of the inductor 372 corresponds to an end portion of the inductor 372 closer to the first side surface 146. The first part 372a is not exposed to the first side surface 146 as is the case with the end part 166c of the signal transmission wiring 166b. In addition, the inductor 372 is formed so as to overlap the seal ring 160 and straddle the seal ring 160, similar to the signal transmission wiring 166b. That is, a length of the seal ring 160 extending along the direction D3 is shorter than a length of the inductor 372 extending along the direction D3. The inductor 372 is formed using a wiring 183c. The wiring 183c is formed on the same surface as the wiring 183b and the wiring 183.

Further, as shown in FIG. 32, the inductor 372 and the seal ring 160 viewed through the depth direction from the first side surface 146 toward the third side surface 148 are stacked upward from the transistor layer 130 side along the direction D1. The vias 151b, 153b, and 155b forming the seal ring 160 and the wirings 152b, 154b, and 156b forming the seal ring 160 extend along the direction D2, and lengths of the vias 151b, 153b, and 155b and the wirings 152b, 154b, and 156b along the direction D2 is longer than a length of the first part 372a of the inductor 372 along the direction D2. In addition, similar to the length of the first part 372a of the inductor 372 along the direction D2, the length of the vias 151b, 153b, and 155b and the wirings 152b, 154b, and 156b forming the seal ring 160 along the direction D2 is longer than the length of the end part 166c of the signal transmission wiring 166b along the direction D2. In addition, in a cross-sectional view of the semiconductor module 10J, the inductor 372 and the seal ring 160 may be stacked upward from the transistor layer 130 along the direction D1 as shown in FIG. 32, and the lengths of the vias 151b, 153b, and 155b and the wirings 152b, 154b, and 156b forming the seal ring 160 along the direction D2 may be longer than the length of the first part 372a of the inductor 372 along the direction D2.

In addition, although one inductor 372 is shown in FIG. 29 and FIG. 31, the memory chip 110 includes a plurality of inductors 372. For example, the inductors 372 are arranged side by side along the direction D2.

The semiconductor module 10J includes the configuration described above. As a consequence, the insulating layer 182 and the seal ring 160 prevent the plurality of power wirings 164, the plurality of ground wirings 165, and the plurality of signal transmission wirings 166b from absorbing moisture from the first side surface 146 and from corroding or deteriorating the wiring due to the intrusion of impurities or the like.

Also, the inductor 372 is covered by the insulating layer 182 and is not exposed to the side surface of the memory cube 100. Further, the inductor 372 is formed to straddle the seal ring 160 and be shorter than the seal ring 160 when viewed from the first side surface 146. As a consequence, in the inductor 372, as in the case of the signal transmission wiring 166b, the insulating layer 182 and the seal ring 160 suppress moisture absorption, corrosion, deterioration, and the like of the wiring due to the entry of impurities and the like.

In addition, by suppressing moisture absorption, corrosion, deterioration, and the like of the wiring due to the intrusion of impurities and the like, insulation between adjacent inductors 372 is ensured, and short circuits between adjacent inductors 372 are suppressed. As a result, a distance between the adjacent inductors 372 and the distance between the inductors 372 and 272 can be shortened. Therefore, the semiconductor module 10J can increase the number of inductors 372 in the memory chip 110 and improve the communication between the inductor 372 and the inductor 272.

Further, since the inductor 372 is not exposed to the respective side surfaces of the memory cube 100, breakage of the inductor 372 can be suppressed by ESD. Consequently, for example, since an ESD protection circuit of the inductor 372 is not required, power consumption caused by the ESD protection circuit is suppressed, and power consumption of the semiconductor module 10J is reduced. In addition, a delay caused by the ESD protection circuit is suppressed, and the semiconductor module 10J can operate at high speed.

Therefore, reliability of the semiconductor module 10J can be maintained without impairing long-term reliability.

### 10-3. Another Example of Inductor 372 (Inductor 372f)

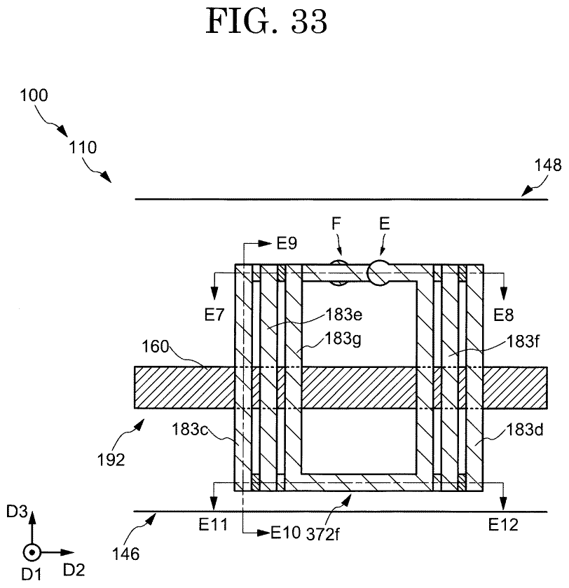

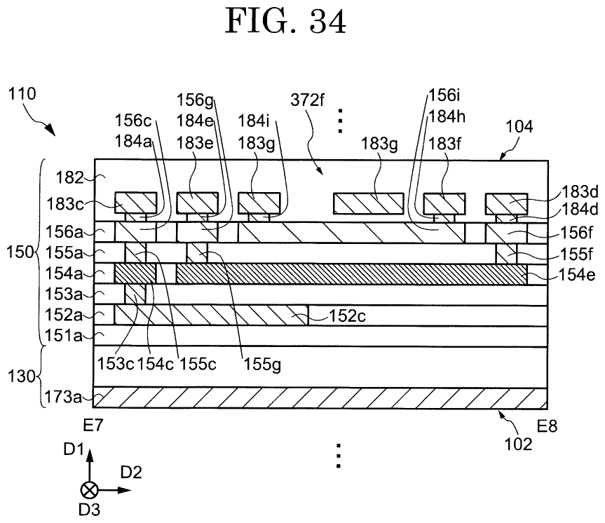

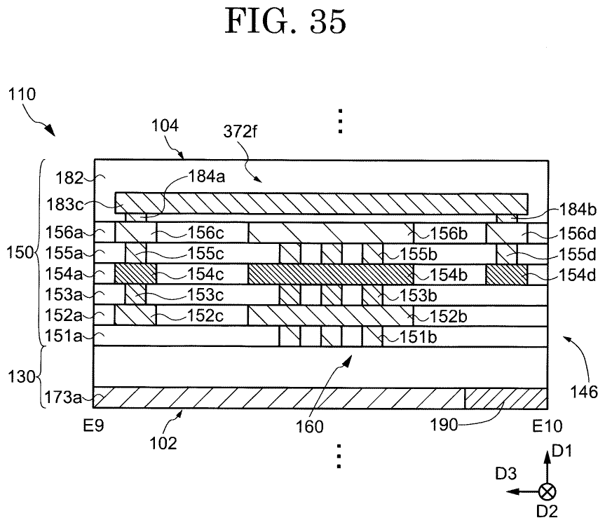

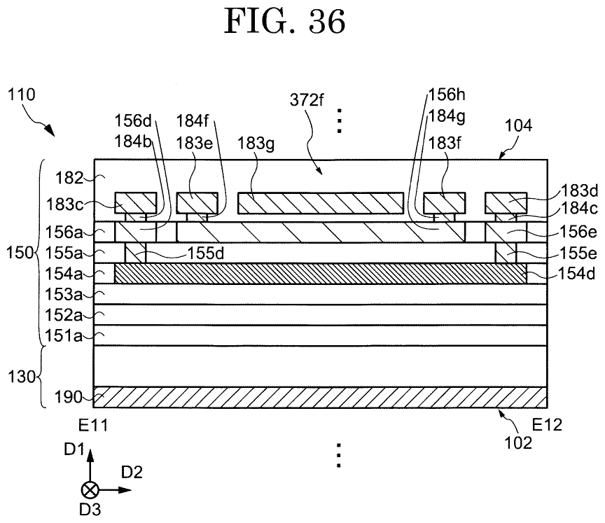

The inductor 372f of the semiconductor module 10J will be described referring to FIG. 33 to FIG. 36. FIG. 33 is a plan view showing an example of a configuration of the seal ring 160 and the inductor 372f. FIG. 34 is a cross-sectional view of the inductor 372f taken along a line E7-E8 of FIG. 33. FIG. 35 is a cross-sectional view of the seal ring 160 and the inductor 372f taken along a line E9-E10 of FIG. 33. FIG. 36 is a cross-sectional view of the inductor 372f taken along a line E11-E12 of FIG. 33. Configurations that are the same as or similar to those in FIG. 1 to FIG. 32 will be described as necessary.

The inductor 372f shown in FIG. 33 to FIG. 36 includes the terminal E, the terminal F, a wiring 152c, a via 153c, a wiring 154c, a via 155c, a wiring 156c, a via 184a, the wiring 183c, a via 184b, a wiring 156d, a via 155d, a wiring 154d, a via 155e, a wiring 156e, a via 184c, a wiring 183d, a via 184d, a wiring 156f, a via 155f, a wiring 154e, a via 155g, a wiring 156g, a via 184e, a wiring 183e, a via 184f, a wiring 156h, a via 184g, a wiring 183f, a via 184h, a wiring 156i, a via 184i, and a wiring 183g. The inductor 372f is an example of a three-turn inductor when the memory chip 110 is viewed through the second surface 104 of the memory chip 110 along the direction D1. The inductor 372f is parallel to the first surface 102 and the second surface 104.

The wiring 152c is formed in the same layer as the wiring 152b, and the via 153c is formed in the same layer as the via 153b. The wiring 154c, the wiring 154d, and the wiring 154e are formed in the same layer as the wiring 154b. The via 155c, the via 155d, the via 155e, the via 155f, and the via 155g are formed in the same layer as the via 155b. The wiring 156c, the wiring 156d, the wiring 156e, the wiring 156f, the wiring 156g, the wiring 156h and the wiring 156i are formed in the same layer as the wiring 156b. The wiring 183c, the wiring 183d, the wiring 183e, the wiring 183f, and the wiring 183g are formed on the same layer as the wiring 183b.

The via 184a, the via 184b, the via 184c, the via 184d, the via 184e, the via 184f, the via 184g, the via 184h, and the via 184i are formed between the layer where the insulated layer 156a and wirings 156b to 156i are formed and the layer where the wiring 183c, wiring 183d, wiring 183e, wiring 183f, and wiring 183g are formed in the direction D1.

The wiring 152c extends in the direction D2, one end of the wiring 152c is electrically connected to the terminal F, and the other end of the wiring 152c is electrically connected to the via 153c. The via 153c, the wiring 154c, the via 155c, the wiring 156c, and the via 184a extend in the direction D1 and are electrically connected to each other. The via 184a is electrically connected to one end of the wiring 183c. The wiring 183c extends in the direction D3, and the other end of the wiring 183c is electrically connected to the via 184b. The wiring 183c is configured to overlap the seal ring 160 and straddle the seal ring 160.

The via 184b, the wiring 156d, and the via 155d extend in the direction D1 and are electrically connected to each other. The via 155d is electrically connected to one end of the wiring 154d. The wiring 154d extends in the direction D2, and the other end of the wiring 154d is electrically connected to the via 155e. The via 155e, the wiring 156e, and the via 184c extend in the direction D1 and are electrically connected to each other. The via 184c is electrically connected to one end of the wiring 183d. The wiring 183d extends in the direction D3, and the other end of the wiring 183d is electrically connected to the via 184d. The wiring 183d is configured to overlap the seal ring 160 and straddle the seal ring 160.

The via 184d, the wiring 156f, and the via 155f extend in the direction D1 and are electrically connected to each other. The via 155f is electrically connected to one end of the wiring 154e. The wiring 154e extends in the direction D2, and the other end of the wiring 154e is electrically connected to the via 155g. The via 155g, the wiring 156g, and the via 184e extend in the direction D1 and are electrically connected to each other. The via 184e is electrically connected to one end of the wiring 183e. The wiring 183e extends in the direction D3, and the other end of the wiring 183e is electrically connected to the via 184f. The wiring 183e is configured to overlap the seal ring 160 and straddle the seal ring 160.

The via 184f extends in the direction D1 and is electrically connected to one end of the wiring 156h. The wiring 156h extends in the direction D2, and the other end of the wiring 156h is electrically connected to the via 184g. The via 184g extends in the direction D1 and is electrically connected to one end of the wiring 183f. The wiring 183f extends in the direction D3, and the other end of the wiring 183f is electrically connected to the via 184h. The wiring 183f is configured to overlap the seal ring 160 and straddle the seal ring 160.

The via 184h extends in the direction D1 and is electrically connected to one end of the wiring 156i. The wiring 156i extends in the direction D2, and the other end of the wiring 156i is electrically connected to the via 184i. The via 184i extends in the direction D1 and is electrically connected to one end of the wiring 183g.

The wiring 183g extends in the direction D3 and is configured to overlap the seal ring 160 and straddle the seal ring 160. Further, the wiring 183g is bent in the direction D2 and extends in the direction D2 after straddling the seal ring 160. Further, the wiring 183g extends in the direction D2, and then bends in the direction D3 and extends in the direction D3. Further, the wiring 183g extends in the direction D3 and is configured to overlap the seal ring 160 and straddle the seal ring 160. Further, the wiring 183g is bent in the direction D2 and extends in the direction D2 after straddling the seal ring 160. The other end of the wiring 183g extending in the direction D2 is electrically connected to the terminal E.

As shown in FIG. 33, the wiring 183c, the wiring 183d, the wiring 183e, the wiring 183f, and the wiring 183g overlapping the seal ring 160 are formed in the same plane, and parts of the wiring 183c, the wiring 183e, the wiring 183d, the wiring 183e, the wiring 183f, and the wiring 183g are formed in parallel along the direction D3.

As shown in FIG. 33 or FIG. 34, parts of the wiring 152c, the wiring 154e, wiring 156i, and the wiring 183g overlap each other along the direction D1 and are formed in parallel along the direction D2. The wiring 152c is formed in the same layer as the wiring 152b constituting the seal ring 160, the wiring 154e is formed in the same layer as the wiring 154b constituting the seal ring 160, and the wiring 156i is formed in the same layer as the wiring 156b forming the seal ring 160.

As shown in FIG. 33 or FIG. 36, parts of the wiring 154d, the wiring 156h, and the wiring 183g are stacked along the direction D1 and overlap each other, and are formed in parallel along the direction D2. The wiring 154d is formed in the same layer as the wiring 154b constituting the seal ring 160, and the wiring 156h is formed in the same layer as the wiring 156b constituting the seal ring 160.

As shown in FIG. 33, the wiring 183c and the wiring 183e face the wiring 183d and the wiring 183f. As shown in FIG. 33, FIG. 34, or FIG. 36, the wiring 154d faces the wiring 154e, and the wiring 156h faces the wiring 156i.

That is, the inductor 372f is composed of the wiring 183c and the wiring 183e, and the wiring 183d and the wiring 183f, which are formed in the same layer and overlap the seal ring 160 and face each other, the wiring 154d and the wiring 154e formed in the same layer as the wiring 154b constituting the seal ring 160 and opposed to each other, and the wiring 156h and the wiring 156i formed in the same layer as the wiring 156b constituting the seal ring 160.

In addition, as shown in FIG. 33 and FIG. 36, the wiring 183g, the wiring 156h, and the wiring 154d overlap each other and correspond to an end portion of the inductor 372f on the first side surface 146 side. The wiring 183g, the wiring 156h, and the wiring 154d are not exposed to the first side surface 146, similar to the end part 166c of the signal transmission wiring 166b. The wiring 183g, the wiring 156i, the wiring 154e, and the wiring 152c overlap each other and correspond to an end portion of the inductor 372f opposite to the first side surface 146.

By forming the end portion of the inductor 372f on the side of the first side surface 146 and the end of the inductor 372f on the side opposite to the side of the first side surface 146 as shown in FIG. 33 and FIG. 36, the wirings 183c to 183 g of the inductor 372f can overlap the seal ring 160 and straddle the seal ring 160 as shown in the cross section shown in FIG. 35.

Consequently, the three-turn inductor 372f configured as described above is insulated from the seal ring 160 by the insulating layers 151a to 182, and is not short-circuited with the seal ring 160.

In addition, similar to the inductor 372, the memory chip 110 includes a plurality of inductors 372f arranged along the direction D2.

The semiconductor module 10J includes the inductor 372f as described above, and has the same advantages as the semiconductor module 10J including the inductor 372.

### 10-4. Other Example of Inductor 372 (Inductor 372g)

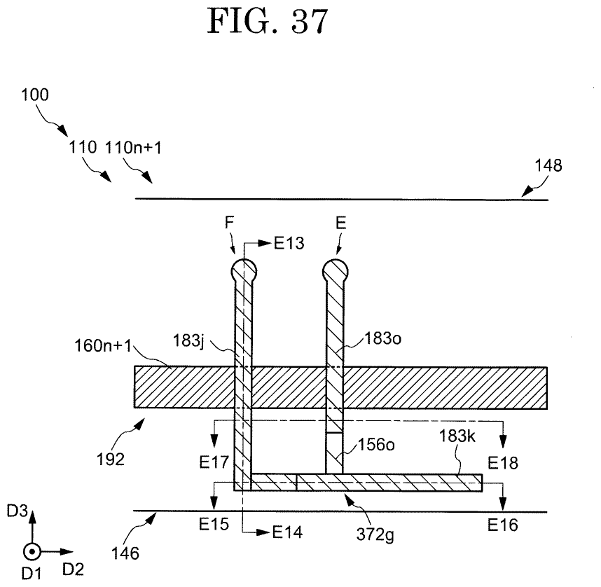

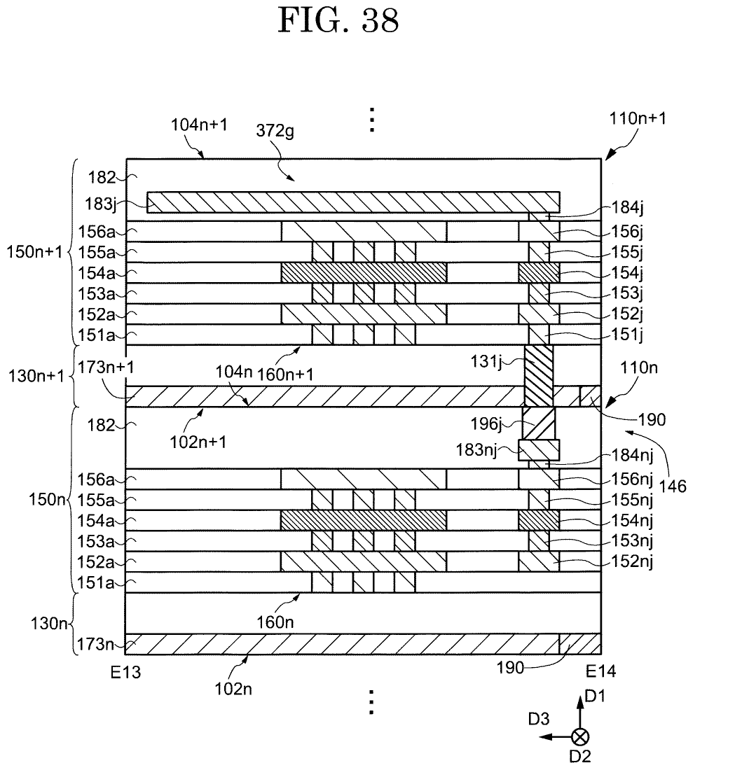

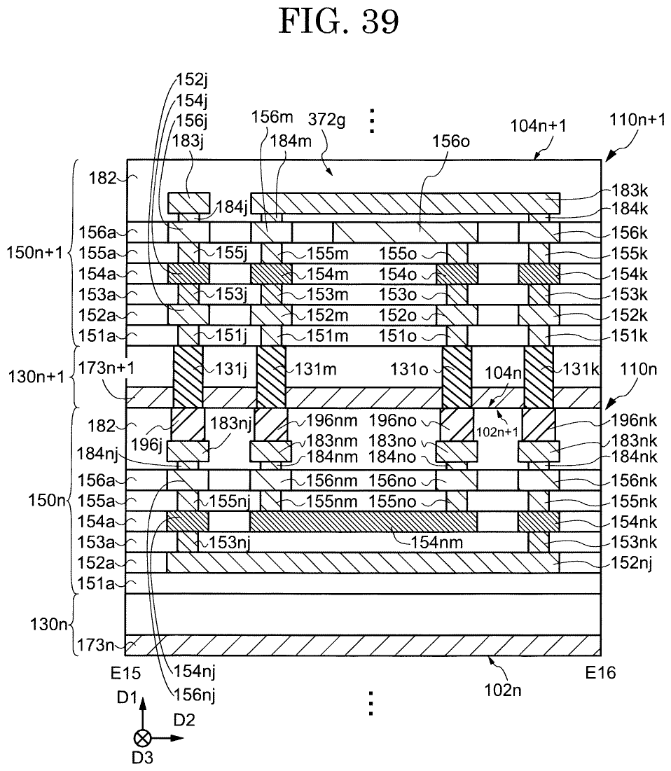

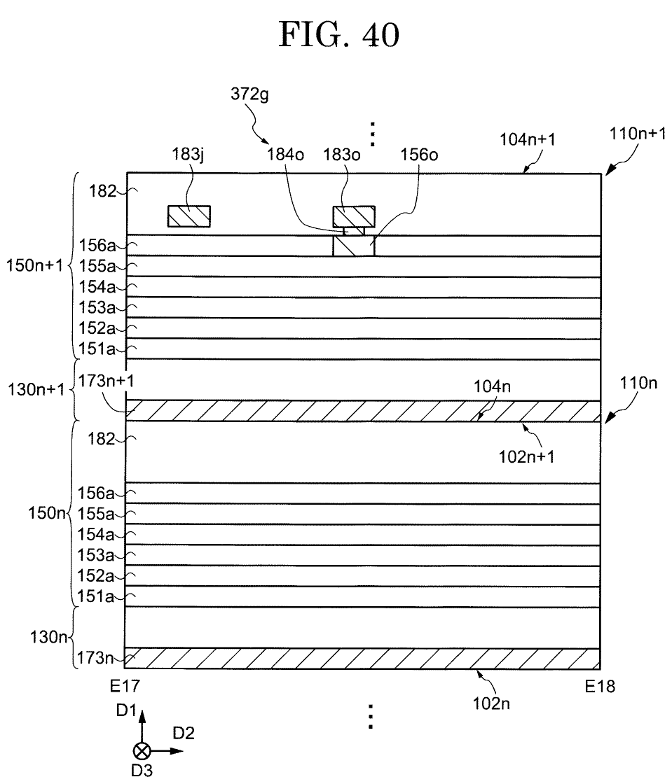

The inductor 372 g of the semiconductor module 10J will be described referring to FIG. 37 to FIG. 40. FIG. 37 is a plan view showing configurations of the seal ring 160 and the inductor 372g. FIG. 38 is a cross-sectional view of the seal ring 160 and the inductor 372g taken along a line E13-E14 of FIG. 37. FIG. 39 is a cross-sectional view of the inductor 372g taken along a line E15-E16 of FIG. 37. FIG. 40 is a cross-sectional view of the inductor 372g taken along a line E17-E18 of FIG. 37. The same or similar configurations as those in FIG. 1 to FIG. 36 will be described as necessary.

The inductor 372g shown in FIG. 37 to FIG. 40 is, unlike the inductor 372f, an inductor having a plurality of turns formed over a plurality of memory chips in a cross-sectional view. Since other configurations of the inductor 372g are the same as the configuration of the inductor 372f, explanation thereof will be omitted.

As shown in FIG. 38 to FIG. 40, a first surface 102n of the memory chip 110n+1 is bonded to a second surface 104n+1 of the memory chip 110n. The inductor 372g is arranged over two memory chips (memory chip 110n and 110n+1).

FIG. 39 shows a cross section (structure) of the inductor 372g when viewed from the first side surface 146 toward the third side surface 148 in a depth direction. When viewed from the first side surface 146 to the third side surface 148, the inductor 372g shown in FIG. 39 is an example of a two-turn inductor provided over two memory chips (memory chip 110n and 110n+1). Further, the inductor 372g is parallel to the first side surface 146 and the third side surface 148.

The inductor 372g shown in FIG. 37 to FIG. 40 includes the terminal E, the terminal F, a wiring 183j, a via 184j, a wiring 156j, a via 155j, a wiring 154j, a via 153j, a wiring 152j, a via 151j, a through-hole electrode 131j, a wiring 196j, a wiring 183nj, a via 184nj, a wiring 156nj, a via 155nj, a wiring 154nj, a via 153nj, a wiring 152nj, a via 153nk, a wiring 154nk, a via 155nk, a wiring 156nk, a via 184nk, a wiring 183nk, a wiring 196nk, a through-hole electrode 131k, a via 151k, a wiring 152k, a via 153k, a wiring 154k, a via 155k, a wiring 156k, a via 184k, a wiring 183k, a via 184m, a wiring 156m, a via 155m, a wiring 154m, a via 153m, a wiring 152m, a via 151m, a through-hole electrode 131m, a wiring 196 nm, a wiring 183 nm, a via 184 nm, a wiring 156 nm, a via 155 nm, a wiring 154 nm, a via 155no, a wiring 156no, a via 184no, a wiring 183no, a wiring 196no, a through-hole electrode 131o, a via 151o, a wiring 152o, a via 153o, a wiring 154o, a via 155o, a wiring 156o, a via 184o, and a wiring 183o.

The memory chip 110n includes the wiring 196j, the wiring 183nj, the via 184nj, the wiring 156nj, the via 155nj, the wiring 154nj, the via 153nj, a wiring 152nj, the wiring 153nk, the wiring 154nk, the via 155nk, the wiring 156nk, the via 184nk, the wiring 183nk, the wiring 196nk, the wiring 196 nm, the wiring 183 nm, the via 184 nm, the wiring 156 nm, the via 155 nm, the wiring 154 nm, the via 155no, the wiring 156no, the via 184no, the wiring 183no, the wiring 196no, and a seal ring 160n. The function and structure of the seal ring 160n is the same as the function and structure of the seal ring 160. The function and structure of the seal ring 160n will be described as required.

The wiring 152nj is formed in the same layer as the wiring 152b of the memory chip 110n, and the vias 153nj and 153nk are formed in the same layer as the via 153b of the memory chip 110n. The wiring 154nj, the wiring 154nk, and the wiring 154 nm are formed in the same layer as the wiring 154b of the memory chip 110n. The via 155nj, the via 155nk, the via 155 nm, and the via 155no are formed in the same layer as the via 155b of the memory chip 110n. The wiring 156nj, the wiring 156nk, the wiring 156 nm, and the wiring 156no are formed in the same layer as the wiring 156b of the memory chip 110n. The wiring 183nj, the wiring 183nk, the wiring 183 nm, and the wiring 183no are formed in the same layer.

The via 184nj, the via 184nk, the via 184 nm, and the via 184no are formed between the layer on which the insulation layer 156a, the wiring 156nj, the wiring 156nk, the wiring 156 nm, and the wiring 156no are formed and the layer on which the wiring 183nj, the wiring 183nk, the wiring 183 nm, and the wiring 183no are formed in the memory chip 110n in the direction D1.

The wiring 196j, the wiring 196nk, the wiring 196 nm, and the wiring 196no are formed on the wiring 183nj, the wiring 183nk, the wiring 183 nm, and the wiring 183no.

The memory chip 110n+1 includes the terminal E, the terminal F, the wiring 183j, the via 184j, the wiring 156j, the via 155j, the wiring 154j, the via 153j, the wiring 152j, the via 151j, the through-hole electrode 131j, the through-hole electrode 131k, the via 151k, the wiring 152k, the via 153k, the wiring 154k, the via 155k, the wiring 156k, the via 184k, the wiring 183k, the via 184m, the wiring 156m, the via 155m, the wiring 154m, the via 153m, the wiring 152m, the via 151m, the through-hole electrode 131m, the through-hole electrode 131o, the via 151o, the wiring 152o, the via 153o, the wiring 1540, the via 155o, the wiring 156o, the via 184o, the wiring 183o, and a seal ring 160n+1. In addition, the function and structure of the seal ring 160n+1 are the same as the function and structure of the seal ring 160. The function and structure of the seal ring 160n+1 will be described as required.

The via 151j, the via 151k, the via 151m, and the via 151o are formed in the same layer as the via 151b of the memory chip 110n+1. The wiring 152j, the wiring 152k, the wiring 152m, and the wiring 152o are formed in the same layer as the wiring 152b of the memory chip 110n+1. The via 153j, the via 153k, the via 153m, and the via 153o are formed in the same layer as the via 153b of the memory chip 110n+1. The wiring 154j, the wiring 154k, the wiring 154m, and the wiring 154o are formed in the same layer as the wiring 154b of the memory chip 110n+1. The via 155j, the via 155k, the via 155m, and the via 155o are formed in the same layer as the via 155b of the memory chip 110n+1. The wiring 156j, the wiring 156k, the wiring 156m, and the wiring 156o are formed in the same layer as the wiring 156b of the memory chip 110n+1. The wiring 183j, the wiring 183k, and the wiring 183o are formed in the same layer. The via 184j, the via 184k, the via 184m, and the via 1840 are formed in the same layer.

The through-hole electrode 131j, the through-hole electrode 131k, the through-hole electrode 131m and the through-hole electrode 131o are formed so as to penetrate the transistor layer 130n+1, and are connected to the via 151j, the via 151k, the via 151m, and the via 151o. Further, when the memory chip 110n+1 is bonded to the memory chip 110n, the through-hole electrode 131j, the through-hole electrode 131k, the through-hole electrode 131m, and the through-hole electrode 131o are connected to the wiring 196j, the wiring 196nk, the wiring 196 nm, and the wiring 196no of the memory chip 110n.

Here, a connection of the inductor 372g is explained.

The wiring 183j extends in the direction D3, one end of the wiring 183j is electrically connected to the terminal F, and the other end of the wiring 183j is electrically connected to the via 184j. The wiring 183j overlaps the seal rings 160n and 160n+1 and is configured to straddle the seal rings 160n and 160n+1. The via 184j, the wiring 156j, the via 155j, the wiring 154j, the via 153j, the wiring 152j, the via 151j, the through-hole electrode 131j, the wiring 196j, the wiring 183nj, the via 184nj, the wiring 156nj, the via 155nj, the wiring 154nj, and the via 153nj extend in the direction D1 and are electrically connected to each other. The wiring 154nj is electrically connected to one end of the wiring 152nj. The wiring 152nj extends in the direction D2, and the other end of the wiring 152nj is electrically connected to the via 153nk.

The via 153nk, the wiring 154nk, the via 155nk, the wiring 156nk, the via 184nk, the wiring 183nk, the wiring 196nk, the through-hole electrode 131k, the via 151k, the wiring 152k, the via 153k, the wiring 154k, the via 155k, the wiring 156k, and the via 184k extend in the direction D1 and are electrically connected to each other. The via 184k is electrically connected to one end of the wiring 183k. The wiring 183k extends in the direction D2, and the other end of the wiring 183k is electrically connected to the via 184m. The via 184m, the wiring 156m, the via 155m, the wiring 154m, the via 153m, the wiring 152m, the via 151m, the through-hole electrode 131m, the wiring 196 nm, the wiring 183 nm, the via 184 nm, the wiring 156 nm, and the via 155 nm extend in the direction D1 and are electrically connected to each other. The via 155 nm is electrically connected to one end of the wiring 154 nm. The wiring 154 nm extends in the direction D2, and the other end of the wiring 154 nm is electrically connected to the via 155no.

The via 155no, the wiring 156no, the via 184no, the wiring 183no, the wiring 196no, the through-hole electrode 131o, the via 151o, the wiring 152o, the via 153o, the wiring 154o, and the via 155o extend in the direction D1 and are electrically connected to each other. The via 155o is electrically connected to one end of the wiring 156o. The wiring 156o extends in the direction D2 and then bends in the direction D3 and extends in the direction D3.

The other end of the wiring 156o extending in the direction D3 is electrically connected to the via 184o. The via 184o extends in the direction D1 and is electrically connected to one end of the wiring 183o. The wiring 183o extends in the direction D3 and the other end of the wiring 183o is electrically connected to the terminal E. The wiring 183o is configured to overlap the seal ring 160 and straddle the seal ring 160.

The wiring 183g extends in the direction D3 and is configured to overlap the seal ring 160 and straddle the seal ring 160. Further, the wiring 183g is bent in the direction D2 and extends in the direction D2 after straddling the seal ring 160. Further, the wiring 183g extends in the direction D2, and then bends in the direction D3 and extends in the direction D3. Further, the wiring 183g extends in the direction D3 and is configured to overlap the seal ring 160 and straddle the seal ring 160. Further, the wiring 183g is bent in the direction D2 and extends in the direction D2 after straddling the seal ring 160. The other end of the wiring 183g extending in the direction D2 is electrically connected to the terminal E.

As shown in FIG. 37, the wiring 183j and the wiring 183o overlapping the seal ring 160 are formed on the same plane and are parallel-formed along the direction D3.

As shown in FIG. 39, a substantially coiled portion of a two-turn inductor 196 nm is formed by the wiring 183j, the via 184j, the wiring 156j, the via 155j, the wiring 154j, the via 153j, the wiring 152j, the via 151j, the through-hole electrode 131j, the wiring 196j, the wiring 183nj, the via 184nj, the wiring 156nj, the via 155nj, the wiring 154nj, the via 153nj, the wiring 152nj, the via 153nk, the wiring 154nk, the via 155nk, the wiring 156nk, the via 184nk, the wiring 183nk, the wiring 196nk, the through-hole electrode 131k, the via 151k, the wiring 152k, the via 153k, the wiring 154k, the via 155k, the wiring 156k, the via 184k, the wiring 183k, the via 184m, the wiring 156m, the via 155m, the wiring 154m, the via 153m, the wiring 152m, the via 151m, the through-hole electrode 131m, the wiring 196 nm, the wiring 183 nm, the via 184 nm, the wiring 156 nm, the via 155 nm, the wiring 154 nm, the via 155no, the wiring 156no, the via 184no, the wiring 183no, the wiring 196no, the through-hole electrode 131o, the via 151o, the wiring 152o, the via 153o, the wiring 154o, the via 155o, and the wiring 156o.

That is, similar to the inductor 372f, the inductor 372g is composed of the wiring 183j and the wiring 183o overlapping the seal rings 160n and 160n+1 and alternately provided in the same layer, the wiring 183k that is arranged in the same layer as the wiring 183j and the wiring 183o and does not overlap the seal rings 160n and 160n+1, and a plurality of wirings that are arranged in the same layer as the wirings which form the seal rings 160n and 160n+1 and are arranged across two memory chips (110n and 110n+1).

Further, as shown in FIG. 37 and FIG. 39, a substantially coiled part of the two-turn inductor 372g is not exposed to the first side surface 146, similar to the end part 166c of the signal transmission wiring 166b.

By forming the substantially coil part of the inductor 372g arranged over the two memory chips on the first side surface 146 side by the wiring forming the seal ring 160, the wiring 183j and the wiring 183o connected to the substantially coil part of the inductor 372g can overlap the seal rings 160n and 160n+1, and can straddle the seal rings 160n and 160n+1.

Consequently, the two-turn inductor 372g configured as described above is insulated from the seal rings 160n and 160n+1 by the insulating layers 151a to 182 provided in the two memory chips 110n and 110n+1, respectively, and is not shorted with the seal rings 160n and 160n+1.

In addition, although one inductor 372g is shown in FIG. 37 to FIG. 40, the memory chips 110n and 110n+1 include a plurality of inductors 372g. For example, the plurality of inductors 372g is arranged side by side along the direction D2.

The semiconductor module 10J includes the inductor 372g as described above, and has the same advantages as the semiconductor module 10J including the inductor 372.

### 11. Eleventh Embodiment

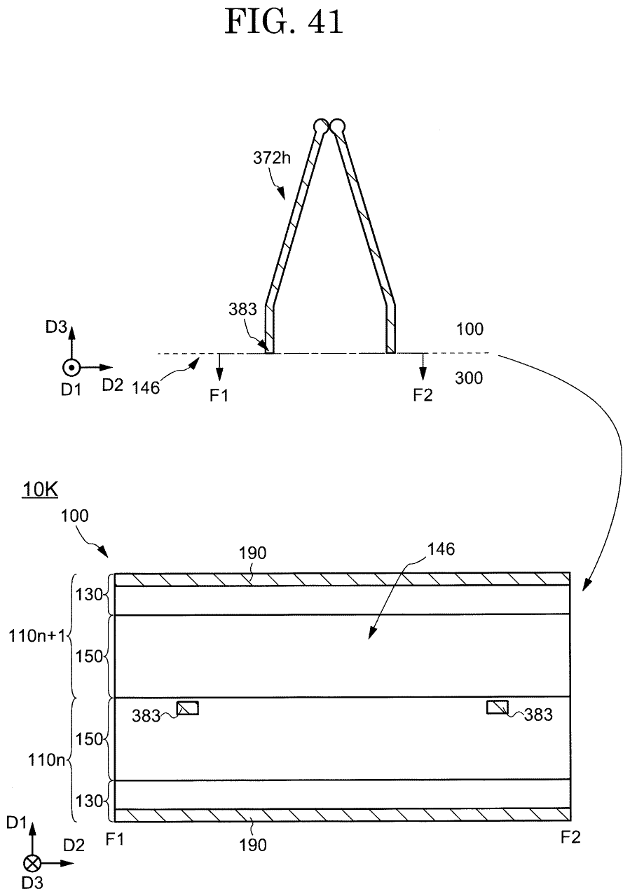

Referring to FIG. 41 to FIG. 46, inductors 372h to 372j included in a semiconductor module 10K according to an eleventh embodiment will be described. In a method for forming the inductor 372 included in the semiconductor module 10K, two sides of the inductors 372h to 372j are formed in the memory cube 100, and straight sides of the inductors 372h to 372j are formed in the rewiring layers 300 of the memory cube 100. Straight sides of the inductors 372h to 372j formed on the rewiring layer 300 are formed on the first side surface 146. For example, since other configurations and functions are the same as the configurations and functions described in the first embodiment, the second embodiment, or the tenth embodiment, a detailed description thereof will be omitted. The method for forming the inductor 372 according to the eleventh embodiment can be appropriately combined with or replaced with the configurations described in the first to tenth embodiments as long as they do not contradict each other.

[11-1. Manufacturing Method of One-Turn Inductor 372h]

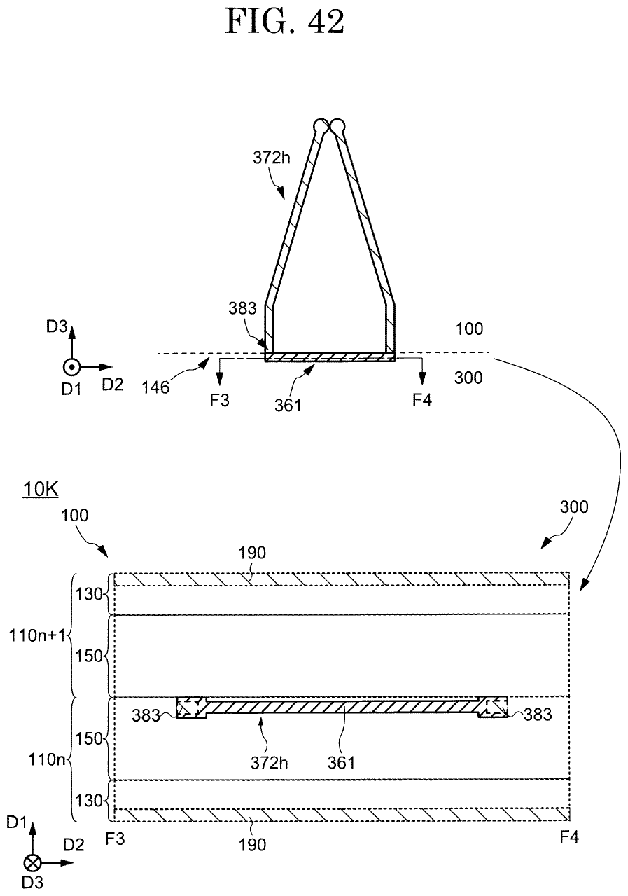

Referring to FIG. 41 and FIG. 42, an example of a manufacturing method of the one-turn inductor 372h included in the semiconductor module 10K will be described. FIG. 41 is a plan view showing an example of the manufacturing method of the inductor 372h included in the semiconductor module 10K, and a side view of the semiconductor module 10K along a line F1-F2. FIG. 42 is a plan view showing the example of the manufacturing method of the inductor 372h shown in FIG. 41 and a cross-sectional view showing a cross section of the semiconductor module 10K along a line F3-F4. The same or similar configurations as those in FIG. 1 to FIG. 40 will not be described here.

The manufacturing method of the semiconductor module 10K shown in FIG. 41 and FIG. 42 includes that two sides of the one-turn inductor 372h are formed using a wiring 383 of the memory chip 110n, and that after the two sides of the inductor 372h are formed, one straight side of the inductor 372h is formed using a side wiring 361 of the rewiring layer 300.

In addition, in the exemplary embodiments shown in FIG. 41 and FIG. 42, it is assumed that inductors 372h included in the memory chip 110n+1 and the rewiring layer 300 and inductors 372h included in the memory chip 110n and the rewiring layer 300 are alternately arranged along the direction D2. Therefore, in the case where a certain region of the semiconductor module 10K is enlarged, as shown in FIG. 41 and FIG. 42, there are regions in which the memory chip 110n and the rewiring layer 300 include the inductor 372h, and there are regions in which the memory chip 110n+1 and the rewiring layer 300 do not include the inductor 372h. Further, although not shown, there are regions in which the memory chip 110n+1 and the rewiring layer 300 include the inductor 372h, and there are regions in which the memory chip 110n and the rewiring layer 300 do not include the inductor 372h. The memory chips 110 and the rewiring layer 300 other than the memory chips 110n and 110n+1 and the rewiring layer 300 included in the semiconductor module 10K also have the same configuration as the memory chips 110n and 110n+1 and the rewiring layer 300.

As shown in FIG. 41 and FIG. 42, the memory cube 100 included in the semiconductor module 10K includes memory chips 110n and 110n+1 and rewiring layers 300. The memory chip 110n and the rewiring layer 300 include inductors 372. The inductor 372h shown in FIG. 41 and FIG. 42 is, for instance, the one-turn inductor. In the method for forming the memory cube 100 including the one-turn inductor 372h, the memory cube 100 has two sides of the inductor 372h of the memory chip 110n formed by using the wiring 383, and the wiring 383 forming the two sides of the inductor 372h is exposed to the first side surface 146.

After the two sides of the one-turn inductor 372 are formed using the wiring 383 of the memory chip 110n, as shown in FIG. 42, the side wiring 361 of the rewiring layer 300 is formed on the first side surface 146 of the memory chip 110n. That is, the side wiring 361 of the rewiring layer 300 is formed on the first side surface 146 so as to overlap the wiring 383 forming the two sides exposed to the first side surface 146. As a result, the side wiring 361 is electrically connected to the wiring 383 forming the two sides. As shown in FIG. 42, a wiring width of the side wiring 361 around the wiring 383 is increased so as to surround the cross section of the wiring 383. As a result, the side wiring 361 is securely connected to the wiring 383. In addition, the side wiring 361 around the wiring 383 may be referred to as an electrode pad, and may be individually formed as an electrode pad.

The inductor 372h according to the eleventh embodiment is formed using the wiring 383 and the side wiring 361 that differs from the wiring 383. The side wiring 361 is included in the rewiring layer 300 and is formed on the first side surface 146 of the memory cube 100. That is, a portion of the inductor 372h is included in the rewiring layer 300 by using the method for forming the inductor 372h. Consequently, a distance along the direction D3 between the inductor 372h and the inductor 272 in the corresponding logic chip 200 on a one-to-one basis can be shorter than a distance along the direction D3 between the inductor 372h included in the memory cube 100 and the inductor 272 in the logic chip 200. Consequently, the inductor communication between the inductor 372h and the inductor 272 can be improved.

[11-2. Manufacturing Method of Three-Turn Inductor 372i]

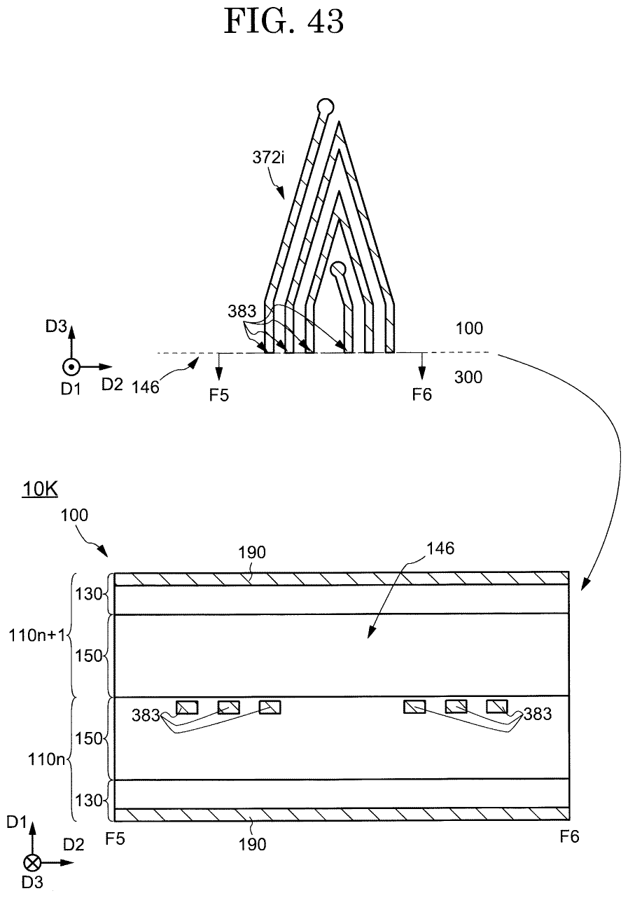

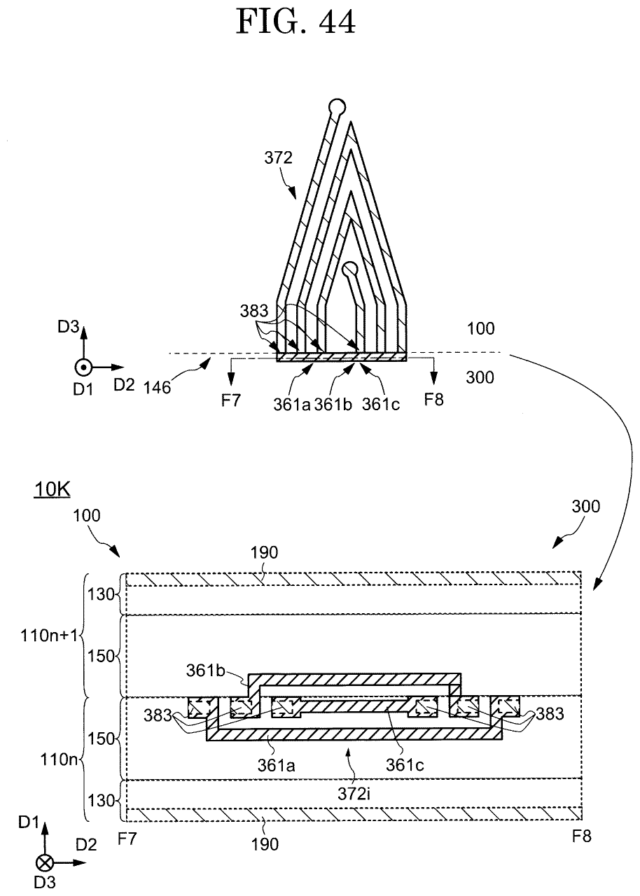

Referring to FIG. 43 and FIG. 44, an example of the manufacturing method of the three-turn inductor 372i included in the semiconductor module 10K will be described. FIG. 43 is a plan view showing an example of a manufacturing method of the inductor 372i included in the semiconductor module 10K, and a side view of the semiconductor module 10K along a line F5-F6. FIG. 44 is a plan view showing an exemplary manufacturing method of the inductor 372i shown in FIG. 43 and a cross-sectional view showing a cross section of the semiconductor module 10K along a line F7-F8. The same or similar configurations as those in FIG. 1 to FIG. 42 will be omitted here.

As shown in FIG. 43 and FIG. 44, the semiconductor module 10K may include the three-turn inductor 372i. The manufacturing method of the semiconductor module 10K shown in FIG. 43 and FIG. 44 includes that two sides of each of the first turn to the third turn of the inductor 372i are formed using the wiring 383 of the memory chip 110n, that after the two sides of each of the first turn to the third turn of the inductor 372i are formed, a side wiring 361a corresponding to one side of the straight line of the first turn, a side wiring 361b corresponding to one side of the straight line of the second turn, and a side wiring 361c of the rewiring layers 300 corresponding to one side of the straight line of the third turn are formed.

In addition, in the examples shown in FIG. 43 and FIG. 44, as in the examples shown in FIG. 42 and FIG. 43, it is assumed that the inductors 372i included in the memory chip 110n+1 and the rewiring layer 300 and the inductors 372i included in the memory chip 110n and the rewiring layer 300 are alternately arranged along the direction D2. Therefore, in the examples shown in FIG. 43 and FIG. 44, description of the same configuration and function as those of the examples shown in FIG. 42 and FIG. 43 will be omitted.

As shown in FIG. 43, in the inductor 372i, if the innermost side is the first turn, two sides constituting the first-turn inductor, two sides constituting the second-turn inductor, and two sides constituting the third-turn inductor are formed by the wiring 383. Therefore, the cross sections of the six wirings 383 forming the two sides constituting the first-turn inductor, the two sides constituting the second-turn inductor, and the two sides constituting the third-turn inductor are exposed to the first side surface 146.

Similar to forming the one-turn inductor 372h, after the two sides of each of the first to third turns of the three-turn inductor 372i are formed using the wiring 383 of the memory chip 110n, as shown in FIG. 44, the side wiring 361a corresponding to one side of the straight line of the first turn of the inductor 372i, the side wiring 361b corresponding to one side of the straight line of the second turn of the inductor 372i, and the side wiring 361c of the rewiring layer 300 corresponding to one side of the straight line of the third turn of the inductor 372i are formed on the first side surface 146 of the memory cube 100.

For example, the side wiring 361a is formed on the first side surface 146 of the memory chip 110n so as to overlap the wiring 383 forming the second side of the first turn exposed on the first side surface 146, and the side wiring 361a is electrically connected to the wiring 383 forming the second side of the first turn. For example, the side wiring 361b is formed on the first side surface 146 of the memory chip 110n and the first side surface 146 of the memory chip 110n+1 so as to overlap the wiring 383 forming the second side of the second turn exposed on the first side surface 146, and the side wiring 361b is electrically connected to the wiring 383 forming the second side of the second turn. For example, the side wiring 361c is formed on the first side surface 146 of the memory chip 110n in the same manner as the side wiring 361a, and the side wiring 361c is electrically connected to the wiring 383 forming the second side of the third turn.

Similar to the one-turn inductor 372h, wiring widths of the side wirings 361a to 361c around the cross section of the wiring 383 of the three-turn inductor 372i are increased so as to surround the cross section of the wiring 383.

The inductor 372i according to the eleventh embodiment is formed using the wiring 383 and the side wirings 361a to 361c that differ from the wiring 383. The side wirings 361a to 361c are included in the rewiring layer 300 and are formed on the first side surface 146 of the memory cube 100. As a consequence, similar to the inductor 372h, the inductor communication between the inductor 372i and the inductor 272 can be improved.

[11-3. Manufacturing Method of Three-turn Inductor 372j]

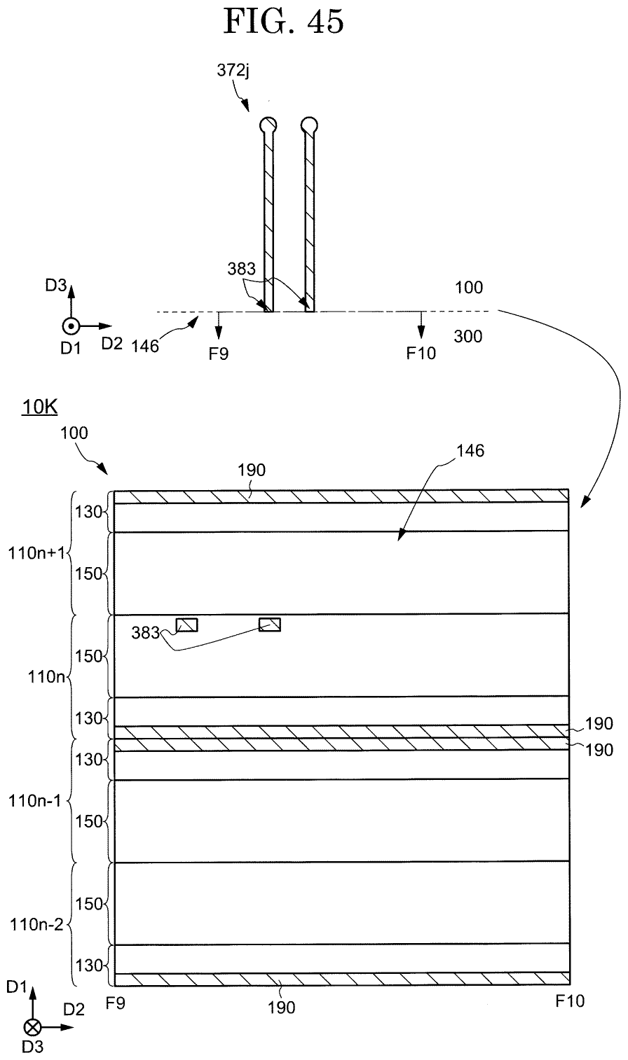

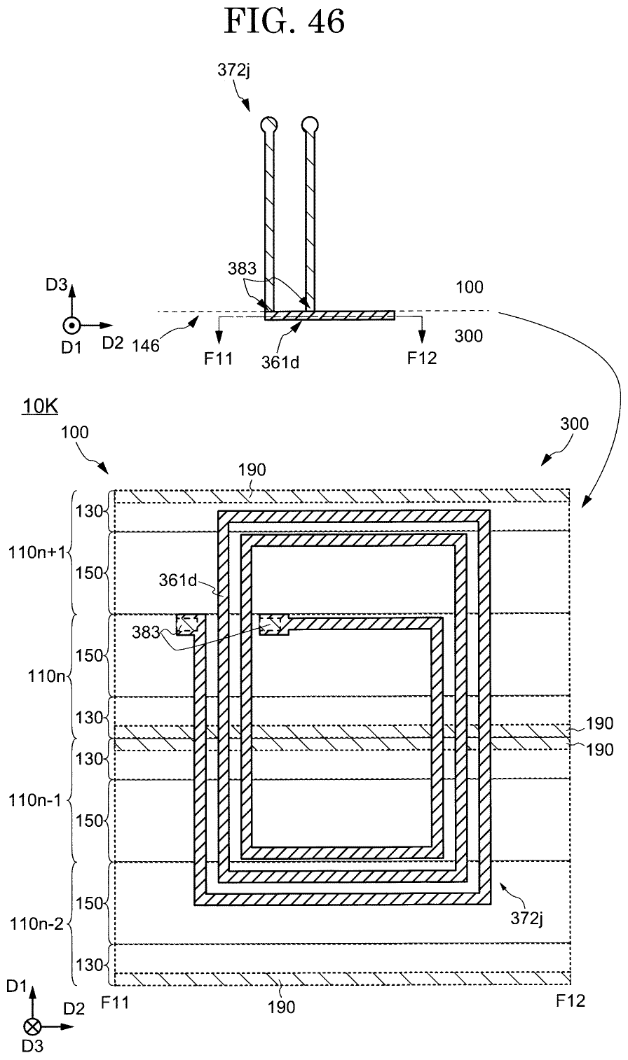

FIG. 45 and FIG. 46 show an exemplary method for manufacturing the three-turn inductor 372 included in the semiconductor module 10K. FIG. 45 is a plan view showing an exemplary manufacturing method of the inductor 372 included in the semiconductor module 10K, and a side view of the semiconductor module 10K along a line F9-F10. FIG. 46 is a plan view showing an exemplary manufacturing method of the inductor 372 shown in FIG. 45, and a cross-sectional view showing a cross section of the semiconductor module 10K along a line F11-F12. Descriptions of the same or similar configurations as those in FIG. 1 to FIG. 44 will be omitted.

As shown in FIG. 45 and FIG. 46, the semiconductor module 10K may include an inductor 372j having a plurality of turns formed over a plurality of memory chips 110 (110n-2, 110n-1, 110n, and 110n+1). Specifically, the semiconductor module 10K includes the three-turn inductor 372j including three-turn coils formed in the rewiring layers 300 parallel to the first side surface 146 and a surface formed in the direction D1 and the direction D2.

In addition, although not shown in the drawings, a plurality of inductors 372j is arranged along the direction D2 in the same manner as the respective embodiments. Further, in the example shown in FIG. 45 and FIG. 46, although two wirings 383 corresponding to two terminals of the inductor 372j are formed in the memory chip 110n, the two wirings 383 corresponding to the two terminals of the inductor 372j may be formed in any one of the memory chip 110n+1, the memory chip 110n-1, and the memory chip 110n-2. In addition, among the two wirings 383 corresponding to the two terminals of the inductor 372j, the wiring 383 corresponding to one terminal may be formed in any one of the memory chip 110n+1, the memory chip 110n-1, and the memory chip 110n-2, and the wiring 383 corresponding to the remaining terminals may be formed in a memory chip that differs from the memory chip in which the wiring 383 corresponding to the one terminal is formed.

The manufacturing method of the semiconductor module 10K shown in FIG. 45 and FIG. 46 includes that a wiring connected to two terminals of a three-turn inductor 372j is formed using two wirings 383 of the memory chip 110n, and that after the two wirings 383 corresponding to the two terminals of the inductor 372j are formed, a side wiring 361d of the rewiring layer 300 corresponding to a three-turn coil is formed.

As shown in FIG. 45, a wiring connected to the two terminals of a three-turn inductor 372j is formed by two wirings 383 of the memory chip 110n. Thus, a cross section of each of the two wirings 383 is exposed to the first side surface 146.

After the two wirings 383 of the inductor 372j are formed, as shown in FIG. 46, the side wiring 361d of the rewiring layer 300 corresponding to the coils of the three-turn inductor 372j are formed on the first side surface 146 of the memory cube 100. That is, the side wiring 361d of the rewiring layer 300 is formed on the first side surface 146 of the memory cube 100 over the plurality of memory chips 110n-2, 110n-1, 110n, and 110n+1.

For example, the side wiring 361d is formed on the first side surface 146 of the memory cube 100 so as to overlap each of the two wirings 383 exposed on the first side surface 146 corresponding to the side surface of the memory chip 110n, and the side wiring 361d is electrically connected to each of the cross sections of the two wirings 383.

Further, for example, the side wiring 361d of the three-turn inductor 372j shown in FIG. 46 includes wirings of first to third turns from the inside toward the outside. The first-turn wiring is formed over the memory chip 110n and the memory chip 110n-1, the second-turn wiring is formed over the memory chip 110n+1, the memory chip 110n, the memory chip 110n-1, and the memory chip 110n-2, and the third-turn wiring is formed over the memory chip 110n+1, the memory chip 110n, the memory chip 110n-1, and the memory chip 110n-2.

Similar to the inductors 372h and 372i, the side wiring 361d around the cross section of the wiring 383 of the three-turn inductor 372j is wider so as to surround the cross section of the wiring 383.

The inductor 372j according to the eleventh embodiment is formed using the wiring 383 and the side wiring 361d that differs from the wiring 383. The side wiring 361d is included in the rewiring layer 300 and is formed on the first side surface 146 of the memory cube 100. Consequently, as with the inductors 372h and 372i, the inductor communication between the inductor 372j and the inductor 272 can be improved.

### 12. Twelfth Embodiment

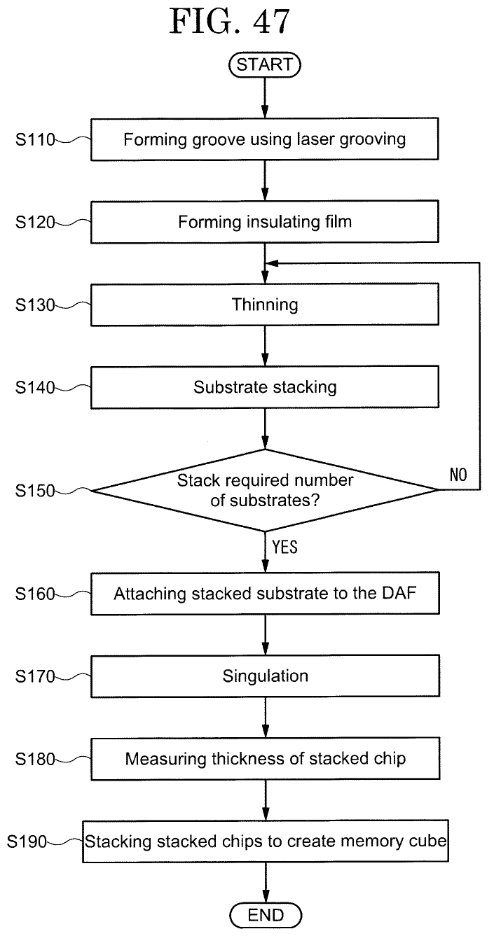

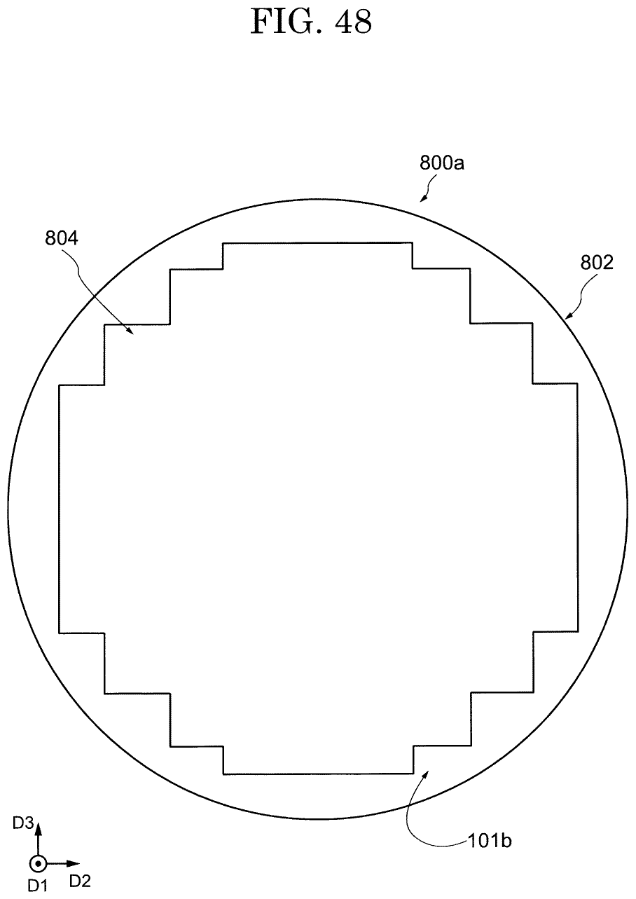

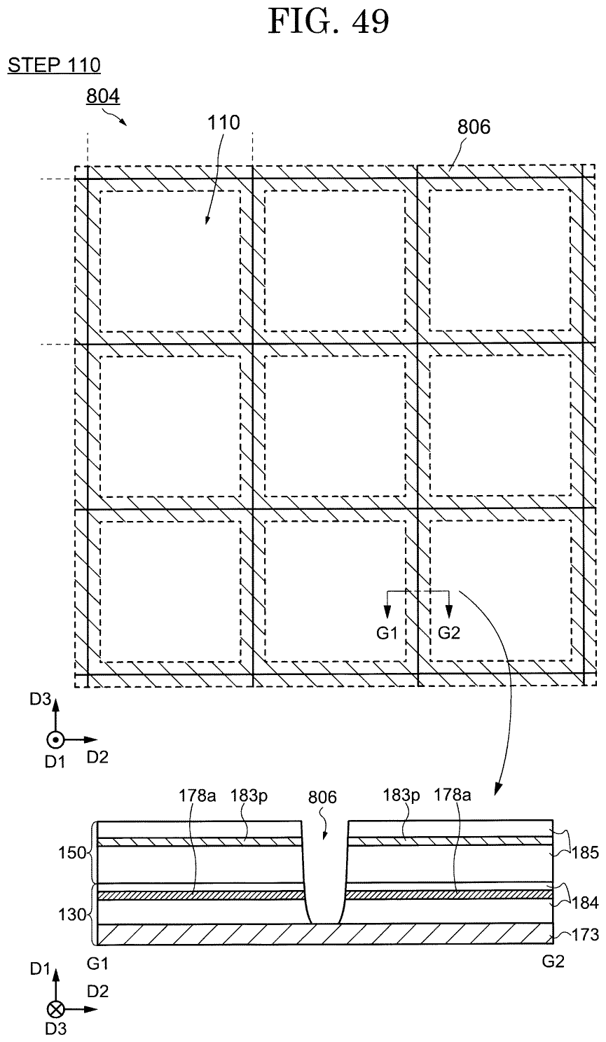

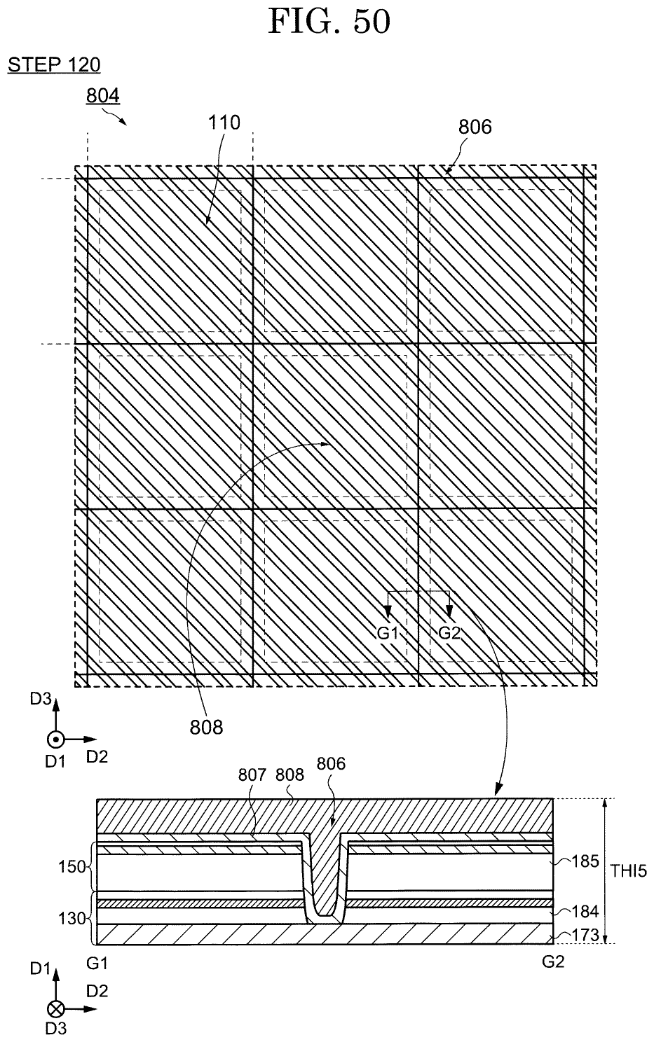

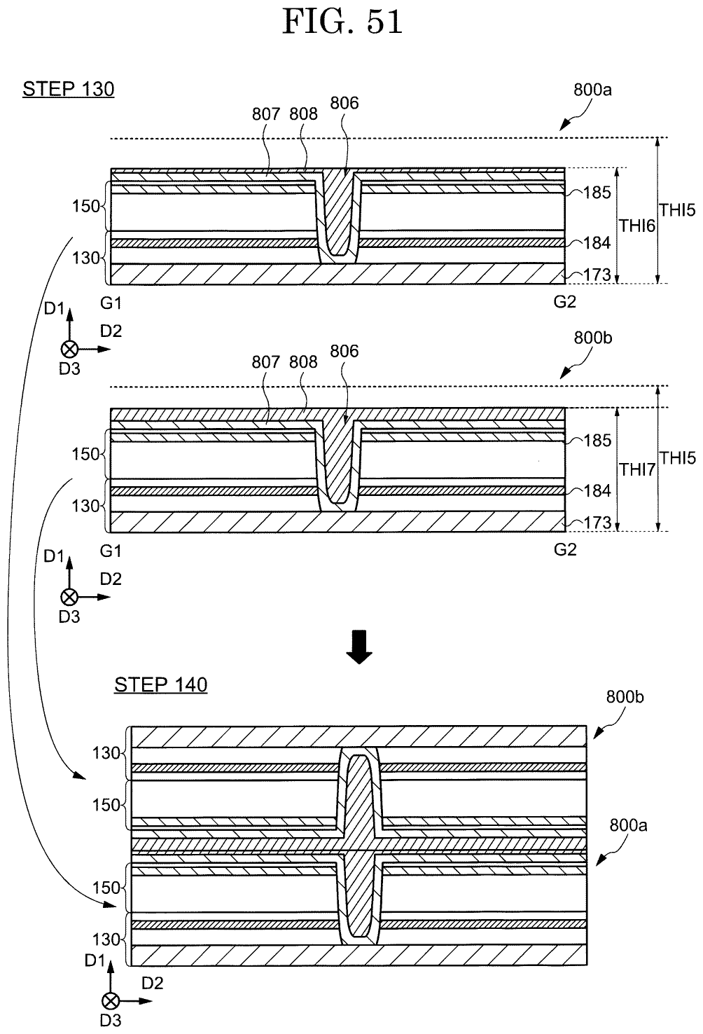

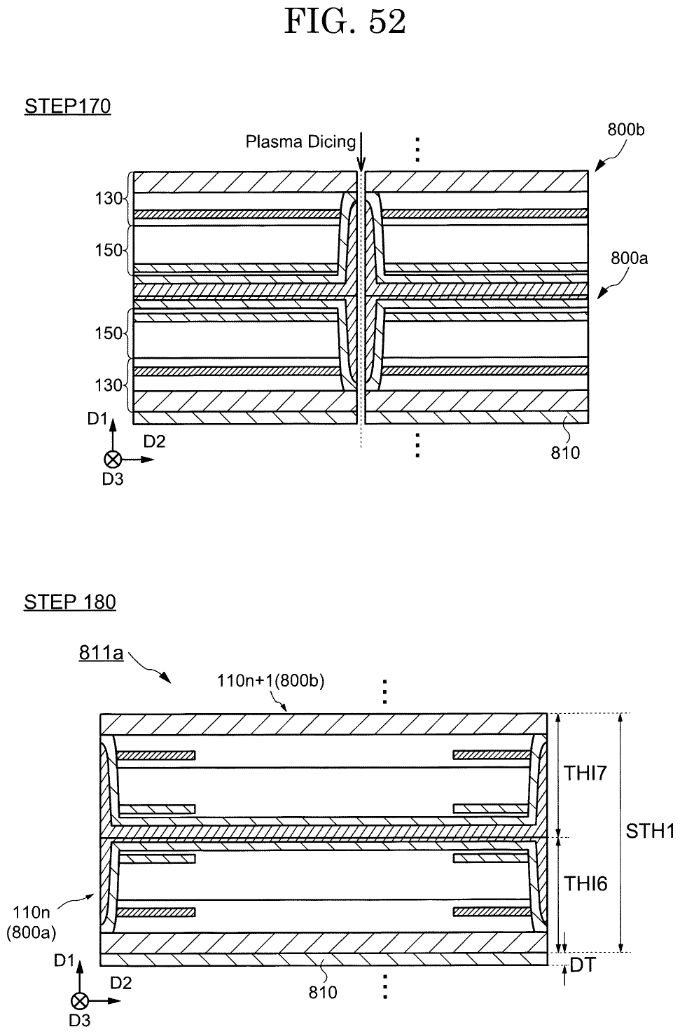

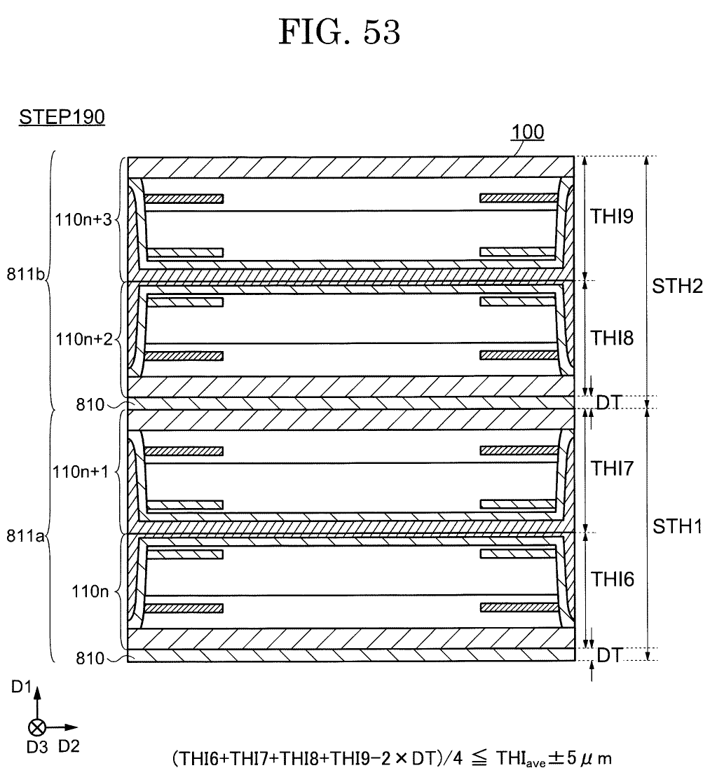

A method for manufacturing the memory cube 100 according to a twelfth embodiment will be described with reference to FIG. 47 to FIG. 53. FIG. 47 is a flowchart showing the method for manufacturing the memory cube 100. FIG. 48 is a plan view showing the method for manufacturing the memory cube 100. FIG. 49 is a plan view showing step S110 (STEP 110) of the manufacturing method of the memory cube 100, and a cross-sectional view showing a cross section of a memory substrate 800a along a line G1-G2. FIG. 49 is an enlarged view of a memory chip region 804. FIG. 50 is a plan view showing step S120 (STEP 120) of the manufacturing method of the memory cube 100, and a cross-sectional view showing a cross section of the memory substrate 800a along a line G1-G2. FIG. 51 is a cross-sectional view showing step S130 (STEP 130) of the manufacturing method of the memory cube 100 and showing a cross section of the memory substrate 800a along a line G1-G2. FIG. 51 is a cross-sectional view showing step S140 (STEP 140) in the manufacturing method of the memory cube 100. FIG. 52 is a cross-sectional view showing step S170 (STEP 170) and step S180 (STEP 180) of the manufacturing method of the memory cube 100. FIG. 53 is a cross-sectional view showing step S190 (STEP 190) of the manufacturing method of the memory cube 100. Descriptions of the same or similar configurations as those in FIG. 1 to FIG. 46 will be omitted.

As shown in FIG. 47, the method for manufacturing the memory cube 100 includes step S110 (STEP 110) to step S190 (STEP 190).

When the manufacturing method of the memory cube 100 is started, the memory substrate 800a is prepared. For example, as shown in FIG. 48, a second surface 101b of the memory substrate 800a overlaps a peripheral region 802 and the memory chip region 804. The memory chip region 804 overlaps the plurality of memory chips 110 and a groove 806, and includes the plurality of memory chips 110 and the groove 806 (see FIG. 49). The peripheral region 802 is a region around the memory chip region 804. For example, the plurality of memory chips 110 includes the same configuration as that of the first embodiment. Therefore, a configuration similar to that of the first embodiment in the memory chip 110 will be described as necessary. STEP 110 is the step of using laser grooving to form the groove 806 that defines each of the plurality of memory chips 110. The groove 806 of the memory substrate 800a shown in FIG. 49 is formed by a laser with reference to alignment markers (not shown). The groove 806 is formed in the insulating layer 185 included in the wiring layer 150 and the insulating layer 184 included in the transistor layer 130. In addition, for example, the wiring layer 150 includes a wiring 183p, the transistor layer 130 includes a wiring 178a, and the end part (side surface) of the wiring 183p and the end part (side surface) of the wiring 178a are exposed in the groove 806. In addition, a portion of the groove 806 may be formed in the substrate 173 in accordance with the output of the laser or the like.

Step S120 (STEP 120) is a step of forming an insulating layer 807 and an insulating layer 808 on a substrate (the insulating layer 185). The insulating layer 807 and the insulating layer 808 are formed in the groove 806 by STEP 120, and the groove 806 is filled with the insulating layer 807 and the insulating layer 808. That is, as shown in FIG. 50, the insulating layer 807 is formed on upper and side surfaces of the insulating layer 185, a side surface of the wiring 183p, a side surface of the insulating layer 184, a side surface of the wiring 178a, and a portion of the surface of the substrate 173 exposed by the groove 806, and the insulating layer 808 is formed on the insulating layer 807. For example, a CVD device can be used to form the insulating layer 807 and the insulating layer 808. For example, the insulating layer 807 may include SIN, SiON or the like as an insulating film, and the insulating layer 808 may include SiO₂ or the like as an insulating film. In addition, the insulating layer 185 and the insulating layer 184 include a low dielectric constant film having a dielectric constant lower than that of the insulating film 190 (see FIG. 5A).

Step S130 (STEP 130) is a step of thinning the surface (insulating layer 808) of the memory substrate 800a. STEP 130 planarizes the surface of the memory substrate 800a. For example, as shown in FIG. 51, the surface of the memory substrate 800a (the memory substrate 800a) is polished. Consequently, as shown in FIG. 51, a thickness THI5 of the memory substrate 800a is thinned to a thickness THI6. For example, a surface (insulating layer 808) of a memory substrate 800b is polished in the same manner as the memory substrate 800a, and the thickness THI5 of the memory substrate 800b is thinned to a thickness THI7. For example, the thickness THI6 is smaller than the thickness THI5, and the thickness THI7 is smaller than the thickness THI6. For example, a CMP device can be used for polishing. In the embodiment shown in FIG. 51, although the surface of the memory substrate 800a and the surface of the memory substrate 800b after thinning include the insulating layer 808, the surface of the memory substrate 800a and the surface of the memory substrate 800b after thinning may not include the insulating layer 808 and the insulating layer 807 may be exposed as needed.

Step S140 (STEP 140) is a step of stacking the memory substrate. For example, the surface of the memory substrate 800a where the insulating layer 808 is exposed and the surface of the memory substrate 800b where the insulating layer 808 is exposed are F2F bonded by STEP 140 shown in FIG. 51. STEP 140 may be replaced with STEP 130.

Step S150 (STEP 150) is a step of determining whether or not a predetermined number (required number) of memory substrates have been stacked. If the required number of substrates are not stacked (NO in STEP 150), the process returns to STEP 130, and STEP 130 and STEP 140 are executed again. If the required number of substrates are stacked (YES in STEP 150), step S160 (STEP 160) is executed.

STEP 160 is a step in which a plurality of substrates stacked in STEP 150 are attached to a DAF 810. By performing STEP 160, the required number of stacked substrates can be fixed to the DAF 810. That is, the required number of stacked substrates are supported by the DAF 810. In addition, an example of a manufacturing method of the memory cube 100 according to the twelfth embodiment is an example in which two memory substrates 800a and 800b are stacked. The DAF 810 may be an adhesive film, an adhesive layer, or the like as long as it can bond the substrate and fix the substrate to the film.

Step S170 (STEP 170) is a step of singulating the required number of stacked substrates to which the DAF 810 is attached in STEP 160. A stacked chip 811a is formed by performing STEP 170 shown in FIG. 52. In particular, the required number of stacked substrates to which the DAF 810 is attached is singulated into individual stacked chips 811a using plasma dicing (Plasma Dicing) with reference to alignment markers (not shown).

Step S180 (STEP 180) is a step of measuring a thickness of the singulated stacked chip 811a in STEP 170. For example, as shown in FIG. 52, a thickness STH1 of the stacked chip 811a is measured.

Step S190 (STEP 190) is a step of stacking a plurality of stacked chips whose thickness is measured in STEP 180 to form the memory cube 100. For example, the stacked chip 811a is stacked with a stacked chip 811b by performing STEP 190 shown in FIG. 53, and the memory cube 100 is formed. For example, the thickness of the stacked chip 811a is the thickness STH1, and a thickness of the stacked chip 811b is a thickness STH2. In addition, the stacked chip 811a includes the memory chips 110n and 110n+1, and the stacked chip 811b includes the memory chips 110n+2 and 110n+3. For example, the thickness of the memory chip 110n is a thickness THI6, the thickness of the memory chip 110n+1 is a thickness THI7, the thickness of the memory chip 110n+2 is a thickness THI8, and the thickness of the memory chip 110n+3 is a thickness THI9. The example of a manufacturing method of the memory cube 100 according to the twelfth embodiment is an example in which two stacked chips 811a and 811b are stacked.

As described above, the memory cube 100 is formed.

The manufacturing method of the memory cube 100 according to the twelfth embodiment includes forming the groove 806 defining each of the plurality of memory chips 110 on the memory substrate 800a, forming insulating layers 807 and 808 in the groove 806, and plasma dicing each of the plurality of memory chips 110 along the groove 806, prior to stacking the plurality of memory chips 110. Since the groove 806 is filled by the insulating layers 807 and 808, the first side surface 106, the second side surface 105, the third side surface 108, and the fourth side surface 107 of each memory chip 110 are covered by the insulating layers 807 and 808. Therefore, a low dielectric constant film having high hygroscopicity is not exposed from the first side surface 106, the second side surface 105, the third side surface 108, and the fourth side surface 107 of each memory chip 110. As a result, the memory cube 100 can suppress corrosion, deterioration, and the like of each device due to moisture absorption and intrusion of impurities and the like. Therefore, the reliability of the semiconductor module can be maintained without impairing the long-term reliability of the semiconductor module.

Further, the manufacturing method of the memory cube 100 according to the twelfth embodiment includes forming the groove 806 defining each of the plurality of memory chips 110 on the memory substrate 800a prior to stacking the plurality of memory chips 110. Therefore, in the method for manufacturing the memory cube 100 according to the twelfth embodiment, it is possible to delete (remove) the wiring layers (metal layers) between the plurality of memory chips 110 before the singulation of the memory chip 110 by the plasma dicing. As a result, in the plasma dicing of the method for manufacturing the memory cube 100 according to the twelfth embodiment, since it is not necessary to dice the metal layer, the memory chip 110 can be easily singulated.

In addition, the memory cube 100 may not include the seal ring 160 because corrosion, deterioration, and the like of each device due to moisture absorption and intrusion of impurities and the like can be suppressed. As a result, the method for manufacturing the memory cube 100 according to the twelfth embodiment can simplify the design and manufacturing of the seal ring 160.

In addition, the method for manufacturing the memory cube 100 according to the twelfth embodiment includes stacking a plurality of memory chips having different thicknesses. For example, as shown in FIG. 53, as the mean thickness of the memory chip is a thickness THlₐᵥₑ, the manufacturing method of the memory cube 100 according to the twelfth embodiment includes stacking the memory chip 110 thicker than the thickness THlₐᵥₑ and the memory chip 110 thinner than the thickness THlₐᵥₑ. Consequently, in the manufacturing method of the memory cube 100 according to the twelfth embodiment, the mean thickness of the memory chip can be set to a thickness THlₐᵥₑ±5 μm. Specifically, the mean thickness THlₐᵥₑ of the memory chip included in the memory cube 100 shown in FIG. 53 can be expressed by the following Formula (1) using a thickness of the DAF 810 as a thickness DT. That is, in the method for manufacturing the memory cube 100 according to the twelfth embodiment, it is possible to reduce variations in the thicknesses of the plurality of memory cubes 100.

$$\frac{( TH 16 + TH 17 + TH 18 + TH 19 - 2 \times DT}{4} \leq {THI}_{ave} \pm 5 μm \qquad ( 1 )$$

### 13. Thirteenth Embodiment

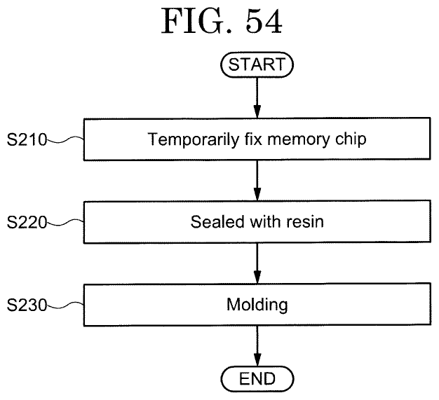

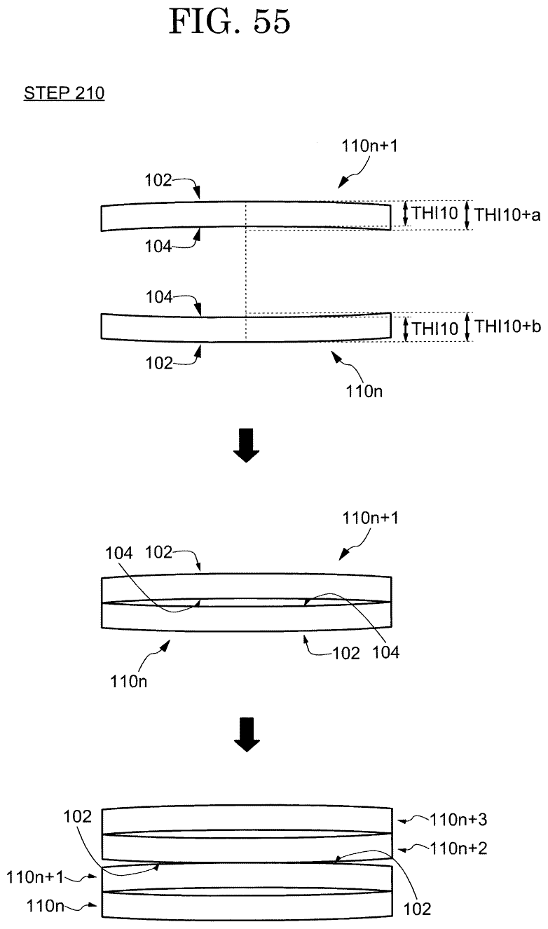

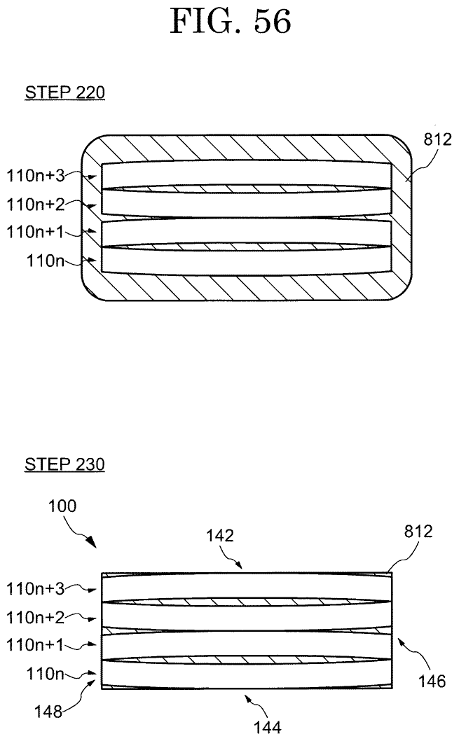

A method of manufacturing the memory cube 100 according to a thirteenth embodiment will be described with reference to FIG. 54 to FIG. 56. FIG. 54 is a flowchart showing a method of manufacturing the memory cube 100. FIG. 55 is a cross-sectional view showing step S210 (STEP 210) of the manufacturing method of the memory cube 100. FIG. 56 is a cross-sectional view showing step S220 (STEP 220) in the method of manufacturing the memory cube 100, and a cross-sectional view showing step S230 (STEP 230) in the method of manufacturing the memory cube 100. The same or similar configurations as those in FIG. 1 to FIG. 53 will not be described here.

As shown in FIG. 54, the method for manufacturing the memory cube 100 includes steps S210 (STEP 210) to S230 (STEP 230). For example, the plurality of memory chips 110 includes the same configuration as that of the first embodiment. Therefore, a configuration similar to that of the first embodiment in the memory chip 110 will be described as necessary.

For example, when the manufacturing method of the memory cube 100 is started, the memory chips 110n and 110n+1 are prepared. For example, as shown in FIG. 55, the memory chip 110n includes the concave first surface 102 and the convex second surface 104 with the chip warped. For example, a thickness of the memory chip 110n is a thickness THI10+a, and a distance (thickness) between the concave first surface 102 and the convex second surface 104 is a thickness THI10. Similar to the memory chip 110n, the memory chip 110n+1 includes the concave first surface 102 and the convex second surface 104, and the chip is warped. Further, for example, a thickness of the memory chip 110n+1 is a thickness THI10+b, and a distance (thickness) between the concave first surface 102 and the convex second surface 104 is a thickness THI10.

STEP 210 is a step of stacking and temporarily fixing a plurality of memory chips. As shown in FIG. 55, STEP 210 includes that the convex second surface 104 of the memory chip 110n is temporarily bonded (F2F bonded) with the convex second surface 104 of the memory chip 110n+1, that the convex second surface 104 of the memory chip 110n+2 is temporarily bonded (F2F bonded) to the convex second surface 104 of the memory chip 110n+3, and that the temporarily bonded concave first surfaces 102 of the memory chips 110n and 110n+1 are temporarily bonded to the concave first surfaces 102 of the memory chips 110n+2 and 110n+3. In addition, in STEP 210 surfaces may be temporarily bonded by mechanically adjusting the positions of the memory chips using alignment markers (not shown) provided in the memory chips 110n to 110n+3. Further, the position of each memory chip may be adjusted with reference to a chip outer shape by using a surface tension (not shown) of a liquid such as water applied to the chip surface in advance, and then temporarily bonded. In addition, an example of how to manufacture the memory cube 100 according to the thirteenth embodiment is an example in which four memory chips 110n to 110n+3 are stacked and temporarily fixed.

As shown in FIG. 56, STEP 220 is a step of sealing the temporarily bonded memory chips 110n to 110n+3 with resin. For example, the resin is a molding material 812. For example, STEP 220 is a step of the present bonding. In addition, a plurality of memory chips that are temporarily bonded can be collectively bonded (collectively molded) by STEP 220. Since each of the memory chips 110n to 110n+3 has a warp, a space is included between adjacent memory chips in the temporarily bonded memory chips 110n to 110n+3. Therefore, the resin can be injected into the respective spaces by STEP 220, and the temporarily bonded memory chips 110n to 110n+3 can be sealed with the resin.

STEP 230 is a step of manufacturing the memory cube 100 by polishing and shaping the memory chips 110n to 110n+3 sealed by STEP 220. A method for manufacturing the memory cube 100 includes polishing the memory chips 110n to 110n+3, planarizing the first side 142 and the second side 144 corresponding to an outermost surface along the direction D1 of the memory cube 100, planarizing the second side 145 and the fourth side 147 corresponding to an outermost surface along the direction D2 of the memory cube 100, and planarizing the first side 146 and the third side 148 corresponding to an outermost surface along the direction D3 of the memory cube 100, thereby forming the memory cube 100. In the manufacturing method of the memory cube 100 according to the thirteenth embodiment, surplus resin of the memory chips 110n to 110n+3 sealed by STEP 220 can be removed.

In addition, although not shown, the method includes forming a flat second side surface 145 (see FIG. 1) and a flat fourth side surface 147 (see FIG. 1). For example, the CMP device can be used for polishing.

As described above, the memory cube 100 is formed.

Since the memory chip has inherent warpage, in the method for manufacturing the memory cube to which the method for manufacturing the memory cube 100 according to the thirteenth embodiment is not applied, when the number of memory chips to be stacked increases, the stress of each memory chip is integrated. As a result, in the method for manufacturing the memory cube to which the method for manufacturing the memory cube 100 according to the thirteenth embodiment is not applied, there is a possibility that the memory cube may be damaged. Also, if each memory chip is bonded using an adhesive, the long-term reliability of the memory cube may be affected depending on the thickness of the adhesive.

Meanwhile, the memory cube 100 according to the thirteenth embodiment includes STEP 210 to STEP 230. In the method for manufacturing the memory cube 100 according to the thirteenth embodiment, the temporary bonding and the main bonding can be performed while maintaining the inherent warpage of the memory chip. As a result, in the method for manufacturing the memory cube 100 according to the thirteenth embodiment, even if the number of memory chips to be stacked is increased, it is possible to suppress integration of the stress of each memory chip and suppress the defect caused by the integration of the stress of each memory chip. Further, for example, the manufacturing method of the memory cube 100 according to the thirteenth embodiment includes stacking a plurality of memory chips 110 by F2F bonding, and includes resin sealing between the stacked memory chips 110. Therefore, the method for manufacturing the memory cube 100 according to the thirteenth embodiment includes sealing each memory chip by filling a gap caused by warpage with resin, so that the thickness of the resin can be minimized.

### 14. Fourteenth Embodiment

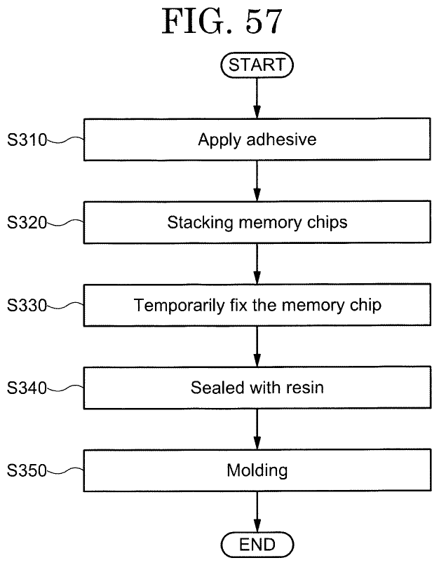

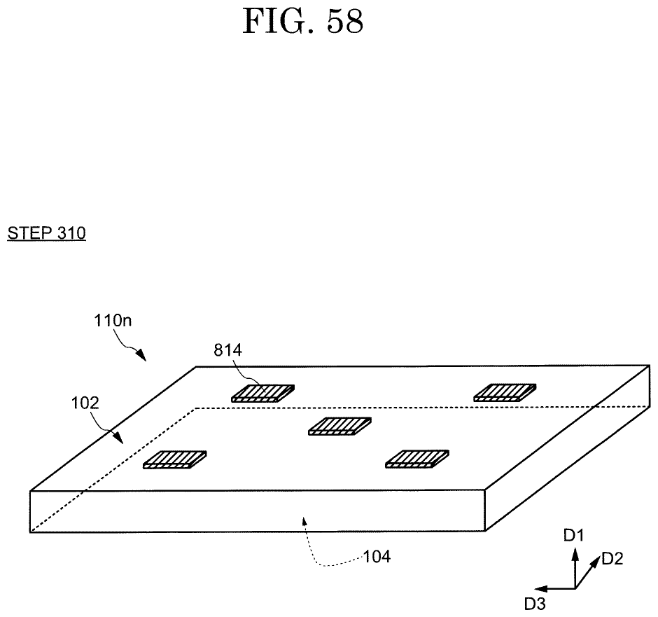

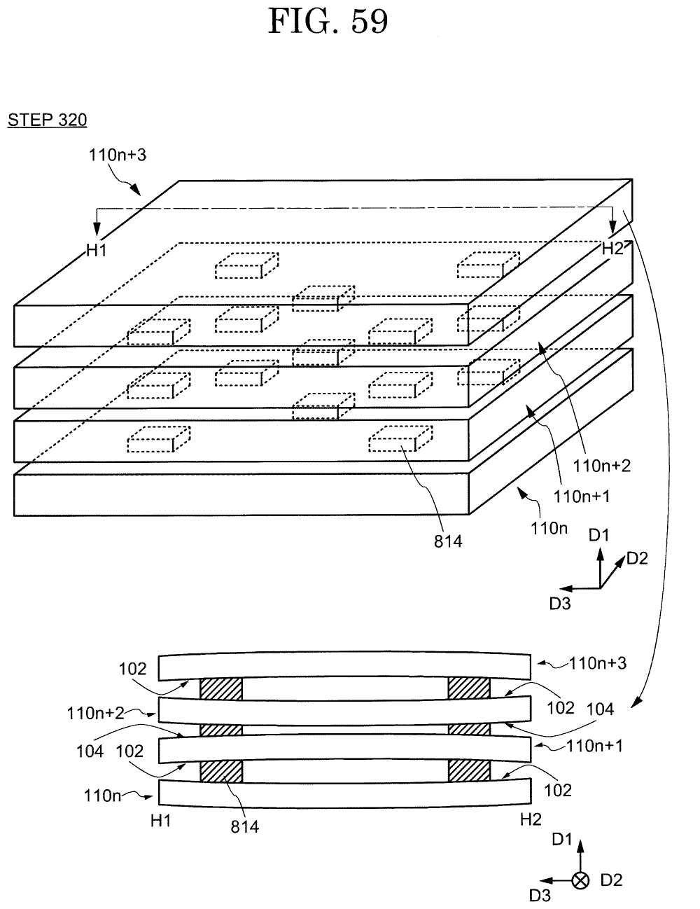

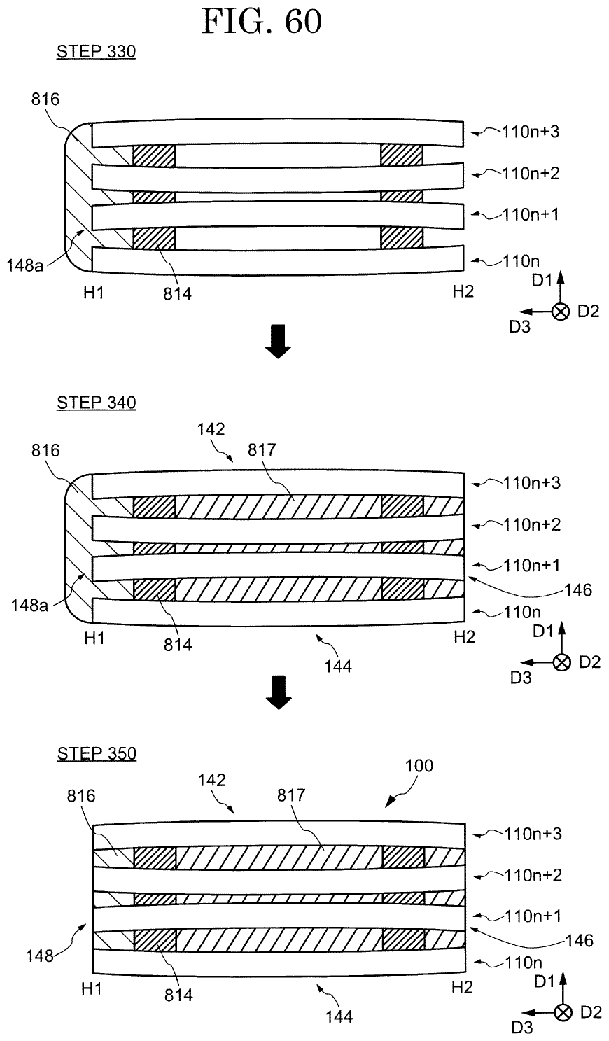

A method for manufacturing the memory cube 100 according to a fourteenth embodiment will be described with reference to FIG. 57 to FIG. 60. FIG. 57 is a flowchart showing a method for manufacturing the memory cube 100. FIG. 58 is a perspective view showing step S310 (STEP 310) of the manufacturing method of the memory cube 100. FIG. 59 is a perspective view showing step S320 (STEP 320) of a manufacturing method of the memory cube 100 and a cross-sectional view showing a cross section taken along a line H1-H2. FIG. 60 is a cross-sectional view showing step S330 (STEP 330) to step S350 (STEP 350) in the manufacturing method of the memory cube 100. Descriptions of the same or similar configurations as those in FIG. 1 to FIG. 56 will be omitted.

As shown in FIG. 57, the method for manufacturing the memory cube 100 include step S310 (STEP 310) to S350 (STEP 350). For example, the plurality of memory chips 110 includes the same configuration as that of the first embodiment. Therefore, a configuration similar to that of the first embodiment in the memory chip 110 will be described as necessary.

For example, when the manufacturing method of the memory cube 100 is started, the memory chips 110n to 110n+3 are prepared. An example of the manufacturing method of the memory cube 100 according to the fourteenth embodiment is an example in which four memory chips 110n to 110n+3 are stacked. In order to explain the manufacturing method of the memory cube 100 according to the fourteenth embodiment in an easy-to-understand manner, the first surface 102 and the second surface 104 of each of the memory chips 110n to 110n+3 shown in FIG. 58 and FIG. 59 are flat surfaces. In practice, each memory chip is warped, as shown in a cross-section along a line H1-H2 shown in FIG. 59 and in each cross-section in FIG. 60.

STEP 310 is a step of applying an adhesive 814 to the memory chip 110n. For example, as shown in FIG. 58, the adhesive 814 is applied over the first side 102 of the memory chip 110n. In addition, as shown in FIG. 59, the adhesive 814 is also applied on the second surface 104 of the memory chip 110n+1 and on the first surface 102 of the memory chip 110n+2. An exemplary method for manufacturing the memory cube 100 according to the fourteenth embodiment includes applying the adhesive 814 to five locations on respective corresponding surfaces of the memory chips 110n to 110n+2. In addition, positions of the adhesive 814 on the corresponding surfaces of the memory chips 110n to 110n+2 are not limited to those shown in FIG. 58.

STEP 320 is a step of stacking a plurality of memory chips. As shown in FIG. 59, the memory chip 110n+1 is bonded to the memory chip 110n such that the first surface 102 of the memory chip 110n+1 is bonded to the adhesive 814 on the first surface 102 of the memory chip 110n. That is, the memory chip 110n+1 is stacked on the memory chip 110n such that the first surface 102 of the memory chip 110n+1 faces the first surface 102 of the memory chip 110n. In addition, the memory chip 110n+2 is bonded to the memory chip 110n+1 so that the second surface 104 of the memory chip 110n+2 is bonded to the adhesive 814 on the second surface 104 of the memory chip 110n+1. That is, the memory chip 110n+2 is stacked on the memory chip 110n+1 such that the second surface 104 of the memory chip 110n+2 faces the second surface 104 of the memory chip 110n+1. Similarly, the memory chip 110n+3 is bonded to the memory chip 110n+2 such that the first surface 102 of the memory chip 110n+3 is bonded to the adhesive 814 on the first surface 102 of the memory chip 110n+2. That is, the memory chip 110n+3 is stacked on the memory chip 110n+2 such that the first surface 102 of the memory chip 110n+3 faces the first surface 102 of the memory chip 110n+2.

STEP 330 is a step of temporarily bonding the plurality of stacked memory chips 110n to 110n+3. Specifically, as shown in STEP 330 of FIG. 60, STEP 330 includes sealing an end part 148a that ultimately corresponds to the third side surface 148 of the memory cube 100 with a UF agent 816.

An exemplary manufacturing method of the memory cube 100 according to the fourteenth embodiment can be temporarily bonded by STEP 330 while maintaining the inherent warpage of the memory chip. STEP 330 may be performed in a vacuum environment.

As shown in FIG. 59, STEP 340 is a step of sealing the memory chips 110n to 110n+3 which are temporarily bonded with resin. For example, an example of a method for manufacturing the memory cube 100 according to the fourteenth embodiment includes injecting resin into a gap between the memory chips from the first side surface 146, the second side surface 145 (see FIG. 1), and the fourth side surface 147 (see FIG. 1). For example, the resin is a UF agent 817.

STEP 350 is a step of manufacturing the memory cube 100 by polishing and shaping the memory chips 110n to 110n+3 sealed by STEP 340. The manufacturing method of the memory cube 100 includes, as in the thirteenth embodiment, polishing the memory chips 110n to 110n+3, planarizing the first surface 142 and the second surface 144 corresponding to an outermost surface along the direction D1 of the memory cube 100, planarizing the second side surface 145 and the fourth side surface 147 corresponding to an outermost surface along the direction D2 of the memory cube 100, and planarizing the first side surface 146 and the third side surface 148 corresponding to an outermost surface along the direction D3 of the memory cube 100, thereby forming the memory cube 100. In the manufacturing method of the memory cube 100 according to the fourteenth embodiment, the memory cube 100 can be formed by removing surplus resin of the sealed memory chips 110n to 110n+3 by STEP 350.

In addition, although not shown, the method includes forming a flat second side surface 145 (see FIG. 1) and a flat fourth side surface 147 (see FIG. 1). For example, the CMP device can be used for polishing.

As described above, the memory cube 100 is formed.

Since the memory chip has inherent warpage, in the method for manufacturing the memory cube to which the method for manufacturing the memory cube 100 according to the fourteenth embodiment is not applied, when the number of memory chips to be stacked increases, the stress of each memory chip is integrated. As a result, in the method for manufacturing a memory cube to which the method for manufacturing the memory cube 100 according to the fourteenth embodiment is not applied, there is a possibility that the memory cube may be damaged. Also, if each memory chip is bonded using an adhesive, the long-term reliability of the memory cube may be affected depending on a thickness of the adhesive.

Meanwhile, the manufacturing method of the memory cube 100 according to the fourteenth embodiment includes STEP 310 to STEP 350. Manufacturing methods of the memory cube 100 according to the fourteenth embodiment include applying the adhesive 814 to a plurality of locations on a surface such as the memory chip 110n, bonding and laminating a plurality of memory chips such as the memory chip 110n using the adhesive 814, applying and temporarily bonding the UF agent 816 to the end part 148a of a plurality of memory chips such as the memory chip 110n, and injecting and sealing the UF agent 817 from each side surface of the memory cube 100 after the temporary bonding. As a result, in the method for manufacturing the memory cube 100 according to the fourteenth embodiment, it is possible to temporarily bond and permanently bond the memory chips while maintaining the inherent warpage of the memory chips. As a result, in the method for manufacturing the memory cube 100 according to the fourteenth embodiment, even if the number of stacked memory chips is increased, it is possible to suppress the integration of the stress of each memory chip and suppress the defect caused by the integration of the stress of each memory chip. In addition, since the manufacturing method of the memory cube 100 according to the fourteenth embodiment includes sealing the memory chips by filling the gaps caused by the warpage with the UF agents 816 and 817, a thickness of the resin can be minimized.

### 15. Fifteenth Embodiment

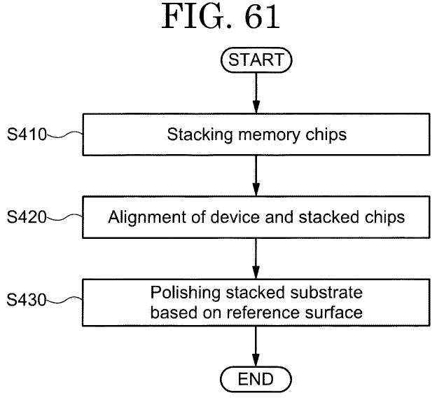

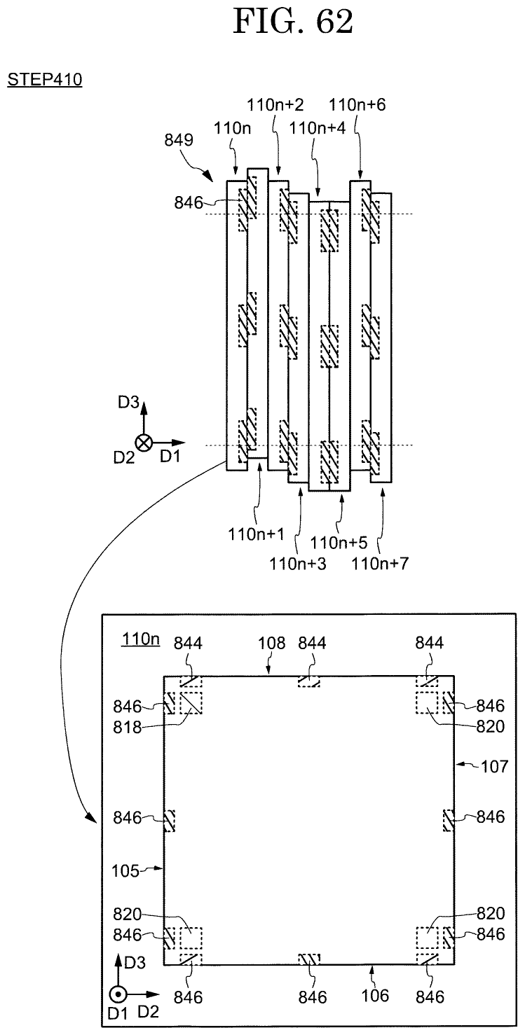

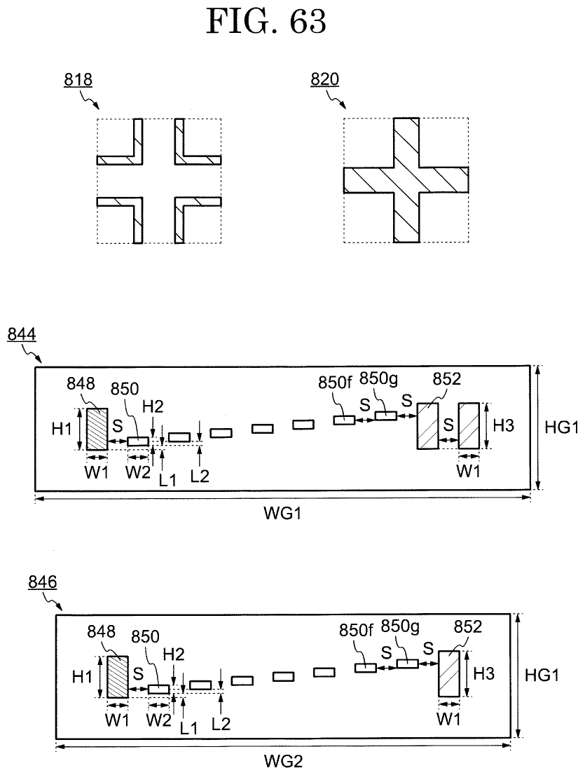

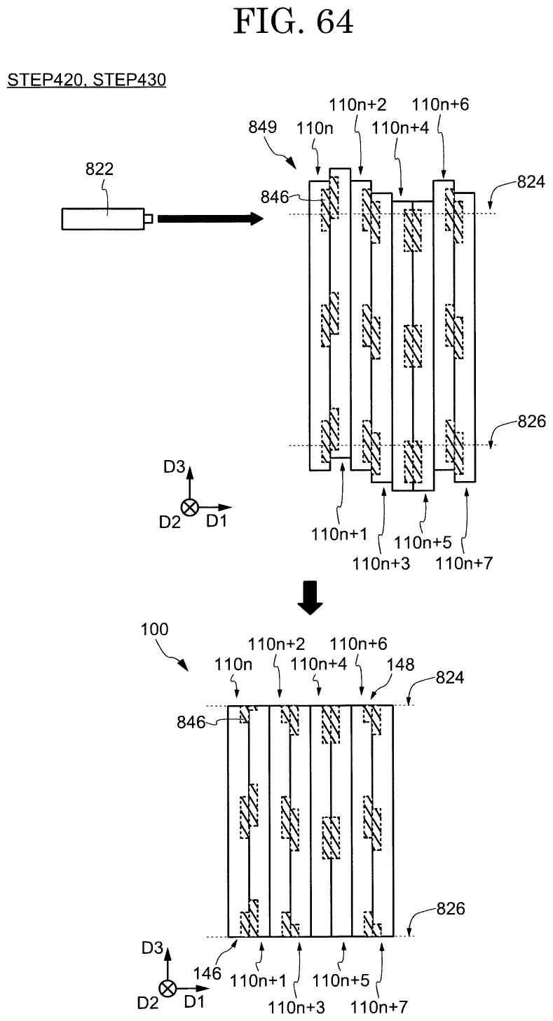

A method for manufacturing the memory cube 100 according to the fifteenth embodiment will be described with reference to FIG. 61 to FIG. 64. FIG. 61 is a flowchart showing the method for manufacturing the memory cube 100. FIG. 62 is a cross-sectional view showing step S410 (STEP 410) of the manufacturing method of the memory cube 100 and a plan view of the memory chip 110. FIG. 63 is a plan view showing a plurality of markers used in the method of manufacturing the memory cube 100. FIG. 64 is a cross-sectional view showing an example of step S420 (STEP 420) and an example of step S430 (STEP 430) in the manufacturing method of the memory cube 100. The same or similar configurations as those in FIG. 1 to FIG. 60 will not be described here.

As shown in FIG. 61, the method for manufacturing the memory cube 100 include step S410 (STEP 410) to step S430 (STEP 430). For example, each of the plurality of memory chips 110n to 110n+7 (see FIG. 62) includes the same configuration as the memory chip 110 described in the first embodiment. Further, stacking of the plurality of memory chips 110n to 110n+7 includes the same configuration as the configuration of the plurality of memory chips 110n to 110n+5 stacked by F2F bonding described in the first embodiment. Therefore, a configuration similar to that of the first embodiment in the memory chip 110 and the like will be described as necessary.

Since the memory chips 110n to 110n+7 include the same configuration, the configuration of the memory chip 110n will be described here, and the configurations of the memory chips 110n+1 to 110n+7 will be described as needed. As shown in FIG. 62, the memory chip 110n includes a marker 818, a plurality of markers 820, and a plurality of marker groups 844 and 846. Although not shown, for example, the marker 818, the plurality of markers 820, and the plurality of marker groups 844 and 846 are formed in the same layers as the power wiring 164, the ground wiring 165, the signal transmission wiring 166 (see FIG. 3, FIG. 7A, FIG. 7B, and the like), and the wiring 183 (see FIG. 11B and the like).

First, with reference to FIG. 62 and FIG. 63, the marker 818, the plurality of markers 820, and the plurality of marker groups 844 and 846 will be described in detail.

For example, the marker 818 and the marker 820 are markers for adjusting a position of a laser irradiation device 822 and a stacked chip 849. For example, the marker groups 844 and 846 are markers for adjusting positions between the memory chips and polishing amounts of the memory chips and detecting the positions between the memory chips when the stacked chip 849 is planarized using the laser irradiation device 822. Further, for example, the marker groups 844 and 846 are markers for adjusting positions between the memory chips and polishing amounts of the memory chips and detecting the positions between the memory chips when the stacked chip 849 is planarized using the CMP device.

As shown in FIG. 62, for example, the marker 818 is arranged at a corner portion where the second side surface 105 and the third side surface 108 intersect, and is formed to be parallel to the direction D2 and the direction D3. The marker 820 is arranged at a corner portion at which the third side surface 108 and the fourth side surface 107 intersect, a corner portion at which the fourth side surface 107 and the first side surface 106 intersect, and a corner portion at which the first side surface 106 and the second side surface 105 intersect, and is formed parallel to the direction D2 and the direction D3. Three marker groups 844 are arranged in parallel along the third side surface 108. Three marker groups 846 are arranged in parallel along each of the first side surface 106, the second side surface 105, and the fourth side surface 107.

The marker 818, the plurality of markers 820, and the plurality of marker groups 844 and 846 are configured as shown in FIG. 63. The markers 818 and 820 may be referred to as alignment markers, and the marker groups 844 and 846 may be referred to as detection markers.

For example, the marker 818 has a bordered cross-shaped component shape, and the marker 820 has a cross shape. In addition, the shapes of the markers 818 and 820 shown in FIG. 63 are merely examples, and the shapes of the markers 818 and 820 may be any shapes as long as the positions of the laser irradiation device 822 and the stacked chip 849 can be adjusted. For example, the marker group 844 includes a marker 848, a plurality of markers 850, and a plurality of markers 852. For example, the marker group 844 includes seven markers 850 and two markers 852. The marker 848 is a rectangular marker having a height H1 and a width W1, marker 850 is a rectangular marker having a height H2 and a width W2, and marker 852 is a rectangular marker having a height H3 and a width W1. A distance between the marker 848 and the marker 850, a distance between the markers 850, a distance between the marker 850 and the marker 852, and a distance between the markers 852 are distances S. A distance between a bottom of the marker 848 and a bottom of the marker 850 is a distance L1, and a distance between a bottom of the marker 850 and a bottom of the adjacent marker 850 is a distance L2. In addition, for example, a width of the marker group 844 is a width WG1, and a height of the marker group 844 is a height HG1. In addition, a configuration of the marker group 844 shown in FIG. 63 is an example, and is not limited to the example shown here. For example, the number and shape of each marker can be changed according to the configuration, specification, application, and the like of the memory cube 100.

For example, marker group 846 has fewer markers 852 than marker group 844. Further, a width of the marker group 846 is a width WG2, and a height of the marker group 846 is the height HG1. Other configurations of the marker group 846 are the same as those of the marker group 844, and description thereof will be omitted.

In the marker groups 844 and 846 according to the fifteenth embodiment, for example, the height H1 is 10 μm, the width W1 and the width W2 are 5 μm, the height H2 is 2 μm, the height H3 is 11 μm, the width WG1 is 120 μm, the height HG1 is 30 μm, and the width WG2 is 110 μm.

Next, a method for manufacturing the memory cube 100 will be described in detail with reference to FIG. 61 to FIG. 64. In addition, although an example of the method for manufacturing the memory cube 100 with reference to FIG. 61 to FIG. 64 includes polishing the stacked chip 849 and manufacturing the memory cube 100 using the laser irradiation device 822, the method for manufacturing the memory cube 100 is not limited to the example with reference to FIG. 61 to FIG. 64. For example, the method for manufacturing the memory cube 100 may include polishing the stacked chip 849 using the CMP device (not shown) to manufacture the memory cube 100, and may include polishing the stacked chip 849 using the laser irradiator device 822 and the CMP device to manufacture the memory cube 100.

For example, when the manufacturing method of the memory cube 100 is started, step S410 (STEP410) is executed. STEP 410 is a step of stacking a plurality of memory chips. As shown in FIG. 62, an example of the manufacturing method of the memory cube 100 according to the fifteenth embodiment is an example including F2F bonding and stacking of eight memory chips 110n to 110n+7 and forming the stacked chip 849. In order to explain an example of the method for manufacturing the memory cube 100 according to the fifteenth embodiment in an easy-to-understand manner, reference signs of the first surface and the second surface of each memory chip are omitted.

STEP 420 is, for example, a step of adjusting positions of the laser irradiator device 822 and the stacked chip 849 with reference to the marker 818 and the plurality of markers 820 included in the stacked chip 849. Adjusting the positions of the laser irradiation device 822 and the stacked chip 849 may be referred to as, for example, alignment between the laser irradiation device 822 and the stacked chip 849.

STEP 430 is a step of irradiating the stacked chip 849 with a laser and polishing the stacked chip 849 according to the positions of the laser irradiator device 822 and the stacked chip 849 adjusted by STEP 420. For example, as shown in FIG. 64, STEP 430 includes, based on a reference surface 824, irradiating the stacked chip 849 with a laser from the memory chip 110n by the laser irradiation device 822, irradiating the stacked chip 849 with the laser from the laser irradiation device 822 while moving the laser irradiation device 822 along the direction D2, and irradiating the stacked chip 849 with the laser from the laser irradiation device 822 while moving the laser irradiation device 822 along the direction D3 from above the stacked chip 849 toward the reference surface 824.

In this case, STEP 430 includes irradiating the stacked chip 849 with a laser from the laser irradiation device 822 while detecting the markers 848, 850, and 852 included in the plurality of marker groups 844, respectively. Consequently, for example, in the case where a marker 850 g of the plurality of marker groups 844 is exposed from the third side surface 148, it can be seen that the laser irradiation device 822 polishes the stacked chip 849 by 11 μm or more, and in the case where a marker 850f is exposed from the third side surface 148, it can be seen that the laser irradiation device 822 polishes the stacked chip 849 by 13 μm or more. That is, in the manufacturing method of the memory cube 100 according to the fifteenth embodiment, it is possible to detect mutual positional deviations along the direction D1, the direction D2, and the direction D3 of the memory chips 110n to 110n+7 by detecting the markers of each of the memory chips exposed from the third side surface 148.

Further, for example, STEP 430 includes, based on a reference surface 826, irradiating the stacked chip 849 with the laser from the memory chip 110n by the laser irradiation device 822, irradiating the stacked chip 849 with the laser from the laser irradiation device 822 while moving the laser irradiation device 822 along the direction D2, and irradiating the stacked chip 849 with the laser from the laser irradiation device 822 while moving the laser irradiation device 822 along the direction D3 from below the stacked chip 849 toward the reference surface 826. As a consequence, in the manufacturing method of the memory cube 100 according to the fifteenth embodiment, similar to the third side surface 148, by detecting the markers of the memory chips exposed from the first side surface 146, it is possible to detect mutual positional deviations along the direction D1, the direction D2, and the direction D3 of the memory chips 110n to 110n+7.

Further, for example, STEP 430 includes, based on the reference surfaces 824 and 826, irradiating the stacked chip 849 with the laser from the memory chip 110n by the laser irradiation device 822, and irradiating the stacked chip 849 with the laser from the laser irradiation device 822 while moving the laser irradiation device 822 along the direction D3 and the direction D2. As a consequence, in the manufacturing method of the memory cube 100 according to the fifteenth embodiment, similar to the third side surface 148, by detecting the markers of the memory chips exposed from the second side surface 145, it is possible to detect mutual positional deviation along the direction D1, the direction D2, and the direction D3 of the memory chips 110n to 110n+7. In the manufacturing method of the memory cube 100 according to the fifteenth embodiment, similar to the second side surface 145, by detecting the markers of the respective memory chips exposed from the fourth side surface 147, it is possible to detect mutual positional deviation along the direction D1, the direction D2, and the direction D3 of the memory chips 110n to 110n+7.

In addition, in the case where the CMP device is used, STEP 420 is a step to install the stacked chip 849 in the CMP device. STEP 430 of using the CMP device is to polish the stacked chip 849 while adjusting a polishing amount of the memory chip with reference to the marker groups 844 and 846. For example, STEP 430 includes polishing the third side surface 148 with the CMP device while detecting the markers 848, 850, and 852 included in each of the plurality of marker groups 844 so as to have a polishing amount corresponding to the reference surface 824. Further, for example, STEP 430 includes polishing the first side surface 146 by the CMP device while detecting the markers 848, 850, and 852 included in each of the plurality of marker groups 844 so as to have a polishing amount corresponding to the reference surface 826. STEP 430 includes polishing the second side 145 and the fourth side 147 with the CMP device, as well as the third side 148 and the first side 146. As a consequence, the manufacturing method of the memory cube 100 according to the fifteenth embodiment includes the use of the CMP device, and the same advantageous effects as those obtained by using the laser irradiation device 822 can be obtained.

Further, in the case where the stacked chip 849 is polished and the memory cube 100 is manufactured using the laser irradiation device 822 and the CMP device, first, STEP 420 and STEP 430 are executed using the CMP device to roughly polish the stacked chip 849, then STEP 420 and STEP 430 are executed using the laser irradiation device 822, and the stacked chip 849 is polished to finely adjust the polishing amount. First, STEP 420 and STEP 430 may be performed using the laser irradiator 822 to polish the stacked chip 849, and then STEP 420 and STEP 430 may be performed using the CMP device to polish the stacked chip 849. As a consequence, the manufacturing method of the memory cube 100 according to the fifteenth embodiment includes the use of the laser irradiation device 822 and the CMP device, and can achieve the same advantageous effects as those obtained in the case where the laser irradiation device 822 is used or in the case where the CMP device is used.

As described above, the memory cube 100 is formed.

When a plurality of memory chips are stacked, positional deviation occurs between the plurality of memory chips along the direction D1, the direction D2, and the direction D3. For example, in the method for manufacturing a memory cube to which the method for manufacturing the memory cube 100 according to the fifteenth embodiment is not applied, if the memory cube is polished using the CMP device, there is a possibility that a side surface of the memory cube is flattened so as to have a slope, and therefore, there is a possibility that a predetermined flatness of the memory cube cannot be obtained. Further, for example, in the method for manufacturing a memory cube to which the method for manufacturing the memory cube 100 according to the fifteenth embodiment is not applied, it is difficult to detect positions of the memory chips included in the memory cube with respect to each other, and if the memory cube is polished using the CMP device, the memory cube may be polished exceeding a predetermined polishing amount.

Meanwhile, the memory cube 100 according to the fifteenth embodiment includes the markers 818 and 820 for adjusting the positions of the device for polishing and the memory chip (for example, the memory chip 110n), and the marker groups 844 and 846 for adjusting the positions between the memory chips and the polishing amounts of the memory chips and detecting the positions between the memory chips. The memory cube 100 according to the fifteenth embodiment includes STEP 410 to STEP 430. The manufacturing method of the memory cube 100 according to the fifteenth embodiment includes stacking the plurality of memory chips 110n to 110n+7, adjusting a position of a device for polishing and the memory chip (for example, the memory chip 110n), polishing each side surface of the stacked chip 849 based on preset reference surfaces 824 and 826, exposing each side surface of the plurality of memory chips 110n to 110n+7, and detecting a position of the plurality of memory chips 110n to 110n+7 with respect to each other using the plurality of marker groups 844 and 846 exposed from each side surface of the plurality of memory chips 110n to 110n+7. As a result, in the manufacturing method of the memory cube 100 according to the fifteenth embodiment, since the positions of the plurality of memory chips 110n to 110n+7 included in the memory cube 100 can be adjusted based on the plurality of markers, the memory cube 100 having a flat predetermined side surface can be manufactured. Further, in the manufacturing method of the memory cube 100 according to the fifteenth embodiment, the positions of the plurality of memory chips 110n to 110n+7 can be adjusted and the positions of the plurality of memory chips 110n to 110n+7 can be detected as three-dimensional data based on the direction D1 to the direction D3.

Therefore, polishing of the side surfaces of the memory cube 100 (the plurality of memory chips 110n to 110n+7) can be stopped at a predetermined polishing amount. That is, the method for manufacturing the memory cube 100 according to the fifteenth embodiment can be configured such that each side surface of the memory cube 100 according to the fifteenth embodiment has a predetermined flatness. Further, since the memory cube 100 according to the fifteenth embodiment has high flatness on each side surface, positional deviation at the time of connection between the memory cube 100 according to the fifteenth embodiment and the logic chip 200 (see FIG. 1) is suppressed.

### 16. Sixteenth Embodiment

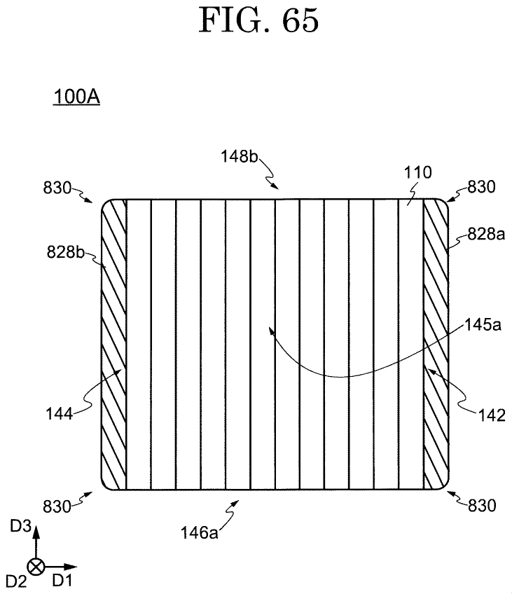

A semiconductor module 10L and a memory cube 100A included in the semiconductor module 10L according to the sixteenth embodiment will be described referring to FIG. 65 to FIG. 68. The semiconductor module 10L and the memory cube 100A included in the semiconductor module 10L includes a configuration in which the plurality of memory chips 110 are sandwiched by dummy chips 828a and 828b. For example, since other configurations and functions are the same as the configurations and functions described in the first embodiment and the like, detailed description thereof will be omitted here. In addition, the semiconductor module 10L can be appropriately combined with or replaced with the configurations described in the first to fifteenth embodiments as long as they do not contradict each other.

### [16-1. Configuration of Memory Cube 100A]

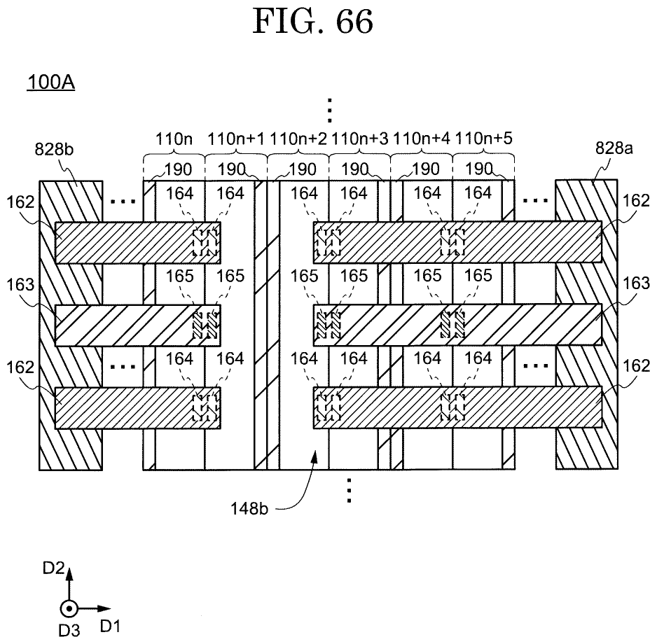

An exemplary configuration of the memory cube 100A will be described referring to FIG. 65 and FIG. 66. FIG. 65 is a side view (plan view) showing a side view of the memory cube 100A viewed from a second side 145a of the memory cube 100A. FIG. 66 is a side view (plan view) showing a side view of the memory cube 100A viewed from a third side 148b of the memory cube 100A. Descriptions of the same or similar configurations as those in FIG. 1 to FIG. 64 will be omitted.

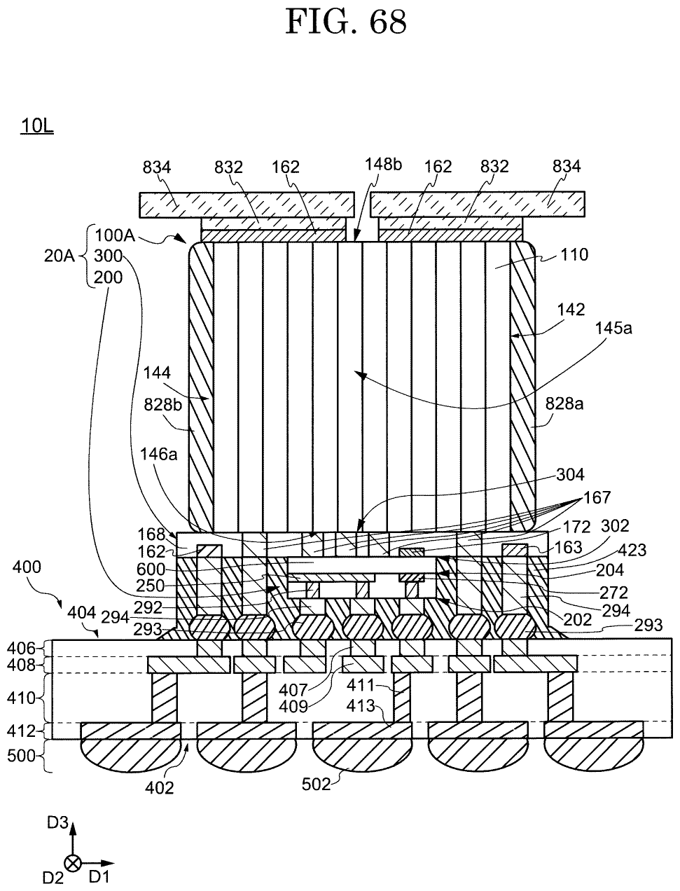

The memory cube 100A includes a configuration in which a plurality of memory chips 110 are stacked, and includes a configuration in which a plurality of memory chips 110 are sandwiched by the dummy chips 828a and 828b. The memory cube 100A also includes the first surface 142 parallel to the direction D2 and the direction D3 and the second surface 144 opposite the first surface 142 and parallel to the first surface 142 with respect to the direction D1. In addition, the memory cube 100A includes a first side surface 146a perpendicular to the first surface 142 and the second surface 144, a second side surface 145a adjacent to the first side surface 146a, a third side surface 148b adjacent to the second side surface 145a, and a fourth side surface (not shown) adjacent to the third side surface 148b and the first side surface 146a. The first side surface 146a of the memory cube 100A contacts a second surface 304 (see FIG. 68) of the rewiring layers 300 (see FIG. 68). The first side 146a is in contact with the rewiring layer 300, the memory cube 100A is electrically connected to the rewiring layer 300, and the memory cube 100A is arranged on the second surface 204 of the logic chip 200 (see FIG. 68). In addition, as described in the first embodiment, the logic chip 200 includes the plurality of TCI-IO 212 and the plurality of logic modules 211, but for example, the plurality of TCI-IO 212 and the plurality of logic modules 211 may be formed on different substrates, and the plurality of TCI-IO 212 formed on different substrates and the plurality of logic modules 211 may be connected to each other using wirings, vias, and the like, and may be stacked.

In the memory cube 100A, the first side surface 146a is an outermost surface on the side where the logic chip 200 is arranged in the direction D3, and the third side surface 148b is an outermost surface on the side opposite the first side surface 146a in the direction D3. The second side surface 145a and the fourth side surface opposite the second side surface 145a are the two outermost surfaces of the memory cube 100A in the direction D2.

The dummy chip 828a contacts the first surface 142 and is arranged on the outermost side of the memory cube 100A in the direction D1, and includes an outermost surface. The dummy chip 828b contacts the second surface 144 and is arranged on the outermost side of the memory cube 100A in the direction D1, and includes an outermost surface. Also, the corner portions of the outermost surfaces of the dummy chips 828a and 828b include an R surface 830. For example, the dummy chips 828a and 828b do not include the wiring layers 150, transistors, and the like. For example, the dummy chips 828a and 828b are a Si substrate and a Si-wafer.

The memory cube 100A also includes a configuration similar to the memory cube 100 described with respect to FIG. 8A and FIG. 8B. Specifically, the memory cube 100A includes a configuration in which the side power wirings 162 are formed on the plurality of power wirings 164 exposed on the third side surface 148b, and the side ground wirings 163 are formed on the plurality of ground wirings 165. For example, the side power wiring 162 is arranged so as to contact a portion of the side surface and the upper surface of the insulating film 168 (see FIG. 8B), the four power supply wirings 164 exposed on the first side surfaces 106n+2 to 106n+5 of the memory chips 110n+2 to 110n+5, and the first side surfaces 106n+2 to 106n+5 of the memory chips 110n+2 to 110n+5, and overlaps the dummy chips 828a and 828b. Further, similar to the side power wiring 162, the other side power wiring 162 is arranged so as to be in contact with a portion of the side surface and the upper surface of the insulating film 168, the two power wiring wirings 164 exposed on the first side surfaces 106n to 106n+1 of the memory chips 110n to 110n+1, and the first side surfaces 106n to 106n+1 of the memory chips 110n to 110n+1, and overlaps the dummy chips 828a and 828b.

In addition, for example, the side ground wiring 163 has the same configuration and function as the side power wiring 162.

In addition, the side power wirings 162 and the side ground wirings 163 extend in the direction D1 and are alternately arranged along the direction D2 in the direction D1, for example, and overlap the dummy chips 828a and 828b.

The memory cube 100A includes the configuration described above. For example, if the corner portions of the outermost surface of the memory cube do not include an R surface, the corner portions of the memory cube are easily chipped. On the other hand, the outermost part of the memory cube 100A includes the dummy chips 828a and 828b including the R surface 830. Therefore, the memory cube 100A can protect the circuit inside the memory cube 100 and the devices such as transistors from an impact from the outside of the memory cube 100A. Consequently, long-term reliability of the memory cube 100A is higher. Although an example is shown in which an outermost surface of a memory cube according to an embodiment of the present invention is an R surface, the outermost surface of the memory cube according to the embodiment of the present invention is not limited to the R surface. A corner portion of a memory cube according to an embodiment of the present invention may be configured so as not to be easily chipped. For example, an outermost part of a memory cube according to an embodiment of the present invention may be a C surface, a thread surface, or a corner cut surface, and the R surface may be called a C surface, a thread surface, a corner cut surface, or the like.

Further, since thermal conduction of the dummy chips 828a and 828b is better than that of the memory chips 110n to 110n+7, the memory cube 100A can suppress thermal expansion toward the memory chips 110n to 110n+7.

### [16-2. Configuration of Memory Cube 100B]

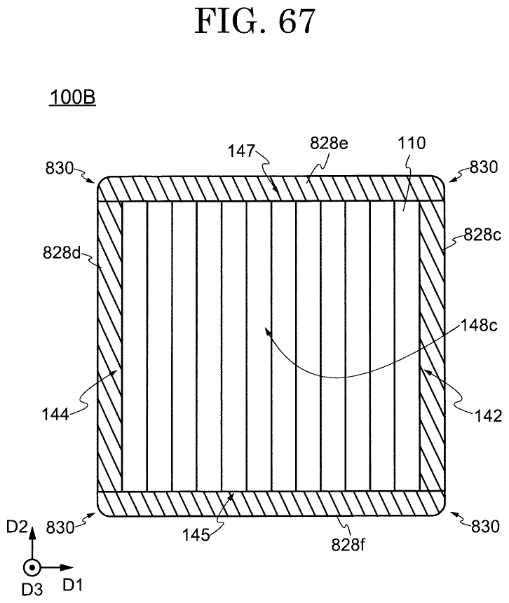

An exemplary configuration of a memory cube 100B will be described referring to FIG. 67. FIG. 67 is a side view (plan view) showing a side view of the memory cube 100B viewed from a third side surface 148c of the memory cube 100B. Descriptions of the same or similar configurations as those in FIG. 1 to FIG. 66 will be omitted.

The memory cube 100B does not include the dummy chips 828a and 828b as compared to the memory cube 100A, and includes the dummy chips 828c to 828f. The memory cube 100B is configured to surround the first surface 142, the second surface 144, the fourth side surface 147, and the second side surface 145 with the dummy chips 828c to 828f. In the memory cube 100B, the third side surface 148c facing the first side surface 146a and the first side surface 146a of the plurality of stacked memory chips 110 are not surrounded by the dummy chips. The remaining configuration of the memory cube 100B is similar to the configuration of the memory cube 100A, and the configuration of the memory cube 100A will be described as needed.

In the memory cube 100B, the first side surface 146a is an outermost surface on the side where the logic chip 200 is arranged in the direction D3, and the third side surface 148c is an outermost surface on the side opposite the first side surface 146a in the direction D3. The first side surface 146a is in contact with and electrically connected to the rewiring layer 300, and the memory cube 100B is arranged on the second side 204 of the logic chip 200 (see FIG. 68).

The dummy chip 828c contacts the first surface 142 and is arranged on the outermost side of the memory cube 100B in the direction D1, and includes an outermost surface. The dummy chip 828d is arranged on the outermost side of the memory cube 100B in the direction D1 while contacting the second surface 144, and includes an outermost surface.

The dummy chip 828e contacts the fourth side surface 147, an end part of the dummy chip 828c on a side of the fourth side surface 147, and an end part of the dummy chip 828d on a side of the fourth side surface 147, and is arranged on the outermost side of the memory cube 100B in the direction D2, and includes an outermost surface. The dummy chip 828f includes the second side surface 145, an end part of the dummy chip 828c on a side of the second side surface 145, and an end part of the dummy chip 828d on a side of the second side surface 145, and an outermost surface arranged on the outermost side of the memory cube 100B in the direction D2. Also, the corner portions of the outermost surfaces of the dummy chips 828e and 828f include R surfaces 830.

In addition, the dummy chips 828c to 828f do not include the wiring layers 150, transistors, and the like, similar to the dummy chips 828a and 828b. For example, the dummy chips 828c to 828f are a Si substrate and a Si-wafer similar to the dummy chips 828a and 828b.

In addition, the memory cube 100B may include a configuration in which, similar to the memory cube 100A, the side power wiring 162 is formed on the plurality of power wirings 164 exposed on the third side surface 148c, and the side ground wirings 163 are formed on the plurality of ground wiring wirings 165.

Further, when the memory cube 100B includes the side power wiring 162 and the side ground wiring 163 similar to those of the memory cube 100A, the side power wirings 162 and the side ground wirings 163 extend in the direction D1, are alternately arranged along the direction D2 in parallel to the direction D1, overlap the dummy chips 828c and 828d, and do not overlap the dummy chips 828e and 828f.

Further, the memory cube 100B includes the configuration described above. The outermost part of the memory cube 100B includes the dummy chips 828c and 828d including the R surface 830, and the dummy chips 828e and 828f. That is, except for the first side surfaces 146a and the third side surfaces 148c of the plurality of memory chips 110 in the memory cube 100B, the first surface 142, the second surface 144, the second side surface 145, and the fourth side surface 147 are surrounded by the dummy chips 828c to 828f.

Therefore, the memory cube 100B can protect the circuit inside the memory cube 100B and devices such as transistors from an external impact of the memory cube 100B. Consequently, the long-term reliability of the memory cube 100B is higher.

In addition, since thermal conductivity of the dummy chips 828c to 828d is better than that of the memory chips 110n to 110n+7, the memory cube 100B can suppress thermal expansion toward the memory chips 110n to 110n+7 except for the first side surface 146a and the third side surface 148c.

### [16-3. Configuration of Semiconductor Module 10L]

A mounting example of the semiconductor module 10L will be described referring to FIG. 68. FIG. 68 is a cross-sectional view showing the mounting example of the semiconductor module 10L. The same or similar configurations as those in FIG. 1 to FIG. 67 will be omitted here.

The semiconductor module 10L replaces the memory cube 100 of the semiconductor module 10D with the memory cube 100A as compared to the semiconductor module 10D shown in FIG. 17, and includes a conductive layer 832 and a heat spreader 834. The remaining configuration of the semiconductor module 10L is the same as that of the semiconductor module 10D, and the same configuration as that of the semiconductor module 10D will be described as needed. In addition, the semiconductor module 10L may include a heat sink (not shown), and may include the heat spreader 834 on which the heat sink is arranged. The memory cube 100A may be the memory cube 100B. The heat spreader 834 may be referred to as a heat conductive member.

The side power wiring 162 is electrically connected to the conductive layer 832. For example, the conductive layer 832 is solder. The heat spreader 834 is electrically connected to the conductive layer 832, and is electrically connected to the side power wiring 162 via the conductive layer 832.

The semiconductor module 10L includes the configuration described above.

For example, an upper limit Tⱼₘₐₓₘ of an operating temperature of the plurality of memory chips 110 is lower than an upper limit Tᵢₘₐₓᵣ of an operating temperature of the logic chip 200. For example, the upper limit Tⱼₘₐₓₘ is approximately 85° C. and the upper limit Tⱼₘₐₓᵣ is approximately 125° C. That is, if heat is transferred to the memory cube 100A due to the heat generated by the logic chip 200, there is a risk that the memory cube 100A may not operate normally.

The memory cube 100A and the logic chip 200 of the semiconductor module 10L can transmit signals to each other by inductor communication. That is, the memory cube 100A and the logic chip 200 the semiconductor module 10L do not transmit signals using physical wirings. Therefore, the memory cube 100A and the logic chip 200 can suppress generation of cracks due to warpage of the chip. Consequently, the semiconductor module 10L is excellent in long-term reliability.

In addition, since the memory cube 100A is sandwiched between the dummy chips 828a and 828b, the heat generated in the memory cube 100A can be discharged to the outside of the semiconductor module 10L via the dummy chips 828a and 828b. Further, since the logic chip 200 is electrically connected to the wiring substrate 400, heat generated in the logic chip 200 can be discharged to the outside of the semiconductor module 10L via the wiring substrate 400. Further, the semiconductor module 10L includes a configuration in which the side power wiring 162 and the heat spreader 834 are electrically connected, and power for driving the semiconductor module 10L is supplied to the side power wiring 162 through the heat spreader 834. The heat spreader 834 supplies power to the semiconductor module 10L and can diffuse heat generated in the semiconductor module 10L.

Therefore, the memory cube 100A and the logic chip 200 of the semiconductor module 10L can suppress the electric interference and thermal interference from each other. As a consequence, the memory cube 100A and the logic chip 200 of the semiconductor module 10L can be stably operated by suppressing thermal malfunctions. Further, since the semiconductor module 10L suppresses malfunctions due to heat, thermal designs of the respective members constituting the respective circuits and the respective devices in the semiconductor module 10L can be simplified.

### 17. Seventeenth Embodiment

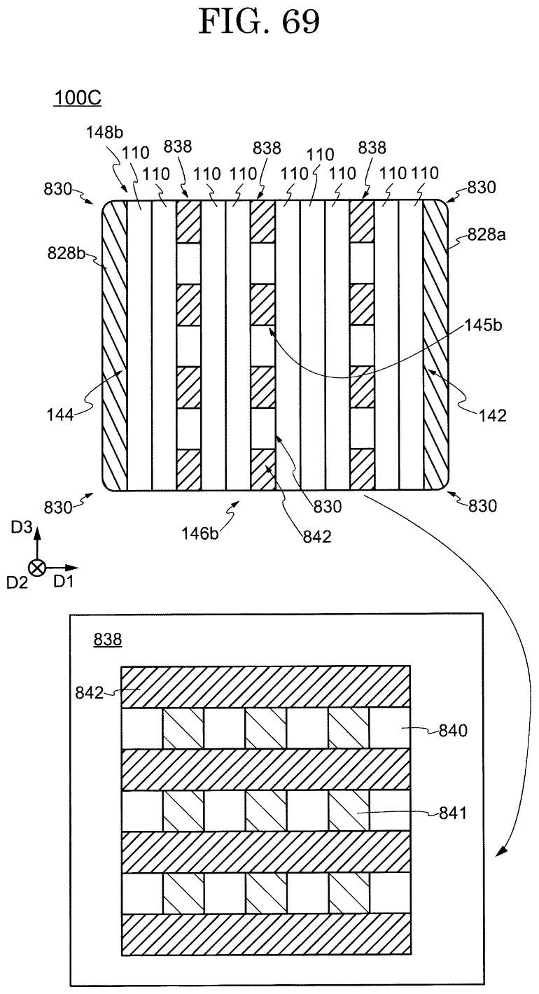

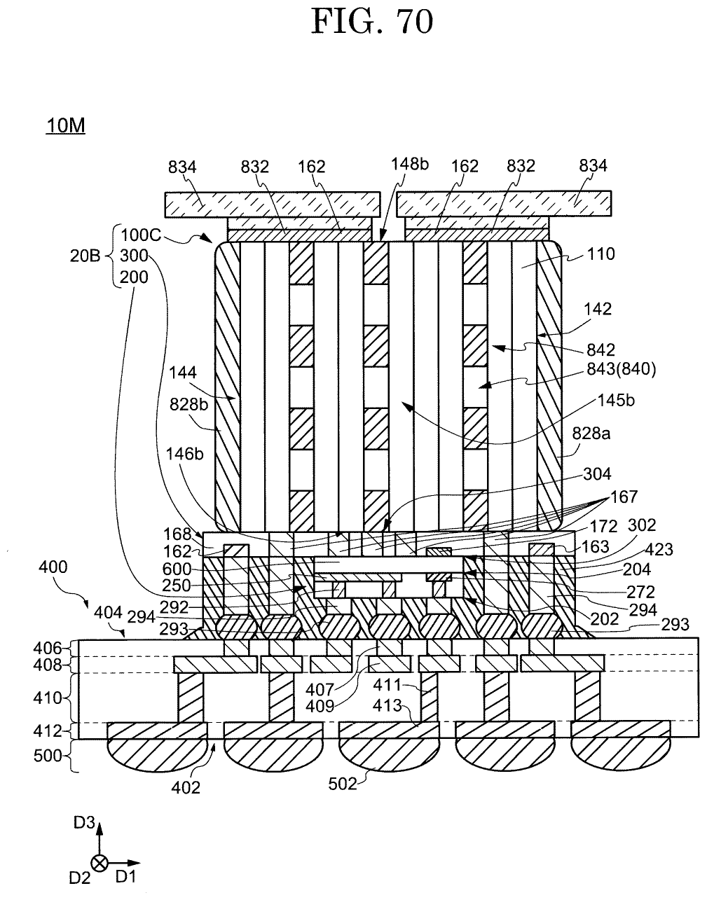

A semiconductor module 10M and a memory cube 100C included in the semiconductor module 10M according to the seventeenth embodiment will be described referring to FIG. 69 and FIG. 70. The semiconductor module 10M and the memory cube 100C included in the semiconductor module 10M include dummy chips 838 including a configuration in which the plurality of memory chips 110 is sandwiched by the dummy chips 828a and 828b, and an opening 840 and a bottom opening 841 between any chips of the plurality of memory chips 110. For example, since other configurations and functions are the same as those described in the sixteenth embodiment and the like, a detailed description thereof will be omitted. In addition, the semiconductor module 10M according to the seventeenth embodiment can be appropriately combined with or replaced with the configurations described in the first to sixteenth embodiments as long as they do not contradict each other.

### [17-1. Configuration of Memory Cube 100C]

An exemplary configuration of the memory cube 100C will be described referring to FIG. 69. FIG. 69 is a side view (plan view) showing a side surface of the memory cube 100C from the second side 145a of the memory cube 100C, and a plan view of the dummy chip 838. The same or similar configurations as those in FIG. 1 to FIG. 68 will not be described here.

The memory cube 100C includes the plurality of dummy chips 838 shown in FIG. 69 as compared to the memory cube 100A. The remaining configuration of the memory cube 100C is similar to the configuration of the memory cube 100A, and the configuration of the memory cube 100A will be described as needed.

For example, the dummy chip 838 is arranged between two memory chips 110. The plurality of memory chips 110 are arranged between two dummy chips 838. For example, the plurality of memory chips 110 may be two, three, four, or more, and may include both a configuration in which two memory chips 110 are stacked and a configuration in which three memory chips 110 are stacked.

In addition, the dummy chip 838 includes a substrate 842, and the opening 840 and the bottom opening 841 formed in the substrate 842. The substrate 842 is a Si substrate and a Si-wafer similar to the dummy chips 828a to 828f. The opening 840 is arranged adjacent to the bottom opening 841.

### [17-2. Configuration of Semiconductor Module 10M]

A mounting example of the semiconductor module 10M will be described referring to FIG. 70. FIG. 70 is a cross-sectional view showing the mounting example of the semiconductor module 10M. The same or similar configurations as those in FIG. 1 to FIG. 69 will not be described here.

The semiconductor module 10M replaces the memory cube 100A with the memory cube 100C as compared to the semiconductor module 10L shown in FIG. 68. The remaining configuration of the semiconductor module 10M is the same as that of the semiconductor module 10L, and the same configuration as that of the semiconductor module 10L will be described as needed.

The semiconductor module 10M includes the plurality of dummy chips 838. For example, since the plurality of dummy chips 838 includes the openings 840 and the bottom openings 841, the memory cube 100C includes a plurality of cavities 843 along the direction D2.

The semiconductor module 10M includes the configuration described above.

For example, the upper limit Tⱼₘₐₓₘ of the operating temperature of the plurality of memory chips 110 is lower than the upper limit Tᵢₘₐₓᵣ of the operating temperature of the logic chip 200. For example, the upper limit Tⱼₘₐₓₘ is approximately 85° C. and the upper limit Tᵢₘₐₓᵣ is approximately 125° C. That is, if heat is transferred to the memory cube 100C due to the heat generated by the logic chip 200, there is a risk that the memory cube 100C may not operate normally.

The semiconductor module 10M and the memory cube 100C include configurations similar to those of the semiconductor module 10L and the memory cube 100B. Therefore, the semiconductor module 10M and the memory cube 100C have the same advantageous effects as those of the semiconductor module 10L and the memory cube 100B. That is, the semiconductor module 10M and the memory cube 100C can suppress generation of cracks due to warpage of the chip, and are excellent in long-term reliability. In addition, the semiconductor module 10M and the memory cube 100C can diffuse the heat generated in the semiconductor module 10M through the dummy chips 828a and 828b and the heat spreader 834 and discharge the heat to the outside of the semiconductor module 10M.

In addition, for example, the semiconductor module 10M may be used in a coolant. For example, the coolant may comprise fluorine and may comprise isobutane. Since the semiconductor module 10M includes the cavity 843, the cavity 843 functions as a flow path of the coolant. Consequently, the semiconductor module 10M can dissipate heat through the coolant passing through the cavity 843.

Therefore, the semiconductor module 10M can be cooled by liquid immersion in the case where the semiconductor module 10M is immersed in the coolant. In addition, the cavity 843 increases a surface area of the semiconductor module 10M, so that the semiconductor module 10M is a highly cooling-efficient module.

### 18. Eighteenth Embodiment

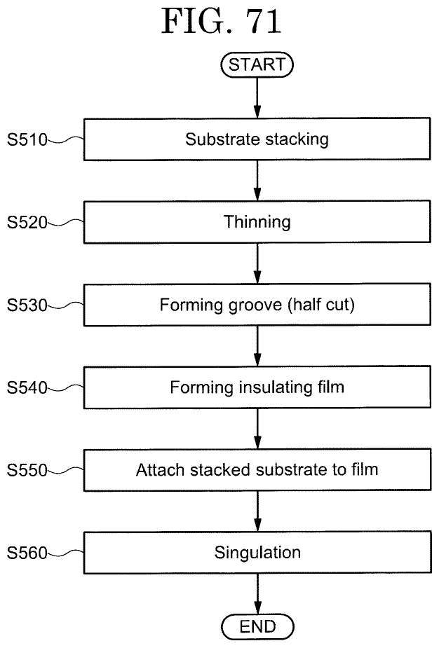

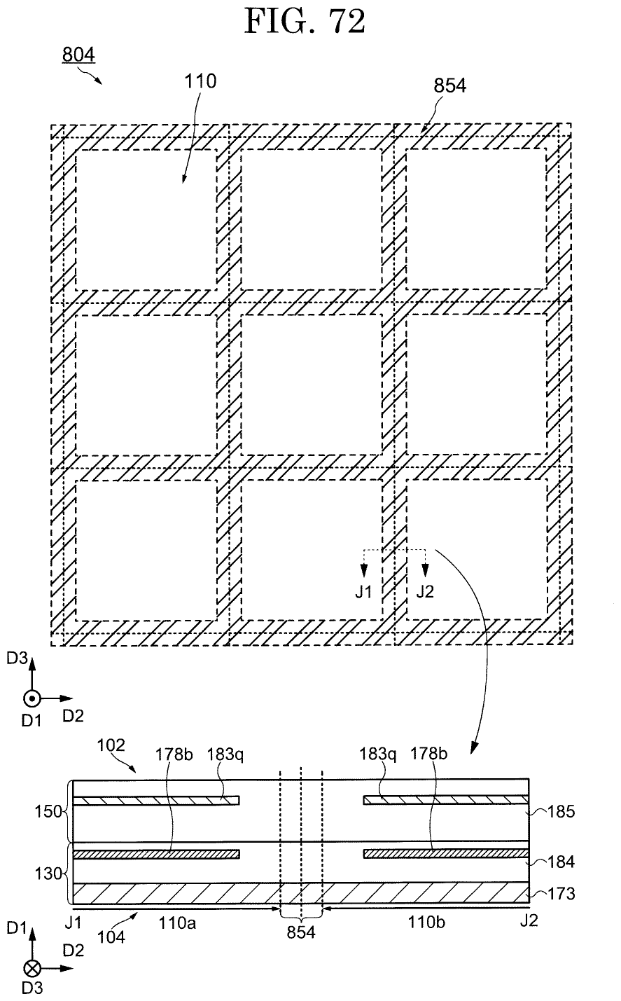

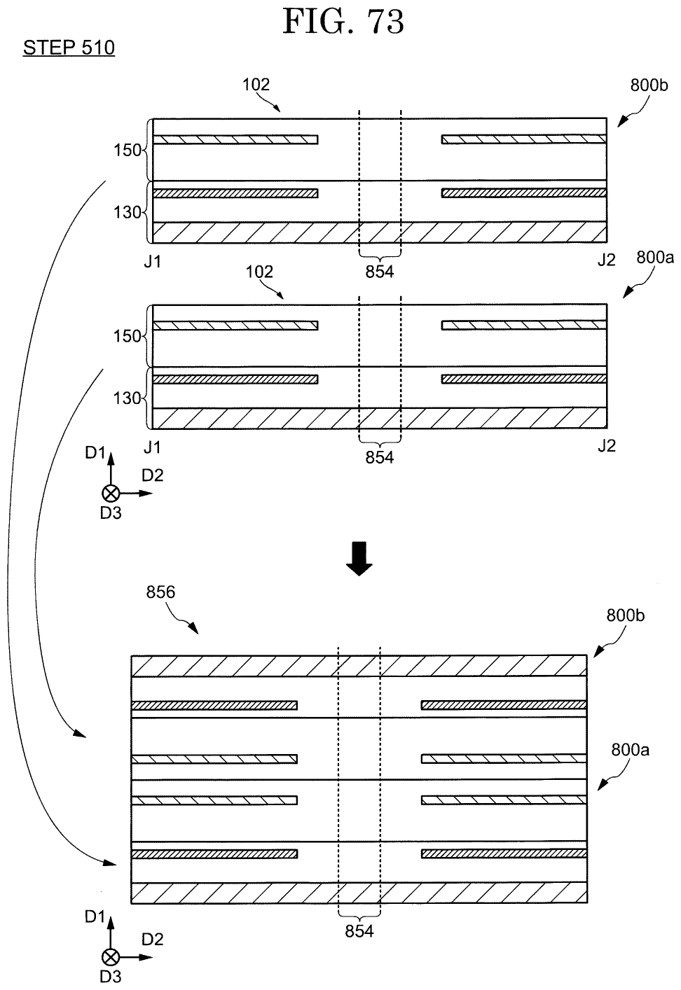

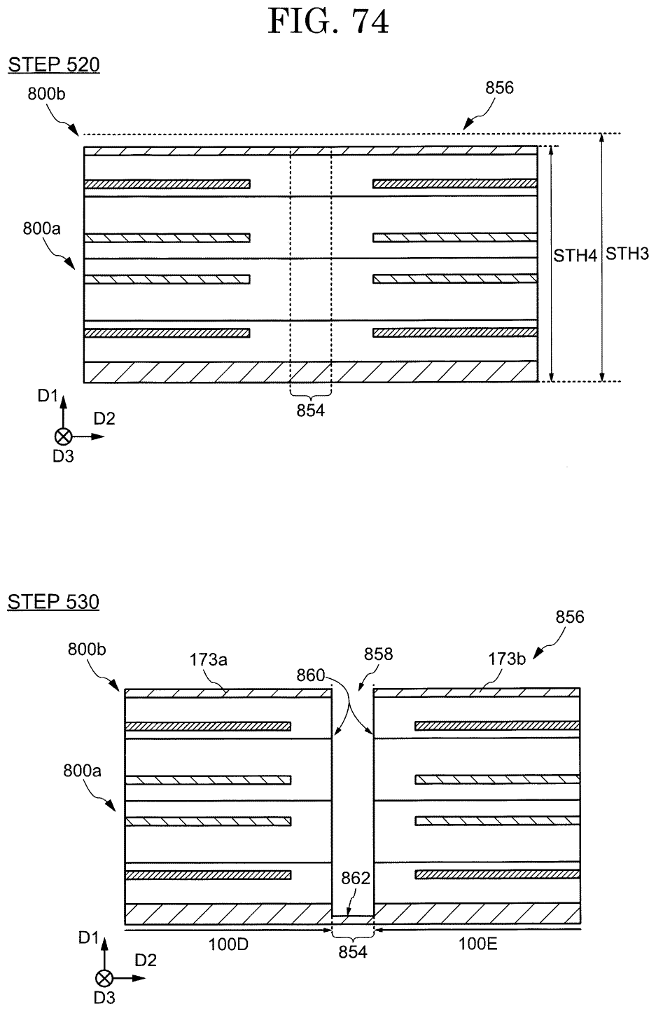

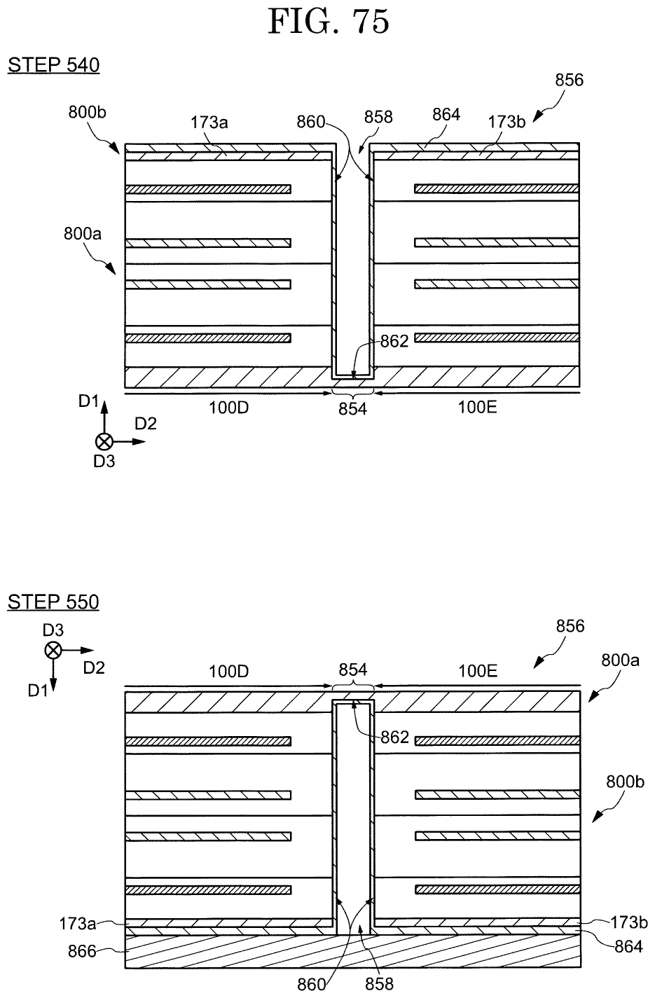

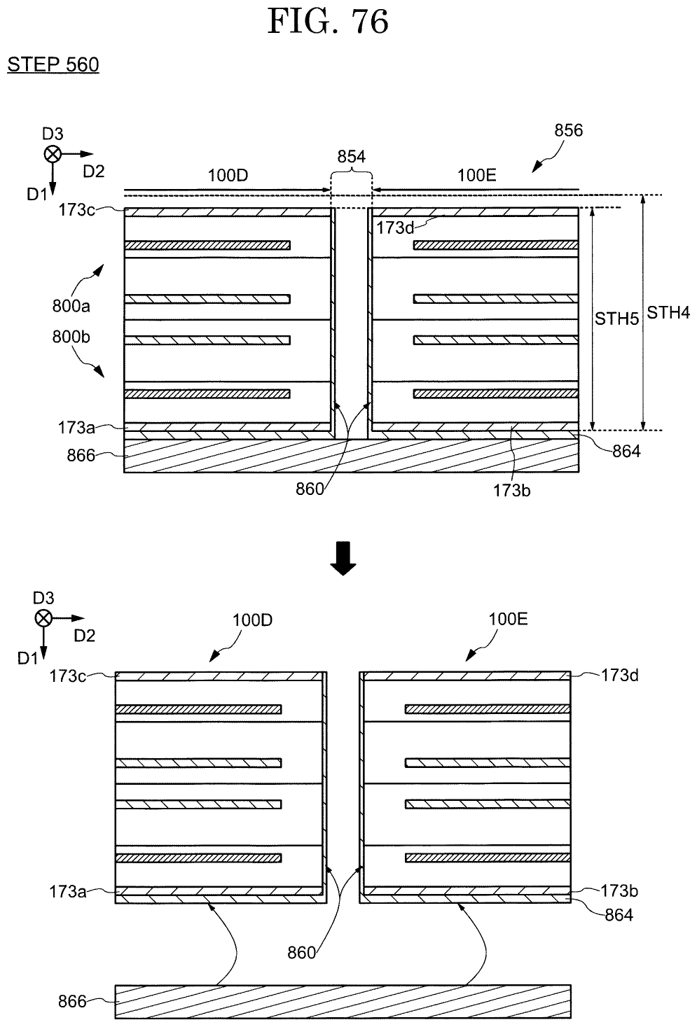

A method for manufacturing the memory cube 100 according to an eighteenth embodiment will be described with reference to FIG. 48, FIG. 71 to FIG. 76. FIG. 71 is a flowchart showing the method for manufacturing the memory cube 100. FIG. 48 is a plan view showing the method for manufacturing the memory cube 100. FIG. 72 is a plan view showing a manufacturing method of the memory cube 100 and a cross-sectional view showing a cross section of the memory chip region 804 along a line J1-J2. FIG. 72 is an enlarged view of the memory chip region 804. FIG. 73 is a cross-sectional view of the memory substrates 800a and 800b taken along a line J1-J2, showing step S510 (STEP 510) in the manufacturing method of the memory cube 100. FIG. 74 is a cross-sectional view showing step S520 (STEP 520) and step S530 (STEP 530) of the manufacturing method of the memory cube 100. FIG. 75 is a cross-sectional view showing step S540 (STEP 540) and step S550 (STEP 550) in the manufacturing method of the memory cube 100. FIG. 76 is a cross-sectional view showing step 560 (STEP 560) of the manufacturing method of the memory cube 100. The same or similar configurations as those in FIG. 1 to FIG. 70 will not be described here.

As shown in FIG. 71, the method for fabricating the memory cube 100 includes STEP 510 to STEP 560.

When the manufacturing method of the memory cube 100 is started, the memory substrate 800a is prepared as in the twelfth embodiment. For example, the memory substrate 800a includes the configuration described with respect to FIG. 48. Here, the configuration of the memory substrate 800a shown in FIG. 48 will be described as needed. Further, for example, although the plurality of memory chips 110 includes the same configuration as that of the first embodiment, the same configuration as that of the first embodiment in the memory chip 110 will be described as necessary.

As shown in FIG. 72, the memory substrate 800a (FIG. 48) includes a memory chip region 804, and the memory chip region 804 includes a dicing region 854. The dicing region 854 is a region for stacking a plurality of substrates and dicing the stacked substrates. For example, as shown in the cross-sectional view along a line J1-J2 in FIG. 72, the dicing region 854 for separating memory chips 110a and 110b does not include a wiring 183q and a wiring 178b. That is, the dicing region 854 includes the insulating layers 184 and 185 and the like, and does not include a layer including a metal such as a wiring.

The STEP 510 is a step of laminating a memory substrate. For example, by performing STEP 510 shown in FIG. 73, the first surface 102 of the memory substrate 800a and the first surface 102 of the memory substrate 800b are F2F bonded to each other to form a stacked substrate 856. In this case, as shown in FIG. 73, ideally, the memory substrates 800a and 800b overlap each other, and the dicing regions 854 are grouped together. In practice, however, it goes without saying that there are variations in the bonding.

STEP 520 is a step of thinning the stacked substrate 856. By performing STEP 520 shown in FIG. 74, the substrate 173 of the memory substrate 800b is thinned, and the stacked substrate 856 is planarized. For example, as shown in FIG. 74, the surface of the substrate 173 of the memory substrate 800b is polished, and a thickness STH3 of the stacked substrate 856 is thinned to a thickness STH4.

STEP 530 is a step of forming a groove 858 that defines each of a plurality of memory cubes including memory cubes 100D and 100E. For example, by performing STEP 530 shown in FIG. 74, the grooves 858 are formed in the dicing region 854 using plasma dicing. The groove 858 ultimately includes a sidewall 860 that is part of the side surface of the memory cubes 100D and 100E, as well as a bottom part 862. The sidewall 860 includes portions of the side surfaces of the transistor layers 130 and the wiring layers 150 of the memory substrates 800a and 800b, respectively. The bottom part 862 is formed on the substrate 173 of the memory substrate 800a. In addition, the plasma dicing in STEP 530 is sometimes referred to as half-cutting.

STEP 540 is a step of forming insulating layer 864 in the groove 858. By performing STEP 540 shown in FIG. 75, the insulating layers 864 are formed on the grooves 858 and the thinned substrates 173a and 173b. For example, materials and devices for forming the insulating layer 864 may be materials and devices for forming the insulating layer 807.

In STEP 550, the stacked substrate 856 on which the insulating layer 864 is formed in STEP 540 is attached to an adhesive layer 866. For example, the insulating layer 864 is attached to the adhesive layer 866 by performing STEP 550 shown in FIG. 75. The stacked substrate 856 is fixed to the adhesive layer 866 by bonding the stacked substrate 856 to the adhesive layer 866. That is, the adhesive layer 866 has a function of fixing and supporting the stacked substrate 856. Consequently, stable singulation can be achieved in the step of singulation (S560) after STEP 550. For example, the adhesive layers 866 may be adhesive films and may be back grinding tapes (Back Grinding Tape, BGT). For example, the BGT is used in a back grinding process of a semiconductor substrate, and is an adhesive tape for protecting the semiconductor substrate.

Step 560 (STEP 560) is a step of forming a single layer of the stacked substrate 856 to which the adhesive layers 866 are attached in STEP 550. For example, by performing STEP 560 shown in FIG. 76, the stacked substrate 856 is polished using the CMP device, and part of the substrate 173 and the bottom part 862 of the memory substrate 800b are removed. By performing STEP 560, the substrate 173 of the memory substrate 800b is separated into substrates 173c and 173d corresponding to the individual memory cubes, and the thickness STH4 of the stacked substrate 856 is thinned to a thickness STH5. As a result, as shown in FIG. 76, the stacked substrate 856 can be singulated into individual memory cubes. For example, the individual memory cubes (memory cube 100D and 100E) singulated from the adhesive layers 866 can be removed.

As described above, the memory cube 100 is formed.

A method of manufacturing the memory cube 100 according to the eighteenth embodiment includes laminating a plurality of memory substrates to form a stacked substrate, thinning the stacked substrate, forming a groove including a bottom part along a dicing region of the stacked substrate, forming an insulating layer on the formed groove and a surface of the stacked substrate, attaching a surface including the insulating layer to the adhesive layer, and singulating the stacked substrate by polishing a surface opposite to the adhesive layer of the stacked substrate.

The dicing region 854 of the stacked substrate 856 according to the eighteenth embodiment does not include a metal such as a wiring. As a result, in the plasma dicing of the method for manufacturing the memory cube 100 according to the eighteenth embodiment, since it is not necessary to dice the metal layer, the plurality of memory cubes 100 can be easily singulated.

Further, since the groove 858 is filled with the insulating layer 864, each side surface of each memory cube 100 is covered with the insulating layer 864. Therefore, a low dielectric constant film having high hygroscopicity is not exposed from each side surface of each memory cube 100. As a result, the memory cube 100 according to the eighteenth embodiment can suppress corrosion, deterioration, and the like of each device due to moisture absorption and intrusion of impurities and the like. Therefore, by using the method for manufacturing the memory cube 100 according to the eighteenth embodiment, it is possible to maintain the reliability of the semiconductor module without impairing the long-term reliability of the semiconductor module.

Further, by using the method for manufacturing the memory cube 100 according to the eighteenth embodiment, since each side surface of the memory cube 100 is protected by the insulating layer, moisture absorption and impurities do not enter from each side surface during manufacturing. Therefore, by using the method for manufacturing the memory cube 100 according to the eighteenth embodiment, it is possible to suppress corrosion, deterioration, and the like of each device due to moisture absorption, impurities, and the like at the time of manufacturing, so that the memory cube 100 does not need to include the seal ring 160.

Various configurations of the semiconductor module and the semiconductor module manufacturing method shown as an embodiment of the present invention can be appropriately combined or replaced as long as they do not conflict with each other, and technical matters common to the embodiments are included in the embodiments without explicit description. Further, based on the semiconductor module and the manufacturing method of the semiconductor module disclosed in the present specification and the drawings, any addition, deletion, or design change of components by a person skilled in the art, or addition, omission, or change of conditions of a process, is included in the scope of the present invention as long as it comprises the gist of the present invention.

It is to be understood that the present invention provides other effects that are different from the effects provided by the aspects of the embodiments disclosed herein, and effects that are obvious from the description herein or that can be easily predicted by a person skilled in the art.

### (Additional Notes)

In addition, the present invention is not limited to the embodiments described above, and can be appropriately modified without departing from the scope of the present invention. For example, one embodiment according to the present invention may have the following configuration.

### (Additional Note 1)

A semiconductor module in which a plurality of memory chips includes memory cubes stacked along a first direction in parallel to a plane formed by a second direction orthogonal to the first direction and a third direction orthogonal to the second direction, wherein
the memory cube includes a bottom surface which is an outermost surface on a side where a semiconductor chip is arranged in the third direction,
each of the plurality of memory chips includes a substrate and a wiring layer stacked on the substrate,
the wiring layer includes a first internal wiring, a second internal wiring and a first inductor,
a first insulating film is included between the first internal wiring and the first inductor and the bottom surface,
the second internal wiring is exposed to the bottom surface,
the first internal wiring, the second internal wiring, and the first inductor are spaced apart from each other,
a length of the first internal wiring extending along the second direction is longer than a length of the first inductor extending along the second direction,
a length of the first internal wiring extending along the third direction is shorter than lengths of the first inductor and the second internal wiring extending along the third direction, and
part of the first inductor overlaps the first internal wiring in a cross-sectional view.

### (Additional Note 2)

The semiconductor module according to additional note 1, wherein
the first inductor has a plurality of turns in a plan view,
the first inductor includes a third internal wiring and a fourth internal wiring,
the third internal wiring is arranged in the same layer as the first internal wiring and the fourth internal wiring, and
the first internal wiring, the third internal wiring, and the fourth internal wiring are spaced apart from each other, and the third internal wiring, the first internal wiring, and the fourth internal wiring are arranged in order from the bottom surface.

### (Additional Note 3)

The semiconductor module according to additional note 1, wherein
the first inductor has a plurality of turns and is arranged over at least two memory chips of the plurality of memory chips in a cross-sectional view,
the first inductor includes a fifth internal wiring, and
the fifth internal wiring is arranged in the same layer as the first internal wiring, is spaced apart from the first internal wiring, and is arranged closer to the bottom surface than the first internal wiring.

### (Additional Note 4)

The semiconductor module according to additional note 1, wherein
each of the plurality of memory chips includes a seal ring arranged on an outer peripheral portion of each of the plurality of memory chips, and
the seal ring includes the first internal wiring.

### (Additional Note 5)

The semiconductor module according to additional note 1, wherein
the semiconductor module further includes a rewiring layer arranged on the bottom surface,
the rewiring layer includes a wiring, and
the wiring is electrically connected to the second internal wiring.

### (Additional Note 6)

The semiconductor module according to additional note 5, wherein
the internal wiring includes at least one power wiring exposed to the bottom surface, and
the at least one power wiring includes the second internal wiring.

### (Additional Note 7)

The semiconductor module according to additional note 5, wherein
the semiconductor module further includes a semiconductor chip for driving the memory cube, and includes a first surface and a second surface parallel to the first surface and a second inductor,
the rewiring layer is arranged between the second surface and the bottom surface, and
the second inductor communicates with the first inductor in a non-contact manner.

### (Additional Note 8)

A semiconductor module in which a plurality of memory chips includes memory cubes stacked along a first direction in parallel to a plane formed by a second direction orthogonal to the first direction and a third direction orthogonal to the second direction, wherein
the memory cube includes a bottom surface which is an outermost surface on a side where the semiconductor chip is arranged in the third direction,
each of the plurality of memory chips includes a substrate and a wiring layer stacked on the substrate,
the wiring layer includes a first internal wiring, a second internal wiring and part of a first inductor,
a first insulating film is included between the first internal wiring and the bottom surface,
the second internal wiring is exposed to the bottom surface,
the first internal wiring, the second internal wiring, and the part of the first inductor are spaced apart from each other,
a length of the first internal wiring extending along the second direction is longer than a length of the part of the first inductor extending along the second direction,
a length of the first internal wiring extending along the third direction is shorter than lengths of the first inductor and the second internal wiring extending along the third direction, and
the part of the first inductor overlaps the first internal wiring in a cross-sectional view.

### (Additional Note 9)

The semiconductor module according to additional note 8, wherein
each of the plurality of memory chips includes a seal ring arranged on an outer peripheral portion of each of the plurality of memory chips, and
the seal ring includes the first internal wiring.

### (Additional Note 10)

The semiconductor module according to additional note 8, wherein
the semiconductor module further includes a rewiring layer arranged on the bottom surface,
the rewiring layer includes a first side surface wiring and a second side surface wiring,
the first side surface wiring is electrically connected to the second internal wiring, and
the second side surface wiring is electrically connected to the part of the first inductor, and constitutes the first inductor.

### (Additional Note 11)

The semiconductor module according to additional note 10, wherein
the first inductor has a plurality of turns in a plan view,
the part of the first inductor includes a third internal wiring and a fourth internal wiring,
the rewiring layer further includes a third side surface wiring spaced apart from the first side surface wiring and the second side surface wiring,
the third internal wiring is arranged in a layer different from the first internal wiring, is arranged in the same layer as the second internal wiring and the fourth internal wiring, and is spaced apart from the second internal wiring and the fourth internal wiring,
the third internal wiring is electrically connected to the second side surface wiring, and
the fourth internal wiring is electrically connected to the third side surface wiring.

### (Additional Note 12)

The semiconductor module according to additional note 10, wherein, the first inductor has a plurality of turns and is arranged over at least two memory chips of the plurality of memory chips in a cross-sectional view.

### (Additional Note 13)

The semiconductor module according to additional note 8, wherein
each of the plurality of memory chips includes a seal ring arranged on an outer peripheral portion of each of the plurality of memory chips, and
the seal ring includes the first internal wiring.

### (Additional Note 14)

The semiconductor module according to additional note 10, wherein
the internal wiring includes at least one power wiring exposed to the bottom surface, and
the at least one power wiring includes the second internal wiring.

### (Additional Note 15)

The semiconductor module according to additional note 10, wherein
the semiconductor module further includes a semiconductor chip for driving the memory cube, and having a first surface, a second surface parallel to the first surface, and a second inductor,
the rewiring layer is arranged between the second surface and the bottom surface, and
the second inductor communicates with the first inductor in a non-contact manner.

### (Additional Note 16)

A method for manufacturing a semiconductor module including a memory cube in which a plurality of memory chips are stacked along a first direction in parallel with a plane formed by a second direction orthogonal to the first direction and a third direction orthogonal to the second direction, comprising:
in each of a first memory substrate including a plurality of memory chips and a second memory substrate including a plurality of memory chips, using laser grooving to form a groove partitioning the plurality of memory chips into respective memory chips, forming a first insulating layer in the groove, forming a second insulating layer on the first insulating layer, and polishing the second insulating layer;
laminating the first memory substrate having the polished second insulating layer and the second memory substrate having the polished second insulating layer, and forming a stacked substrate;
dicing the stacked substrate along the groove of the stacked substrate, and singulating the stacked substrate into a plurality of stacked chips;
measuring a thickness of each of the plurality of stacked chips; and
stacking at least two stacked chips of the plurality of stacked chips to form the memory cube.

### (Additional Note 17)

The method for manufacturing the semiconductor module according to additional note 16, further comprising, after forming the stacked substrate, attaching an adhesive layer to the stacked substrate.

### (Additional Note 18)

The method for manufacturing the semiconductor module according to additional note 16, wherein
forming the stacked substrate includes that the polished second insulating layer of the first memory substrate overlaps and is stacked on the polished second insulating layer of the second memory substrate, and
a thickness of the first memory substrate on which the second insulating layer is polished is different from a thickness of the second memory substrate on which the second insulating layer is polished.

### (Additional Note 19)

The method of manufacturing the semiconductor module according to additional note 16, wherein
each of the first memory substrate and the second memory substrate includes a transistor layer including a transistor for driving the first wiring and the memory chip, and a wiring layer including a second wiring and contacting the transistor layer along the first direction, and
the first insulating layer is in contact with a side surface of each of the first wiring and the second wiring exposed in the groove.

### (Additional Note 20)

The method for manufacturing the semiconductor module according to additional note 16, wherein a thickness of each of the plurality of memory chips included in the memory cube is an average thickness of the memory chip −5 μm or more and an average thickness of the memory chip +5 μm or less.

### (Additional Note 21)

A method for manufacturing a semiconductor module in which a plurality of memory chips having warps includes memory cubes stacked along a first direction in parallel to a plane formed by a second direction orthogonal to the first direction and a third direction orthogonal to the second direction, comprising:
bonding a plurality of memory chips having the warps; and
injecting a resin into at least a portion of a space between each of a plurality of memory chips having the bonded warps and sealing the plurality of memory chips having the bonded warps with a resin.

### (Additional Note 22)

The method for manufacturing the semiconductor module according to additional note 21, further comprising polishing the plurality of memory chips having the sealed warp to form the memory cube.

### (Additional Note 23)

The method of manufacturing a semiconductor module according to additional note 22, wherein
the polishing comprises:
   planarizing first surfaces of outermost surfaces along the first direction and second surfaces opposite the first surfaces in the plurality of memory chips having the bonded warpage;
   planarizing second side surfaces of outermost surfaces along the second direction and fourth side surfaces opposite the second side surfaces in the plurality of memory chips having the bonded warp; and
   planarizing first side surfaces of outermost surfaces along the third direction and third side surfaces opposite the first side surfaces in the plurality of memory chips having the bonded warp.

### (Additional Note 24)

The method for manufacturing the semiconductor module in which a plurality of memory chips having warps includes memory cubes stacked along a first direction in parallel to a plane formed by a second direction orthogonal to the first direction and a third direction orthogonal to the second direction, wherein
the plurality of warped memory chips includes at least a first memory chip and a second memory chip,
the method for manufacturing the semiconductor module includes:
   applying adhesive layers to a plurality of locations on the surface of the first memory chip;
   attaching the second memory chip on the adhesive layers,
   applying a resin to first end parts of the first memory chip and the second memory chip along a third direction; and
   injecting a resin into at least a portion of a space between each of the plurality of memory chips from side surfaces of the first memory chip and the second memory chip, and joining the resin to form the memory cubes.

### (Additional Note 25)

The method for manufacturing the semiconductor module according to additional note 24, further comprising polishing the first memory chip and the second memory chip bonded to each other to form the memory cube.

### (Additional Note 26)

The method of manufacturing a semiconductor module according to additional note 24, wherein the polishing comprises:
planarizing a first surface of an outermost surface along the first direction and a second surface opposite the first surface in the first memory chip and the second memory chip;
planarizing a second side surface of an outermost surface along the second direction and a fourth side surface opposite the second side surface in the plurality of memory chips having the bonded warp; and
planarizing a first side surface of an outermost surface along the third direction and a third side surface opposite the first side surface in the plurality of memory chips having the bonded warp.

### (Additional Note 27)

A method for manufacturing a semiconductor module including a memory cube in which a plurality of memory chips are stacked along a first direction in parallel with a plane formed by a second direction orthogonal to the first direction and a third direction orthogonal to the second direction, wherein
each of the plurality of memory chips includes an alignment marker for adjusting positions of a device for polishing and a memory chip, and a detection marker group for detecting positions between the plurality of memory chips and polishing amounts of the plurality of memory chips, and
the method for manufacturing the semiconductor module includes:
   stacking the plurality of memory chips to form a stacked chip;
   adjusting the positions of the plurality of memory chips and the device for polishing;
   polishing a plurality of side surfaces of the stacked chip based on a predetermined reference surface of the stacked chip; and
   detecting positions of the plurality of memory chips with respect to each other using a plurality of marker groups exposed from the plurality of side surfaces of the stacked chip by the polishing.

### (Additional Note 28)

The method for manufacturing the semiconductor module according to additional note 27, wherein the device for polishing is a laser irradiation device.

### (Additional Note 29)

The method for manufacturing the semiconductor module according to additional note 28, wherein
the polishing includes:
   irradiating a laser from at least one memory chip side by the laser irradiation device;
   irradiating the laser to the stacked chip while moving the laser irradiation device along the second direction; and
   irradiating the laser to the stacked chip while moving the laser irradiation device along the third direction from above the stacked chip toward the reference surface.

### (Additional Note 30)

The method for manufacturing the semiconductor module according to additional note 27, wherein
the detection marker group includes a plurality of markers having different sizes, and
the polishing includes irradiating the laser to the stacked chip while detecting at least one of the plurality of markers.

### (Additional Note 31)

A method for manufacturing a semiconductor module including a memory cube in which a plurality of memory chips are stacked along a first direction in parallel with a plane formed by a second direction orthogonal to the first direction and a third direction orthogonal to the second direction,
each of the plurality of memory chips includes a detection marker group for detecting positions between the plurality of memory chips and polishing amounts of the plurality of memory chips, and
the method for manufacturing the semiconductor module includes:
   stacking the plurality of memory chips to form a stacked chip;
   polishing a plurality of side surfaces of the stacked chip based on a predetermined reference surface of the stacked chip; and
   detecting positions of the plurality of memory chips with respect to each other using a plurality of marker groups exposed from the plurality of side surfaces of the stacked chip by the polishing.

### (Additional Note 32)

The method for manufacturing the semiconductor module according to additional note 31, wherein the device for polishing is a CMP device.

### (Additional Note 33)

A semiconductor module including a memory cube in which a plurality of memory chips are stacked along a first direction in parallel with a plane formed by a second direction orthogonal to the first direction and a third direction orthogonal to the second direction, wherein
the memory cube sandwiches the plurality of memory chips in the first direction, and includes a first substrate and a second substrate including outermost surfaces of the memory cube in the first direction, and a bottom surface and an upper surface opposite the bottom surface on a side where a semiconductor chip is arranged in the third direction,
each of the first substrate and the second substrate does not include a wiring layer,
each of the plurality of memory chips includes a substrate and a wiring layer stacked on the substrate,
the wiring layer includes a first internal wiring, a second internal wiring, and a first inductor,
the first internal wiring is exposed to the upper surface,
the second internal wiring is exposed to the bottom surface,
the first internal wiring, the second internal wiring, and the first inductor are spaced apart from each other, and
the semiconductor module includes a first conductive layer in contact with the first internal wiring, the upper surface, and an upper surface along a third direction of the first substrate, a second conductive layer electrically connected to the first conductive layer, and a heat conductive member electrically connected to the second conductive layer.

### (Additional Note 34)

The semiconductor module of additional note 33, wherein each of the outermost surface of the first substrate and the outermost surface of the second substrate includes an R surface.

### (Additional Note 35)

The semiconductor module according to additional note 33, wherein
the memory cube includes a third substrate including a plurality of openings and a plurality of bottom openings,
the third substrate is arranged so as to be in contact with any one of the plurality of memory chips and a memory chip different from any one of the memory chips, and
the third substrate does not include a wiring layer.

### (Additional Note 36)

The semiconductor module according to additional note 33, wherein
the memory cube further includes a third substrate and a fourth substrate sandwiching the plurality of memory chips in the second direction and including an outermost surface of the memory cube in the second direction, and
each of the outermost surface of the third substrate and the outermost surface of the fourth substrate includes an R surface.

### (Additional Note 37)

The semiconductor module according to additional note 33, wherein
the internal wiring includes a first power wiring exposed on the upper surface and a second power wiring exposed on the bottom surface,
the first power wiring includes the first internal wiring, and
the second power wiring includes the second internal wiring.

### (Additional Note 38)

The semiconductor module according to additional note 33, wherein
the semiconductor module further includes a rewiring layer arranged on the bottom surface,
the rewiring layer includes a wiring, and
the wiring is electrically connected to the second internal wiring.

### (Additional Note 39)

The semiconductor module of additional note 38, wherein
the semiconductor module has a first surface, a second surface parallel to the first surface, and a second inductor, and further includes a semiconductor chip for driving the memory cube,
the rewiring layer is arranged between the second surface and the bottom surface, and
the second inductor communicates with the first inductor in a non-contact manner.

### (Additional Note 40)

The semiconductor module according to additional note 39 further comprising a plurality of metal pillars arranged on the first surface, wherein
the semiconductor chip is directly electrically connected to an external substrate using the plurality of metal pillars.

### (Additional Note 41)

A method for manufacturing a semiconductor module including a memory cube in which a plurality of memory chips are stacked along a first direction in parallel with a plane formed by a second direction orthogonal to the first direction and a third direction orthogonal to the second direction,
bonding each first surface of a first memory substrate and a second memory substrate including the first surface, second surface, and a plurality of memory chips to form a stacked substrate by stacking the first memory substrate and the second memory substrate,
polishing the second surface of the second memory substrate of the stacked substrate,
forming grooves partitioned into respective memory cubes on the stacked substrate so as to reach a portion of the substrate included in the first memory substrate,
forming an insulating layer on the groove and the polished second surface,
attaching an adhesive layer for fixing the stacked substrate to the polished second surface, and
removing the portion of the substrate and polishing the substrate to expose the groove, thereby forming the memory cube.

### (Additional Note 42)

The method for manufacturing the semiconductor module according to additional note 41, wherein the groove is formed between wiring layers included in the respective memory cubes.

### (Additional Note 43)

The method for manufacturing the semiconductor module according to additional note 41, wherein the adhesive layer is a background tape.

### (Additional Note 44)

The method for manufacturing the semiconductor module according to additional note 41, wherein the first surface of a third memory substrate including a first surface, a second surface, and a plurality of memory chips is bonded to the second surface of the second memory substrate to form a stacked substrate made of the first to third memory substrates, polishing the second surface of the third memory substrate of the stacked substrate, forming grooves partitioned into respective memory cubes in the stacked substrate so as to reach a portion of a substrate included in the first memory substrate, forming an insulating layer on the grooves and the polished second 10 surface, attaching an adhesive layer for fixing the stacked substrate to the polished second surface, and removing the portion of the substrate and polishing so as to expose the grooves to form the memory cubes.

What is claimed is:

1. A semiconductor module comprising a memory cube in which a plurality of memory chips is stacked along a first direction parallel to a plane formed by a second direction perpendicular to the first direction and a third direction perpendicular to the second direction, wherein
the memory cube includes a first outermost surface, a third outermost surface opposite the first outermost surface arranged on a side on which a semiconductor chip is arranged in the third direction, and a second outermost surface and a fourth outermost surface opposite the second outermost surface, the second outermost surface and the fourth outermost surface being the two outermost surfaces in the second direction,
each of the plurality of memory chips includes a substrate and a wiring layer stacked on the substrate,
the substrate includes a first side surface along the first outermost surface, a second side surface along the second outermost surface, a third side surface along the third outermost surface and a fourth side surface along the fourth outermost surface,
a first insulating film is included between the first outermost surface and the first side surface, between the second outermost surface and the second side surface, between the third outermost surface and the third side surface, and between the fourth outermost surface and the fourth side surface,
the wiring layer includes an internal wiring,
the internal wiring is connected to an electrode provided on at least one of the second outermost surface, the third outermost surface, and the fourth outermost surface, and
the memory cube is configured to transmit signals while being spaced apart from the semiconductor chip.

2. The semiconductor module according to claim 1, wherein
the plurality of memory chips includes at least one memory controller chip.

3. The semiconductor module according to claim 1, wherein
each of the memory chips includes a seal ring arranged on an outer periphery of the memory chip,
the seal ring is arranged in the wiring layer,
the seal ring extends parallel to the substrate, extends in the third direction, and is arranged on the substrate, in a cross-sectional view, and
the internal wiring extends in the third direction, overlaps the seal ring, and is arranged outside the seal ring along the third direction, in the cross-sectional view.

4. The semiconductor module according to claim 1, wherein
the internal wiring includes a plurality of power supply wirings and a plurality of ground wirings,
the plurality of power supply wirings and the plurality of ground wirings are exposed to either the second outermost surface or the fourth outermost surface, or, both the second outermost surface and the fourth outermost surface.

5. The semiconductor module according to claim 4, wherein
parts of the second outermost surface and the fourth outermost surface are covered with a conductive film.

6. The semiconductor module according to claim 1, further comprising a second insulating film,
wherein
the second outermost surface, the third outermost surface, and the fourth outermost surface are sealed with the first insulating film or the second insulating film.

7. The semiconductor module of claim 6, further comprising a semiconductor chip having a first surface and a second surface parallel to the first surface, for driving the memory cube.

8. The semiconductor module of claim 7, further comprising a plurality of metal pillars arranged on the first surface,
wherein
the semiconductor chip is directly electrically connected to an external substrate using the plurality of metal pillars.

9. The semiconductor module according to claim 1,
wherein
the plurality of memory chips includes a plurality of memory chips of different thicknesses, and
the memory cube has a total thickness determined by stacking the plurality of memory chips of different thicknesses.

10. The semiconductor module according to claim 1,
wherein
the wiring layer includes a first internal wiring, a second internal wiring, and a first inductor, and
the first internal wiring, the second internal wiring, and the first inductor are arranged apart from each other.

11. The semiconductor module according to claim 10,
wherein
the first inductor includes a plurality of turns and is provided across at least two or more memory chips of the plurality of memory chips, in a cross-sectional view.

12. The semiconductor module according to claim 4, further comprising:
a conductive film provided on either or both of the second outermost surface and the fourth outermost surface; and
a pressure bonding mechanism including a power supply pin;
wherein
the pressure bonding mechanism is connected to the conductive film via the power supply pin and configured to supply power from outside to the memory cube via the power supply pin.

13. The semiconductor module according to claim 12, wherein
the pressure bonding mechanism includes a power supply pin support part and a plurality of power supply pins,
the power supply pin support part includes the plurality of power supply pins and includes a function of supporting the plurality of power supply pins, and
each of the plurality of power supply pins is a connector composed of at least a terminal part, a cylindrical member connected to the terminal part, and an elastic member inserted into the cylindrical member.

14. The semiconductor module according to claim 12, wherein
the pressure bonding mechanism includes a plurality of power supply pins, each of the plurality of power supply pins is pressure-bonded to the conductive film and connected to the conductive film, and is configured to supply a voltage from the outside to the memory cube via the plurality of power supply pins.

15. The semiconductor module according to claim 12, wherein
the conductive film includes a conductor made of a metal, and
the conductor is composed of one of copper, nickel, and gold, or a combination of copper, nickel, and gold.

16. A semiconductor module comprising a memory cube in which a plurality of memory chips is stacked along a first direction parallel to a plane formed by a second direction perpendicular to the first direction and a third direction perpendicular to the second direction,
wherein
the memory cube includes a first substrate, a second substrate, a bottom, and an upper surface opposite to the bottom surface,
the first substrate and the second substrate sandwich the plurality of memory chips in the first direction,
the bottom surface is an outermost surface on a side where the semiconductor chips are arranged in the third direction,
each of the first substrate and the second substrate does not include a transistor layer including a transistor,
each of the memory chips includes a substrate, and the transistor layer and a wiring layer stacked on the substrate,
the wiring layer includes a first internal wiring, a second internal wiring, and a first inductor,
the first internal wiring, the second internal wiring, and the first inductor are arranged apart from each other, and
the semiconductor module includes the first internal wiring, a first conductive layer in contact with the upper surface and an upper surface of the first substrate along the third direction, a second conductive layer electrically connected to the first conductive layer, and a heat conductive member electrically connected to the second conductive layer.

17. The semiconductor module according to claim 16, wherein
each of the outermost surface of the first substrate and the outermost surface of the second substrate includes an R surface.

18. The semiconductor module according to claim 16, wherein
the memory cube includes a third substrate and a fourth substrate,
the third substrate and the fourth substrate sandwich the plurality of memory chips in the second direction, and
each of the outermost surface of the third substrate and the outermost surface of the fourth substrate includes an R surface.

19. The semiconductor module according to claim 16, wherein
the first internal wiring includes a first power supply wiring exposed on the upper surface,
the first power supply wiring includes the first internal wiring, and
the second power supply wiring includes the second internal wiring.
